(19) United States
(12) Patent Application Publication
(10) Pub. No.: US 2024/0431097 A1
(43) Pub. Date: Dec. 26, 2024

(54) SEMICONDUCTOR DEVICE AND METHOD OF FABRICATING THE SAME

(71) Applicant: Samsung Electronics Co., Ltd., Suwon-si (KR)

(72) Inventors: Hyunjin Lee, Suwon-si (KR); Jongmin Kim, Suwon-si (KR); Kiseok Lee, Suwon-si (KR); Yun Choi, Suwon-si (KR); Inwoo Kim, Suwon-si (KR); Hui-Jung Kim, Suwon-si (KR); Sohyun Park, Suwon-si (KR); Heejae Chae, Suwon-si (KR)

(21) Appl. No.: 18/545,328

(22) Filed: Dec. 19, 2023

(30) Foreign Application Priority Data
Jun. 23, 2023 (KR) 10-2023-0081373

(51) Int. Cl. H10B 12/00

(52) U.S. Cl. CPC H10B 12/488; H10B 12/315; H10B 12/482

(57) ABSTRACT

Disclosed is a semiconductor device comprising an active pattern including first and second edge parts spaced apart from each other in a first direction, a word line extending along a second direction between the first and second edge parts, a bit line extending along a third direction on the first edge part, a storage node contact on the second edge part, a first active pad between the bit line and the first edge part, and a second active pad between the storage node contact and the second edge part. The first active pad extends in the third direction more than the first edge part. The second active pad extends in a direction opposite to the third direction more than the second edge part.

### CROSS-REFERENCE TO RELATED APPLICATION

This U.S. nonprovisional application claims priority under 35 U.S.C § 119 to Korean Patent Application No. 10-2023-0081373 filed on Jun. 23, 2023 in the Korean Intellectual Property Office, the disclosure of which is hereby incorporated by reference in its entirety.

### BACKGROUND

The present inventive concepts relate to a semiconductor, and more particularly, to a semiconductor device and a method of fabricating the same.

Semiconductor devices have an important role in the electronic industry because of their small size, multi-functionality, and/or low fabrication cost. Semiconductor devices may be categorized as any one of semiconductor memory devices storing logic data, semiconductor logic devices processing operations of logic data, and hybrid semiconductor devices having both memory and logic elements.

Recently, high speed and low energy consumption by electronic products may require that semiconductor devices embedded in the electronic products should have high operating speed and/or lower operating voltage. For satisfying the above demands, semiconductor devices have been more highly integrated. Therefore, various studies have been conducted for enhancing the reliability of semiconductor devices.

### SUMMARY

Some embodiments of the present inventive concepts provide a semiconductor device which can be easily fabricated and has increased integration and a method of fabricating the same.

Some embodiments of the present inventive concepts provide a semiconductor device having improved electrical properties and increased reliability and a method of fabricating the same.

An object of the present inventive concepts is not limited to the mentioned above, and other objects which have not been mentioned above will be clearly understood to those skilled in the art from the following description.

According to some embodiments of the present inventive concepts, a semiconductor device may include a substrate, an active pattern on the substrate that includes a first edge part and a second edge part that are spaced apart from each other in a first direction, a word line that extends along a second direction between the first and second edge parts of the active pattern, the second direction intersects the first direction, a bit line that extends along a third direction on the first edge part of the active pattern, the third direction intersects the first and second directions, a storage node contact on the second edge part of the active pattern, a first active pad between the bit line and the first edge part of the active pattern, and a second active pad between the storage node contact and the second edge part of the active pattern. The first active pad may extend in the third direction beyond the first edge part of the active pattern. The second active pad may extend in a direction opposite to the third direction beyond the second edge part of the active pattern.

According to some embodiments of the present inventive concepts, a semiconductor device may include a substrate, an active pattern on the substrate that includes a first edge part and a second edge part that are spaced apart from each other in a first direction, a word line that extends along a second direction between the first and second edge parts of the active pattern, the second direction intersects the first direction, a bit line that extends along a third direction on the first edge part of the active pattern, the third direction intersects the first and second directions, a storage node contact on the second edge part of the active pattern, a first active pad between the bit line and the first edge part of the active pattern, and a second active pad between the storage node contact and the second edge part of the active pattern. A top surface of the second active pad may be higher than a bottom surface of the bit line with respect to the substrate.

According to some embodiments of the present inventive concepts, a semiconductor device may include a substrate, an active pattern on the substrate that includes a first edge part and a second edge part that are spaced apart from each other in a first direction, a word line that extends along a second direction between the first and second edge parts of the active pattern, the second direction intersects the first direction, a bit line that extends along a third direction on the first edge part of the active pattern, the third direction intersects the first and second directions, a lower storage node contact on the second edge part of the active pattern, an upper storage node contact on the lower storage node contact, the upper storage node contact partially overlaps the lower storage node contact in a direction perpendicular to the second direction, a first active pad between the bit line and the first edge part of the active pattern, a second active pad between the lower storage node contact and the second edge part of the active pattern, a landing pad on the upper storage node contact, and a data storage pattern on the landing pad. The first active pad may extend in the third direction beyond the first edge part of the active pattern. The second active pad may extend in a direction opposite to the third direction beyond the second edge part of the active pattern.

### BRIEF DESCRIPTION OF DRAWINGS

FIG. 1A illustrates a plan view showing a semiconductor device according to some embodiments of the present inventive concepts.

FIG. 1B illustrates an enlarged view partially showing a configuration depicted in FIG. 1A.

FIGS. 2A, 2B, 2C, and 2D illustrate cross-sectional views respectively taken along lines A-A′, B-B′, C-C′, and D-D′ of FIG. 1A.

FIGS. 3 to 5 illustrate cross-sectional views taken along line A-A′ of FIG. 1A.

FIGS. 6A, 6B, and 6C illustrate cross-sectional views respectively taken along lines B-B′, C-C′, and D-D′ of FIG. 1A.

FIGS. 7A, 7B, and 7C illustrate cross-sectional views respectively taken along lines B-B′, C-C′, and D-D′ of FIG. 1A.

FIGS. 8A and 8B illustrate cross-sectional views respectively taken along lines A-A′ and D-D′ of FIG. 1A.

FIG. 9 illustrates a plan view showing a semiconductor device according to some embodiments of the present inventive concepts.

FIGS. 10A, 10B, and 10C illustrate cross-sectional views respectively taken along lines A-A′, C-C′, and D-D′ of FIG. 9.

FIG. 11 illustrates a plan view showing a semiconductor device according to some embodiments of the present inventive concepts.

FIG. 12 illustrates a cross-sectional view taken along line A-A′ of FIG. 11.

FIG. 13 illustrates a plan view showing a semiconductor device according to some embodiments of the present inventive concepts.

FIGS. 14A and 14B illustrate cross-sectional views respectively taken along lines B-B′ and D-D′ of FIG. 13.

FIG. 15 illustrates a plan view showing a semiconductor device according to some embodiments of the present inventive concepts.

FIGS. 16A, 16B, 16C, and 16D illustrate cross-sectional views respectively taken along lines A-A′, B-B′, C-C′, and D-D′ of FIG. 15.

FIG. 17 illustrates a plan view showing a semiconductor device according to some embodiments of the present inventive concepts.

FIGS. 18A, 18B, 18C, and 18D illustrate cross-sectional views respectively taken along lines A-A′, B-B′, C-C′, and D-D′ of FIG. 17.

FIG. 19 illustrates a plan view showing a semiconductor device according to some embodiments of the present inventive concepts.

FIGS. 20A, 20B, 20C, and 20D illustrate cross-sectional views respectively taken along lines A-A′, B-B′, C-C′, and D-D′ of FIG. 19.

FIG. 21 illustrates a cross-sectional view taken along line A-A′ of FIG. 19.

FIG. 22 illustrates a plan view showing a semiconductor device according to some embodiments of the present inventive concepts.

FIGS. 23A, 23B, 23C, and 23D illustrate cross-sectional views respectively taken along lines A-A′, B-B′, C-C′, and D-D′ of FIG. 22.

FIGS. 24A and 24B illustrate cross-sectional views respectively taken along lines B-B′ and C-C′ of FIG. 1A.

FIGS. 25, 26A, 26B, 26C, 26D, 27, 28A, 28B, 28C, 28D, 29, 30A, 30B, 30C, 30D, 31, 32A, 32B, 32C, 32D, 33, 34A, 34B, 34C, and 34D illustrate plan and cross-sectional views showing a method of fabricating a semiconductor device according to some embodiments of the present inventive concepts.

FIG. 35 illustrates a cross-sectional view showing a method of fabricating a semiconductor device according to some embodiments of the present inventive concepts.

FIGS. 36 to 39 illustrate plan and cross-sectional views showing a method of fabricating a semiconductor device according to some embodiments of the present inventive concepts.

FIGS. 40 to 43 illustrate plan and cross-sectional views showing a method of fabricating a semiconductor device according to some embodiments of the present inventive concepts.

FIGS. 44, 45A, 45B, 456C, 46, 47A, 47B, and 47C illustrate plan and cross-sectional views showing a method of fabricating a semiconductor device according to some embodiments of the present inventive concepts.

FIGS. 48, 49A, 49B, and 49C illustrate plan and cross-sectional views showing a method of fabricating a semiconductor device according to some embodiments of the present inventive concepts.

FIGS. 50A and 50B illustrate cross-sectional views showing a method of fabricating a semiconductor device according to some embodiments of the present inventive concepts.

FIGS. 51, 52A, 52B, 52C, 53, 54A, 54B, and 54C illustrate plan and cross-sectional views showing a method of fabricating a semiconductor device according to some embodiments of the present inventive concepts.

FIGS. 55 and 56 illustrate plan and cross-sectional views showing a method of fabricating a semiconductor device according to some embodiments of the present inventive concepts.

FIGS. 57, 58A, and 58B illustrate plan and cross-sectional views showing a method of fabricating a semiconductor device according to some embodiments of the present inventive concepts.

FIGS. 59, 60A, 60B, 60C, and 60D illustrate plan and cross-sectional views showing a method of fabricating a semiconductor device according to some embodiments of the present inventive concepts.

FIGS. 61, 62A, 62B, 62C, 62D, 63, 64A, 64B, 64C, and 64D illustrate plan and cross-sectional views showing a method of fabricating a semiconductor device according to some embodiments of the present inventive concepts.

FIGS. 65 and 66 illustrate plan and cross-sectional views showing a method of fabricating a semiconductor device according to some embodiments of the present inventive concepts.

FIGS. 67, 68A, 68B, 68C, and 68D illustrate plan and cross-sectional views showing a method of fabricating a semiconductor device according to some embodiments of the present inventive concepts.

FIGS. 69A and 69B illustrate cross-sectional views showing a method of fabricating a semiconductor device according to some embodiments of the present inventive concepts.

### DETAILED DESCRIPTION

Some embodiments of the present inventive concepts will now be described in detail with reference to the accompanying drawings to aid in clearly explaining the present inventive concepts.

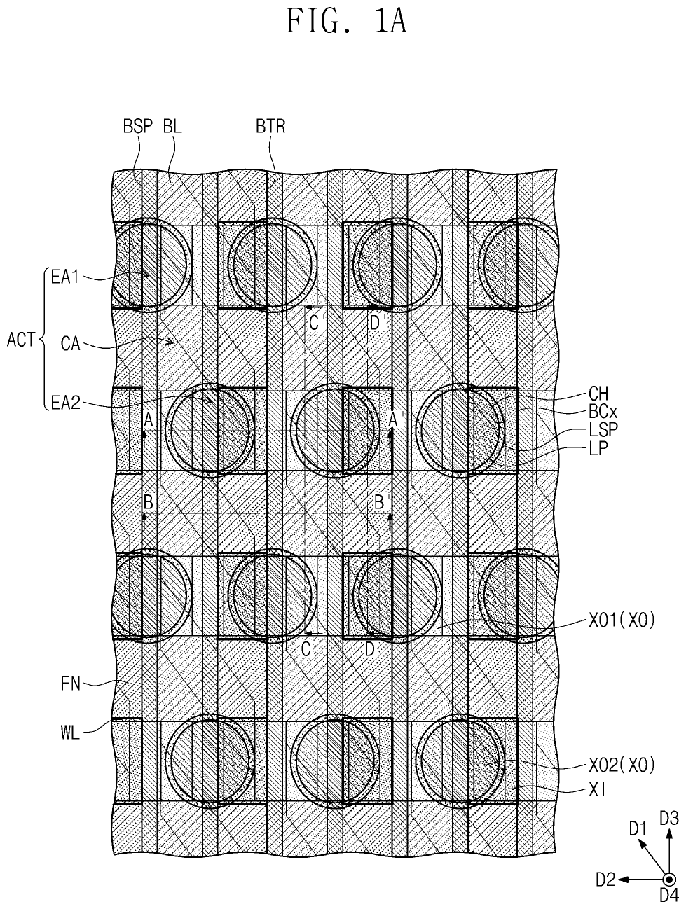

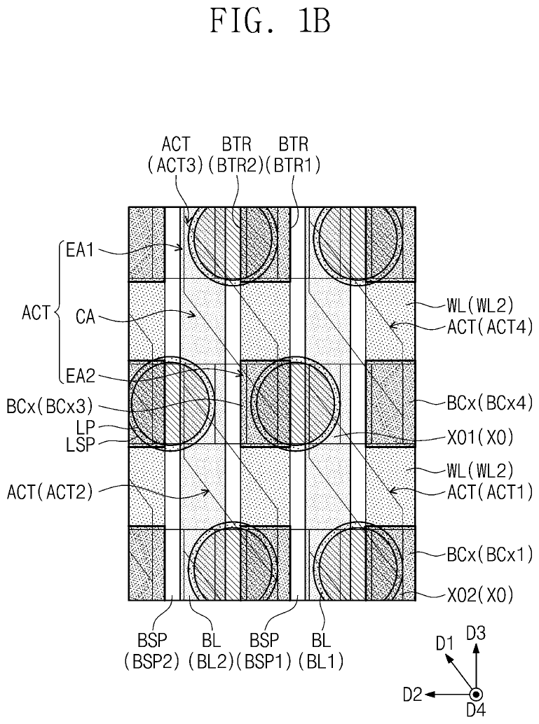

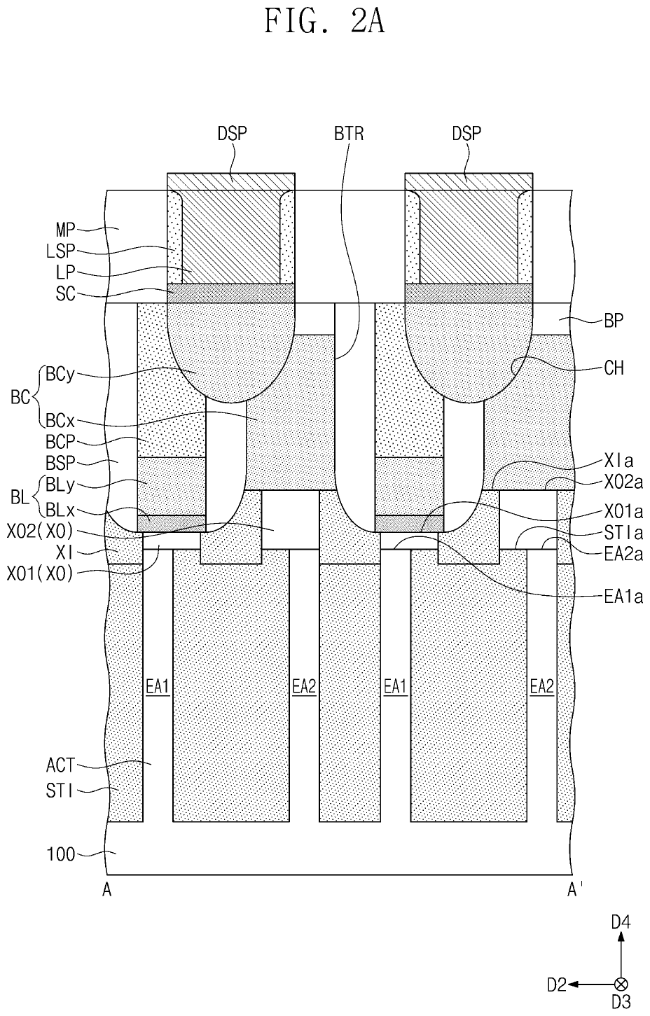

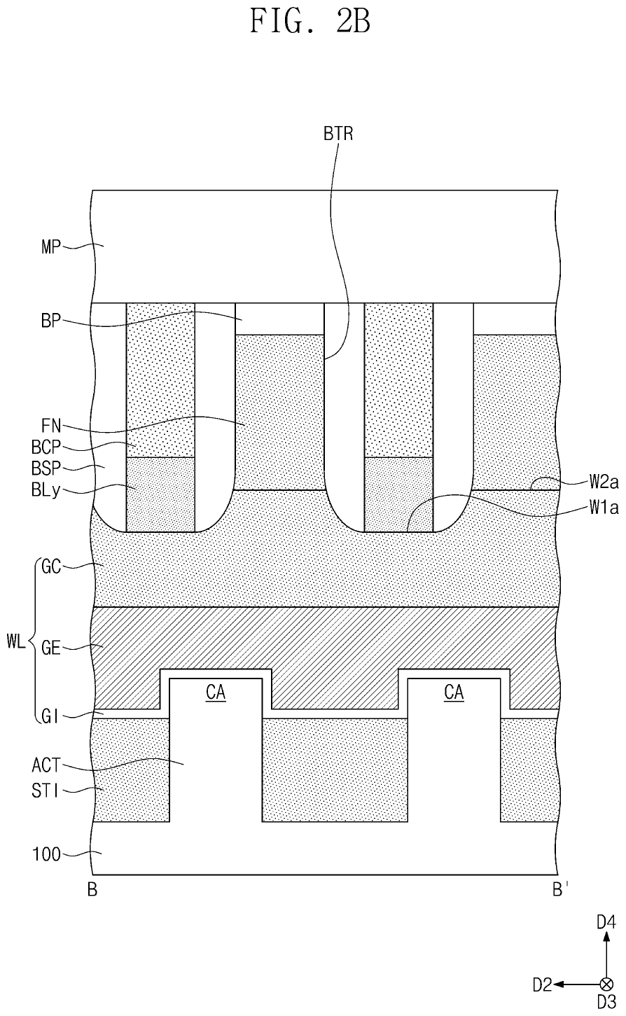

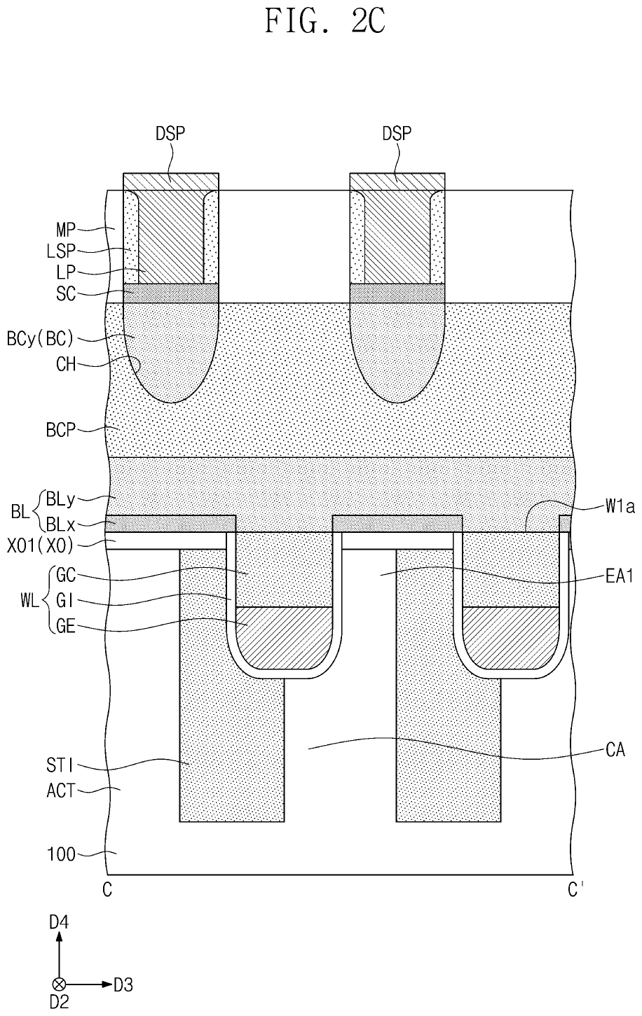

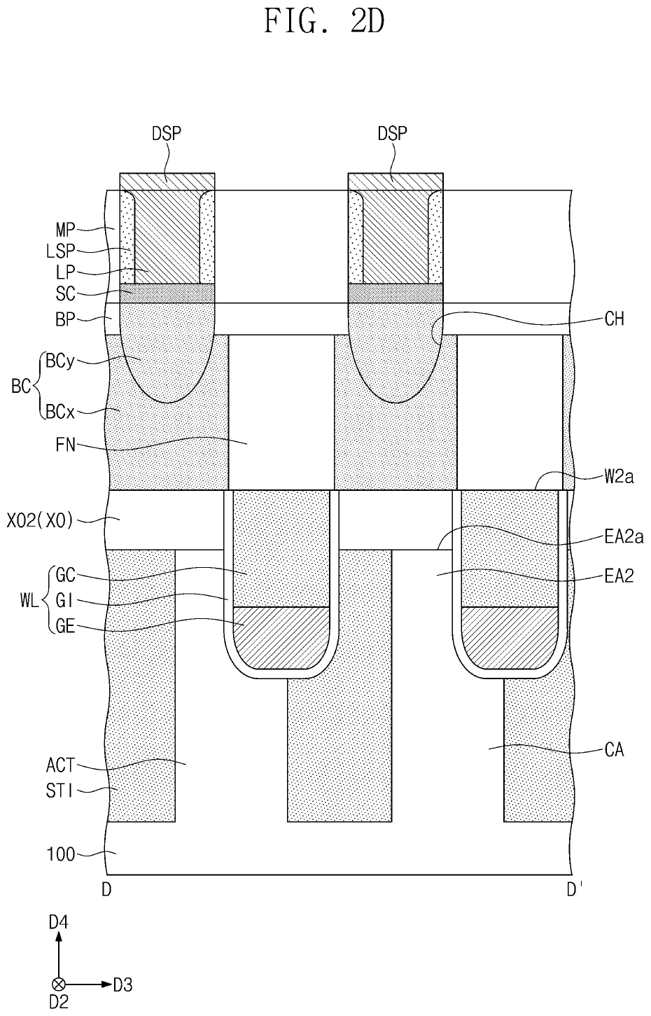

FIG. 1A illustrates a plan view showing a semiconductor device according to some embodiments of the present inventive concepts. FIG. 1B illustrates an enlarged view partially showing a configuration depicted in FIG. 1A. FIGS. 2A, 2B, 2C, and 2D illustrate cross-sectional views respectively taken along lines A-A′, B-B′, C-C′, and D-D′of FIG. 1A.

Referring to FIGS. 1A and 2A to 2D, a substrate 100 may be provided. The substrate 100 may be a semiconductor substrate, for example, a silicon substrate, a germanium substrate, or a silicon-germanium substrate.

The substrate 100 may be provided therein with a device isolation pattern STI that defines an active pattern ACT. The active pattern ACT may be provided in plural. For example, the active patterns ACT may include portions of the substrate 100 that are surrounded by the device isolation pattern STI. For convenience of description, unless otherwise specifically stated in this disclosure, the substrate 100 may be defined to indicate another portion other than the portions of the substrate 100.

Each of the active patterns ACT may have a shape elongated in a first direction D1 parallel to a bottom surface of the substrate 100. The active patterns ACT may spaced apart from each other in a second direction D2 and a third direction D3 that intersect each other and are parallel to the bottom surface of the substrate 100. The first, second, and third directions D1, D2, and D3 may intersect each other. The active patterns ACT may have a shape that protrudes in a fourth direction D4 perpendicular to the bottom surface of the substrate 100. For example, the active pattern ACT may include silicon, for example, monocrystalline silicon.

The active pattern ACT may include a first edge part EA1 and a second edge part EA2 that are spaced apart from each other in the first direction D1, and may also include a central part CA between the first edge part EA1 and the second edge part EA2. The first edge part EA1 and the second edge part EA2 may be opposite ends in the first direction D1 of the active pattern ACT. The central part CA may be provided below a subsequently described word line WL that runs across the active pattern ACT. A subsequently described word line WL may vertically overlap the central part CA of the active pattern ACT. The central parts CA of the active patterns ACT may be spaced apart from each other in the second and third directions D2 and D3.

The first and second edge parts EA1 and EA2 and the central part CA may each include therein an impurity region doped with impurities (e.g., n-type or p-type impurities). The impurity region may constitute or form a source/drain region and/or a channel region.

Neighboring active patterns ACT may be disposed side by side along the second direction D2 (or its opposite direction) or the third direction D3 (or its opposite direction). In this disclosure, the phrase “neighboring active patterns ACT are disposed side by side along a certain direction” may mean that the first edge parts EA1 of neighboring active patterns ACT are disposed along the certain direction.

Referring to FIG. 1B, a first active pattern ACT1, a second active pattern ACT2, a third active pattern ACT3, and a fourth active pattern ACT4 may be disposed along a clockwise direction. The first active pattern ACT1 and its immediately next second active pattern ACT2 may be disposed side by side along the second direction D2. The fourth active pattern ACT4 and its immediately next third active pattern ACT3 may be disposed side by side along the second direction D2. The first active pattern ACT1 and its immediately next fourth active pattern ACT4 may be disposed side by side along the third direction D3. The second active pattern ACT2 and its immediately next third active pattern ACT3 may be disposed side by side along the third direction D3.

The second edge part EA2 of the fourth active pattern ACT4, the first edge part EA1 of the first active pattern ACT1, the second edge part EA2 of the third active pattern ACT3, and the first edge part EA1 of the second active pattern ACT2 may be sequentially disposed along the second direction D2. The first edge part EA1 of the first active pattern ACT1 may be interposed between the second edge part EA2 of the fourth active pattern ACT4 and the second edge part EA2 of the third active pattern ACT3. The second edge part EA2 of the third active pattern ACT3 may be interposed between the first edge part EA1 of the first active pattern ACT1 and the first edge part EA1 of the second active pattern ACT2.

According to the present inventive concepts, as the active patterns ACT are disposed side by side along the second direction D2 (or its opposite direction) or the third direction D3 (or its opposite direction), a semiconductor device may have simplified placement of components therein. Therefore, it may be possible to reduce difficulty of patterning for forming the semiconductor device and as a result to easily fabricate the semiconductor device. In addition, as the components are relatively simply disposed, the semiconductor device may increase in integration.

Referring to FIGS. 1A and 2A to 2D, the device isolation pattern STI may include a dielectric material, such as at least one of silicon oxide (SiO₂) and silicon nitride (SiN). The device isolation pattern STI may be a single layer formed of a single material or a multiple layer including two or more materials. In this disclosure, each of the languages “A or B”, “at least one of A and B”, “at least one of A or B”, “A, B, or C”, “at least one of A, B, and C”, and “at least one of A, B, or C” may include one or any possible combination of elements listed in a corresponding one of the expressions mentioned above.

An active pad XO may be provided on the first and second edge parts EA1 and EA2 of the active pattern ACT. The active pad XO may include a first active pad XO1 on the first edge part EA1 of the active pattern ACT and a second active pad XO2 on the second edge part EA2 of the active pattern ACT. The first active pad XO1 may be interposed between the first edge part EA1 of the active pattern ACT and a bit line BL which will be discussed below. The second active pad XO2 may be interposed between the second edge part EA2 of the active pattern ACT and a storage node contact BC which will be discussed below. The first and second active pads XO1 and XO2 may be interposed between subsequently described word lines WL that neighbor each other in the third direction D3. The first active pad XO1 may have a top surface XO1a located at a level lower than that of a top surface XO2a of the second active pad XO2.

The first and second active pads XO1 and XO2 may include the same material as that of the active pattern ACT. For example, the first and second active pads XO1 and XO2 may include at least one of silicon (e.g., monocrystalline silicon), germanium, and/or silicon-germanium.

The first active pad XO1 may extend in the third direction D3 more than the first edge part EA1 of the active pattern ACT. For example, the first active pad XO1 may cover or overlap a top surface EA1a of the first edge part EA1 of the active pattern ACT, and may extend along the third direction D3 onto an uppermost surface STIa of the device isolation pattern STI adjacent to the first edge part EA1. When viewed in plan, an area of a vertical overlapping region between a subsequently described bit line BL and the top surface XO1a of the first active pad XO1 may be greater an area of a vertical overlapping region between a subsequently described bit line BL and the top surface EA1a of the first edge part EA1 of the active pattern ACT.

The second active pad XO2 may extend in a direction opposite to the third direction D3 more than the second edge part EA2 of the active pattern ACT. For example, the second active pad XO2 may cover or overlap a top surface EA2a of the second edge part EA2 of the active pattern ACT, and may extend along a direction opposite to the third direction D3 onto the uppermost surface STIa of the device isolation pattern STI adjacent to the second edge part EA2. When viewed in plan, an area of a vertical overlapping region between a subsequently described storage node contact BC and the top surface XO2a of the second active pad XO2 may be greater an area of a vertical overlapping region between a subsequently described storage node contact BC and the top surface EA2a of the second edge part EA2 of the active pattern ACT.

Referring to FIG. 1B, the first and second active pads XO1 an XO2 may each be provided in plural. The first active pad XO1 may be provided on the first edge part EA1 of each of the first, second, third, and fourth active patterns ACT1, ACT2, ACT3, and ACT4. The second active pad XO2 may be provided on the second edge part EA2 of each of the first, second, third, and fourth active patterns ACT1, ACT2, ACT3, and ACT4. The second active pad XO2 on the second edge part EA2 of the fourth active pattern ACT4, the first active pad XO1 on the first edge part EA1 of the first active pattern ACT1, the second active pad XO2 on the second edge part EA2 of the third active pattern ACT3, and the first active pad XO1 on the first edge part EA1 of the second active pattern ACT2 may be sequentially disposed along the second direction D2. The first active pad XO1 and the second active pad XO2 that neighbor each other in the second direction D2 may be spaced apart from each other across an active dielectric pattern XI which will be discussed below. The first active pads XO1 that neighbor each other in the third direction D3 may be spaced apart from each other across a word line WL which will be discussed below. The second active pads XO2 that neighbor each other in the third direction D3 may be spaced apart from each other across a word line WL which will be discussed below.

Referring back to FIGS. 1A and 2A to 2D, an active dielectric pattern XI may be interposed between the first active pad XO1 and the second active pad XO2. The active dielectric pattern XI may be interposed word lines WL that neighbor each other in the third direction D3 as discussed below. The active dielectric pattern XI may separate the first active pad XO1 and its neighboring second active pad XO2 from each other in the second direction D2. The active dielectric pattern XI may have a top surface XIa located at a level higher than that of the top surface XO1a of the first active pad XO1. The top surface XIa of the active dielectric pattern XI may be located at substantially the same level as that of the top surface XO2a of the second active pad XO2. The active dielectric pattern XI may have a bottom surface located at a level lower than that of the top surfaces EA1a and EA2a of the first and second edge parts EA1 and EA2. The bottom surface of the active dielectric pattern XI may be located at a level lower than that of the uppermost surface STIa of the device isolation pattern STI. The active dielectric pattern XI may include a dielectric material. For example, the active dielectric pattern XI may include at least one of silicon oxide (SiO₂) and silicon nitride (SiN).

The active dielectric pattern XI may be provided in plural. The active dielectric patterns XI that neighbor each other in the second direction D2 may be spaced apart from each other across the first active pad XO1 or the second active pad XO2. The active dielectric patterns XI may be linearly disposed along the second direction D2 between word lines WL that neighbor each other in the third direction D3 as discussed below. The active dielectric patterns XI that neighbor each other in the third direction D3 may be spaced apart from each other across a word line WL which will be discussed below.

A word line WL may run across the active patterns ACT and the device isolation pattern STI. The word line WL may be interposed between the first active pads XO1 that neighbor each other in the third direction D3 and the second active pads XO2 that neighbor each other in the third direction D3. The word line WL may be provided in plural. The word lines WL may extend along the second direction D2, and may be spaced apart from each other in the third direction D3. The word line WL may be provided on the central part CA of the active pattern ACT and between the first and second edge parts EA1 and EA2. The central part CA of the active pattern ACT may be a portion of the active pattern ACT positioned below the word line WL. The first edge part EA1 of the active pattern ACT may be another portion of the active pattern ACT that protrudes in the third direction D3 from the word line WL. The second edge part EA2 of the active pattern ACT may be a still another portion of the active pattern ACT that protrudes from the word line WL in a direction opposite to the third direction D3. For example, one word line WL may extend along the second direction D2 on the central parts CA on the active patterns ACT linearly disposed side by side along the second direction D2.

Each of the word lines WL may include a gate electrode GE, a gate dielectric pattern GI, and a gate capping pattern GC. The gate electrode GE may penetrate in the second direction D2 through the active patterns ACT and the device isolation pattern STI. The gate dielectric pattern GI may be interposed between the gate electrode GE and the active patterns ACT and between the gate electrode GE and the device isolation pattern STI. The gate electrode GE may be provided thereon with the gate capping pattern GC that covers or overlaps a top surface of the gate electrode GE. The gate electrode GE may include a conductive material. The gate electrode GE may be a single layer formed of one material or a multiple layer formed of two or more materials. The gate dielectric pattern GI may include, for example, at least one of silicon oxide (SiO₂) or high-k dielectric materials. In this disclosure, the high-k dielectric material may be defined to indicate a material whose dielectric constant is greater than that of silicon oxide. The gate capping pattern GC may include silicon nitride (SiN).

The word line WL may have a first top surface W1a and a second top surface W2a. The first top surface W1a of the word line WL may be a portion of a top surface of the word line WL positioned below a bit line BL which will be discussed below, and the second top surface W2a of the word line WL may be another portion of the top surface of the word line WL. The second top surface W2a of the word line WL may be positioned below a fence pattern FN which will be discussed below. The first top surface W1a and the second top surface W2a of the word line WL may be located at different levels from each other. The first top surface W1a of the word line WL may be located at a level lower than that of the second top surface W2a of the word line WL. The first top surface W1a of the word line WL may be located at substantially the same level as that of the top surface XO1a of the first active pad XO1. The second top surface W2a of the word line WL may be located at substantially the same level as that of the top surface XO2a of the second active pad XO2.

Referring to FIG. 1B, a first word line WL1 and a second word line WL2 may be provided which are spaced apart from each other in the third direction D3. The first word line WL1 may be provided on the central part CA of the first active pattern ACT1 and the central part CA of the second active pattern ACT2, and may extend along the second direction D2. The second word line WL2 may be provided on the central part CA of the fourth active pattern ACT4 and the central part CA of the third active pattern ACT3, and may extend along the second direction D2. The second edge part EA2 of the fourth active pattern ACT4, the first edge part EA1 of the first active pattern ACT1, the second edge part EA2 of the third active pattern ACT3, and the first edge part EA1 of the second active pattern ACT2 may be sequentially disposed along the second direction D2 between the first word line WL1 and the second word line WL2.

Referring back to FIGS. 1A and 2A to 2D, a lower storage node contact BCx may be provided on the second edge part EA2 of the active pattern ACT. For example, the lower storage node contact BCx may be interposed between bit lines BL that neighbor each other in the second direction D2 as discussed below and between fence patterns FN that neighbor each other in the third direction D3 as discussed below. The lower storage node contact BCx may be in contact with the top surface XO2a of the second active pad XO2. For example, the lower storage node contact BCx may completely cover or completely overlap the top surface XO2a of the second active pad XO2. The lower storage node contact BCx may be electrically connected through the second active pad XO2 to the second edge part EA2 of the active pattern ACT. For example, the lower storage node contact BCx may include at least one of silicon (e.g., impurity-containing polysilicon) and metallic materials (e.g., Ti, Mo, W, Cu, Al, Ta, Ru, Ir, and Co).

According to the present inventive concepts, the second active pad XO2 may further extend along a direction opposite to the third direction D3 on the second edge part EA2 of the active pattern ACT. There may thus be an increase in contact area between the second active pad XO2 and the lower storage node contact BCx. In addition, even when the lower storage node contact BCx is misaligned, the lower storage node contact BCx may be in contact with the second active pad XO2. As the second active pad XO2 is provided, an easy electrical connection may be accomplished between the lower storage node contact BCx and the second edge part EA2 of the active pattern ACT. As a result, a semiconductor device may have improved electrical properties and increased reliability.

The lower storage node contact BCx may be provided in plural. The plurality of lower storage node contacts BCx may be spaced apart from each other in the second and third directions D2 and D3. The lower storage node contacts BCx that neighbor each other in the second direction D2 may be spaced apart from each other across a bit line BL which will be discussed below. The lower storage node contacts BCx that neighbor each other in the third direction D3 may be spaced apart from each other across a fence pattern FN which will be discussed below.

Referring to FIG. 1B, there may be provided a first lower storage node contact BCx1, a second lower storage node contact BCx2, a third lower storage node contact BCx3, and a fourth lower storage node contact BCx4 that are spaced apart from each other in the second and third directions D2 and D3. The first lower storage node contact BCx1, the second lower storage node contact BCx2, the third lower storage node contact BCx3, and the fourth lower storage node contact BCx4 may be disposed along a clockwise direction. The first lower storage node contact BCx1, the second lower storage node contact BCx2, the third lower storage node contact BCx3, and the fourth lower storage node contact BCx4 may be respectively provided on the second edge part EA2 of the first active pattern ACT1, the second edge part EA2 of the second active pattern ACT2, the second edge part EA2 of the third active pattern ACT2, and the second edge part EA2 of the fourth active pattern ACT4. When viewed in plan, the third lower storage node contact BCx3 and the fourth lower storage node contact BCx4 may be interposed between the first word line WL1 and the second word line WL2. When viewed in plan, the second lower storage node contact BCx2 and the third lower storage node contact BCx3 may be interposed between a first bit line BL1 and a second bit line BL2 which will be discussed below.

Referring back to FIGS. 1A and 2A to 2D, a fence pattern FN may be provided on the word line WL. For example, the fence pattern FN may be interposed between bit lines BL that neighbor each other in the second direction D2 as discussed below and between the lower storage node contacts BCx that neighbor each other in the third direction D3. The fence pattern FN may have a bottom surface located at a level substantially the same as or lower than that of the second top surface W2a of the word line WL and that of the top surface XO2a of the second active pad XO2. The bottom surface of the fence pattern FN may be located at a level higher than that of a bottom surface of a bit line BL which will be discussed below.

The fence pattern FN may be provided in plural. The plurality of fence patterns FN may be spaced apart from each other in the second and third directions D2 and D3. The fence patterns FN that neighbor each other in the second direction D2 may be spaced apart from each other across a bit line BL which will be discussed below. The fence patterns FN that neighbor each other in the third direction D3 may be spaced apart from each other across the lower storage node contact BCx. The fence pattern FN may include, for example, at least one of silicon oxide (SiO₂), silicon nitride (SiN), silicon carbonitride (SiOC), and silicon oxycarbonitride (SiOCN).

A buffer pattern BP may cover or overlap a top surface of the lower storage node contact BCx and a top surface of the fence pattern FN. The buffer pattern BP may be interposed between bit lines BL that neighbor each other in the second direction D2 as discussed below. For example, buffer pattern BP may include at least one of silicon oxide, silicon nitride, and silicon oxynitride. The buffer pattern BP may be a single layer formed of one material or a multiple layer formed of two or more materials. The buffer pattern BP may be a composite layer including a lower buffer pattern and an upper buffer pattern.

A bit-line trench region BTR may be defined between the lower storage node contacts BCx that neighbor each other in the second direction D2 and between the fence patterns FN that neighbor each other in the second direction D2. The bit-line trench region BTR may be provided on the first active pad XO1. The bit-line trench region BTR may cause the active dielectric pattern XI and the gate capping pattern GC to each have an upper portion that is recessed to a certain depth. The bit-line trench region BTR may extend along the third direction D3 on the first edge parts EA1 of the active patterns ACT that are linearly disposed side by side along the third direction D3.

The bit-line trench region BTR may be located at a level higher than that of the first and second edge parts EA1 and EA2 of the active pattern ACT. The bit-line trench region BTR may be spaced apart from the second edge part EA2 of the active pattern ACT. The bit-line trench region BTR may not vertically overlap the second edge part EA2.

The bit-line trench region BTR may be provided in plural. The plurality of bit-line trench regions BTR may be spaced apart from each other in the second direction D2. The bit-line trench regions BTR that neighbor each other in the second direction D2 may be spaced apart from each other across the lower storage node contact BCx or the fence pattern FN.

Referring to FIG. 1B, there may be provided a first bit-line trench region BTR1 and a second bit-line trench region BTR2 that are spaced apart from each other in the second direction D2. The first bit-line trench region BTR1 may extend along the third direction D3, while being provided on the first edge part EA1 of the first active pattern ACT1 and the first edge part EA1 of the fourth active pattern ACT4. The second bit-line trench region BTR2 may extend along the third direction D3, while being provided on the first edge part EA1 of the second active pattern ACT2 and the first edge part EA1 of the third active pattern ACT3. The second and fourth lower storage node contacts BCx2 and BCx4 may be interposed between a first bit line BL1 and a second bit line BL2 which will be discussed below.

Referring back to FIGS. 1A and 2A to 2D, in the bit-line trench region BTR, a bit line BL may be provided on the first edge part EA1 of the active pattern ACT. The bit line BL may be in contact with the top surface XO1a of the first active pad XO1. For example, the bit line BL may completely cover or completely overlap the top surface XO1a of the first active pad XO1. The bit line BL may be electrically connected through the first active pad XO1 to the first edge part EA1 of the active pattern ACT.

According to the present inventive concepts, the first active pad XO1 may further extend along the third direction D3 on the first edge part EA1 of the active pattern ACT. There may thus be an increase in contact area between the first active pad XO1 and the bit line BL. As the first active pad XO1 is provided, an easy electrical connection may be accomplished between the bit line BL and the first edge part EA1 of the active pattern ACT. As a result, a semiconductor device may have increased electrical properties.

The bit line BL may have a bottom surface located at a level lower than that of the top surface XO2a of the second active pad XO2 and that of a bottom surface of the lower storage node contact BCx.

The bit line BL may be provided in plural. The bit lines BL may be spaced apart from each other in the second direction D2 and may extend along the third direction D3. One bit line BL may extend along the third direction D3 on the first edge parts EA1 of the active patterns ACT that are linearly disposed side by side along the third direction D3. For example, the one bit line BL may be in contact with the first active pads XO1 on the first edge parts EA1 of the active patterns ACT that are linearly disposed.

The bit line BL may be a multiple layer including two or more materials. For example, the bit line BL may include a lower bit line BLx and an upper bit line BLy. The upper bit line BLy may extend along the third direction D3. The lower bit line BLx may be interposed between the first active pad XO1 and the upper bit line BLy.

The lower bit line BLx may include at least one of a first barrier pattern (not shown) that prevents diffusion of a material included in the upper bit line BLy and a first silicide pattern (not shown) that improves contact resistance between the upper bit line BLy and the first edge part EA1. For example, the lower bit line BLx may include at least one of metal silicide (e.g., silicide of one or more of Ti, Mo, W, Cu, Al, Ta, Ru, Ir, and/or Co) and metal nitride (e.g., nitride of one or more of Ti, Mo, W, Cu, Al, Ta, Ru, Ir, and/or Co). For example, the upper bit line BLy may include a metallic material, such as Ti, Mo, W, Cu, Al, Ta, Ru, Ir, and/or Co.

Referring to FIG. 1B, there may be a first bit line BL1 and a second bit line BL2 that are spaced apart from each other in the second direction D2. The first bit line BL1 may be provided in the first bit-line trench region BTR1. The second bit line BL2 may be provided in the second bit-line trench region BTR2. The first bit line BL1 may extend along the third direction D3, while being provided on the first edge part EA1 of the first active pattern ACT1 and the first edge part EA1 of the fourth active pattern ACT4. The second bit line BL2 may extend along the third direction D3, while being provided on the first edge part EA1 of the second active pattern ACT2 and the first edge part EA1 of the third active pattern ACT3. When viewed in plan, the second edge part EA2 of the second active pattern ACT2 and the second edge part EA2 of the third active pattern ACT3 may be interposed between the first bit line BL1 and the second bit line BL2.

Referring back to FIGS. 1A and 2A to 2D, in the bit-line trench region BTR, a bit-line capping pattern BCP may be provided on a top surface of the bit line BL. The bit-line capping pattern BCP, together with the bit line BL, may extend along the third direction D3. The bit-line capping pattern BCP may be provided in plural. The plurality of bit-line capping patterns BCP may be spaced apart from each other in the second direction D2. The bit-line capping pattern BCP may vertically overlap the bit line BL. The bit-line capping pattern BCP may be formed of a single layer or a plurality of layers. The bit-line capping pattern BCP may include a first capping pattern, a second capping pattern, and a third capping pattern that are sequentially stacked. Each of the first to third capping patterns may include silicon nitride (SiN). In some embodiments, the bit-line capping pattern BCP may include four or more stacked capping patterns.

In the bit-line trench region BTR, a bit-line spacer BSP may be provided on a lateral surface of the bit line BL and a lateral surface of the bit-line capping pattern BCP. The bit-line spacer BSP may cover or overlap the lateral surface of the bit line BL, the lateral surface of the bit-line capping pattern BCP, and an inner lateral surface of the bit-line trench region BTR. The bit-line spacer BSP may cover or overlap a lateral surface of the lower storage node contact BCx. The bit-line spacer BSP may be in contact with the active dielectric pattern XI. The bit-line spacer BSP may extend along the third direction D3 on the lateral surface of the bit line BL. For example, the bit-line spacer BSP may have a top surface located at substantially the same level as that of a top surface of the buffer pattern BP. The bit-line spacer BSP may be provided in plural. The plurality of bit-line spacers BSP may be spaced apart from each other in the second direction D2. In one bit-line trench region BTR, two bit-line spacers BSP that neighbor each other in the second direction D2 may be spaced apart from each other across one bit line BL. For example, the bit-line spacer BSP may include at least one of silicon oxide (SiO₂), silicon nitride (SiN), silicon carbonitride (SiOC), and silicon oxycarbonitride (SiOCN). The bit-line spacer BSP may be a single layer formed of one material or a multiple layer formed of two or more materials.

A mold pattern MP may be provided on the buffer pattern BP, the bit-line capping pattern BCP, and the bit-line spacer BSP. The mold pattern MP may surround a landing pad LP which will be discussed below. The mold pattern MP may be interposed between neighboring landing pads LP. When viewed in plan, the mold pattern MP may have a mesh shape including contact holes CH which will be discussed below. For example, the mold pattern MP may include at least one of silicon oxide (SiO₂), silicon nitride (SiN), silicon carbonitride (SiOC), and silicon oxycarbonitride (SiOCN).

A contact hole CH may be provided on the second edge part EA2 of the active pattern ACT. The contact hole CH may penetrate the mold pattern MP and the buffer pattern BP. The contact hole CH may cause the lower storage node contact BCx, the bit-line capping pattern BCP, and the bit-line spacer BSP to each have an upper portion that is recessed to a certain depth. The contact hole CH may be shifted in the second direction D2 (or its opposite direction) from the lower storage node contact BCx. A portion of the contact hole CH may vertically overlap the bit line BL. A portion of the contact hole CH may vertically overlap the lower storage node contact BCx. The contact hole CH may be provided in plural. The plurality of contact holes CH may be disposed linearly along the second direction D2 and arranged in a zigzag fashion along the third direction D3.

In the contact hole CH, an upper storage node contact BCy may be provided on the second edge part EA2 of the active pattern ACT. The upper storage node contact BCy may be provided on and in contact with the lower storage node contact BCx. The upper storage node contact BCy may be electrically connected to the second edge part EA2 of a corresponding active pattern ACT through a corresponding lower storage node contact BCx and a corresponding second active pad XO2. The upper storage node contact BCy may be shifted in the second direction D2 (or its opposite direction) from the lower storage node contact BCx. A portion of the upper storage node contact BCy may vertically overlap the bit line BL. The upper storage node contact BCy may be in contact with the bit-line capping pattern BCP and the bit-line spacer BSP. The upper storage node contact BCy and the lower storage node contact BCx may constitute or form a storage node contact BC.

A lowermost surface of the upper storage node contact BCy may be located at a level lower than that of the top surface of the lower storage node contact BCx.

The upper storage node contact BCy may be provided in plural. The plurality of upper storage node contacts BCy may be correspondingly provided in the contact holes CH. The upper storage node contacts BCy may be spaced apart from each other in the second and third directions D2 and D3. The upper storage node contacts BCy, together with the contact holes CH, may be disposed linearly along the second direction D2 and arranged in a zigzag fashion along the third direction D3.

In the contact hole CH, a landing pad LP may be provided on the upper storage node contact BCy. The landing pad LP may vertically overlap the upper storage node contact BCy. The landing pad LP may be electrically connected to the second edge part EA2 of a corresponding active pattern ACT through a corresponding upper storage node contact BCy, a corresponding lower storage node contact BCx, and a corresponding second active pad XO2. The landing pad LP may have a bottom surface located at a level higher than that of a top surface of the bit-line capping pattern BCP. The bottom surface of the landing pad LP may be located at a level higher than that of a bottom surface of the mold pattern MP. The landing pad LP may be provided in plural. The plurality of landing pads LP may be spaced apart from each other in the second and third directions D2 and D3. For example, the landing pad LP may include at least one metallic material (e.g., Ti, Mo, W, Cu, Al, Ta, Ru, Ir, and/or Co). A second silicide pattern SC may further be provided between the landing pad LP and the upper storage node contact BCy. The second silicide pattern SC may include metal silicide (e.g., silicide of one or more of Ti, Mo, W, Cu, Al, Ta, Ru, Ir, and/or Co). In some embodiments, a second barrier pattern (not shown) may be interposed between the landing pad LP and other components, and may prevent diffusion of a material included in the landing pad LP. The second barrier pattern may include metal nitride (e.g., nitride of one or more of Ti, Mo, W, Cu, Al, Ta, Ru, Ir, and/or Co).

A landing pad spacer LSP may be provided on a lateral surface of the landing pad LP. The landing pad spacer LSP may surround and cover or overlap the lateral surface of the landing pad LP. The landing pad spacer LSP may cover or overlap an inner lateral surface of the contact hole CH. An outer lateral surface of the landing pad spacer LSP may be aligned with a lateral surface of the second silicide pattern SC, but the present inventive concepts are not limited thereto. Although not shown in figures, compared to the second silicide pattern SC, the outer lateral surface of the landing pad spacer LSP may protrude in a direction away from a center of the contact hole CH. The landing pad spacer LSP may include at least one of silicon oxide (SiO₂), silicon nitride (SiN), silicon carbonitride (SiOC), and/or silicon oxycarbonitride (SiOCN).

A data storage pattern DSP may be provided on the landing pad LP. The data storage pattern DSP may be provided in plural. The plurality of data storage patterns DSP may be spaced apart from each other in the second and/or third directions D2 and D3. Each of the data storage patterns DSP may be electrically connected to the second edge part EA2 of a corresponding active pattern ACT through a corresponding landing pad LP and a corresponding storage node contact BC.

The data storage pattern DSP may be, for example, a capacitor including a bottom electrode, a dielectric layer, and a top electrode. In this case, a semiconductor device according to the present inventive concepts may be a dynamic random access memory (DRAM). For another example, the data storage pattern DSP may include a magnetic tunnel junction pattern. In this case, a semiconductor device according to the present inventive concepts may be a magnetic random access memory (MRAM). For another example, the data storage pattern DSP may include a phase change material or a variable resistance material. In this case, a semiconductor device according to the present inventive concepts may be a phase change random access memory (PRAM) or a resistive random access memory (ReRAM). This is, however, merely an example, and the present inventive concepts are not limited thereto. The data storage pattern DSP may include various structures and/or materials capable of storing data.

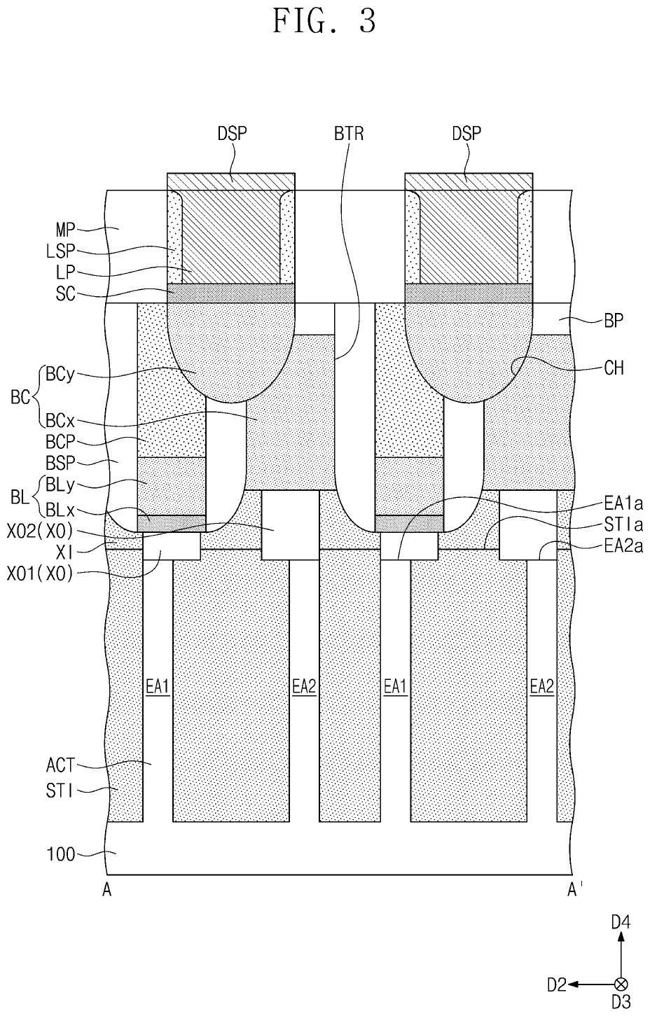

With reference to FIGS. 3 to 24B, the following will describe various embodiments of the present inventive concepts. For brevity of description, an explanation of components repetitive to those discussed above will be omitted, and a difference thereof will be discussed in detail.

FIGS. 3 to 5 illustrate cross-sectional views taken along line A-A′ of FIG. 1A.

Referring to FIGS. 3 to 5, the top surfaces EA1a and EA2a of the first and second edge parts EA1 and EA2 of the active pattern ACT may be located at a level lower than that of the uppermost surface STIa of the device isolation pattern STI. The first and second active pads XO1 and XO2 may have bottom surfaces located at a level lower than that of the uppermost surface STIa of the device isolation pattern STI.

Referring to FIG. 3, the bottom surfaces of the first and second active pads XO1 and XO2 may be located at a level lower than that of a bottom surface of the active dielectric pattern XI. The bottom surfaces of the active dielectric patterns XI may be located at substantially the same level.

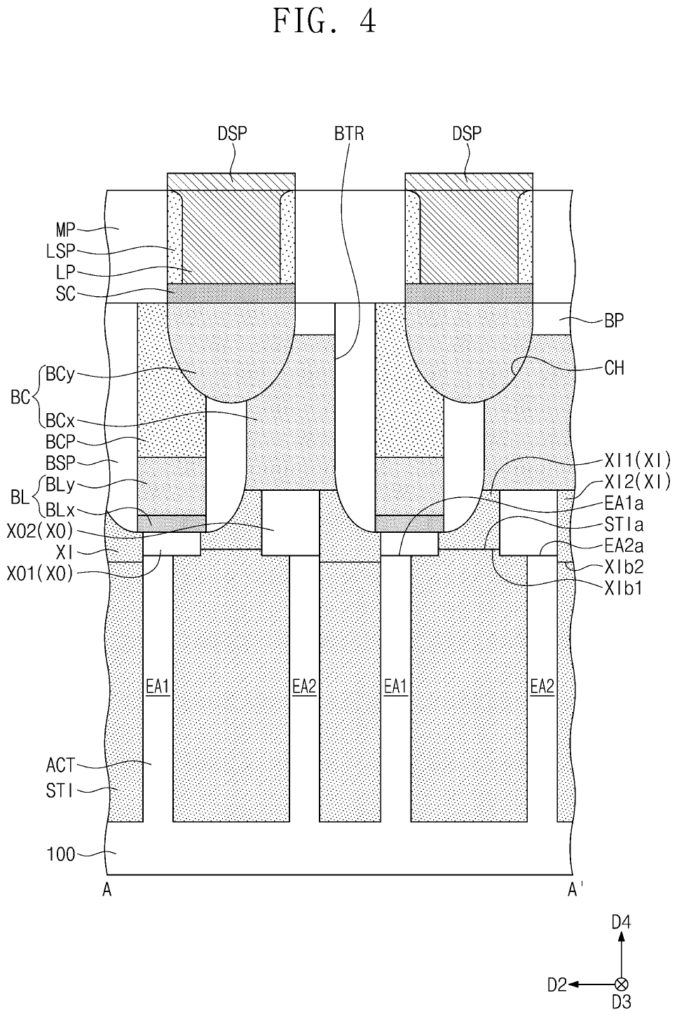

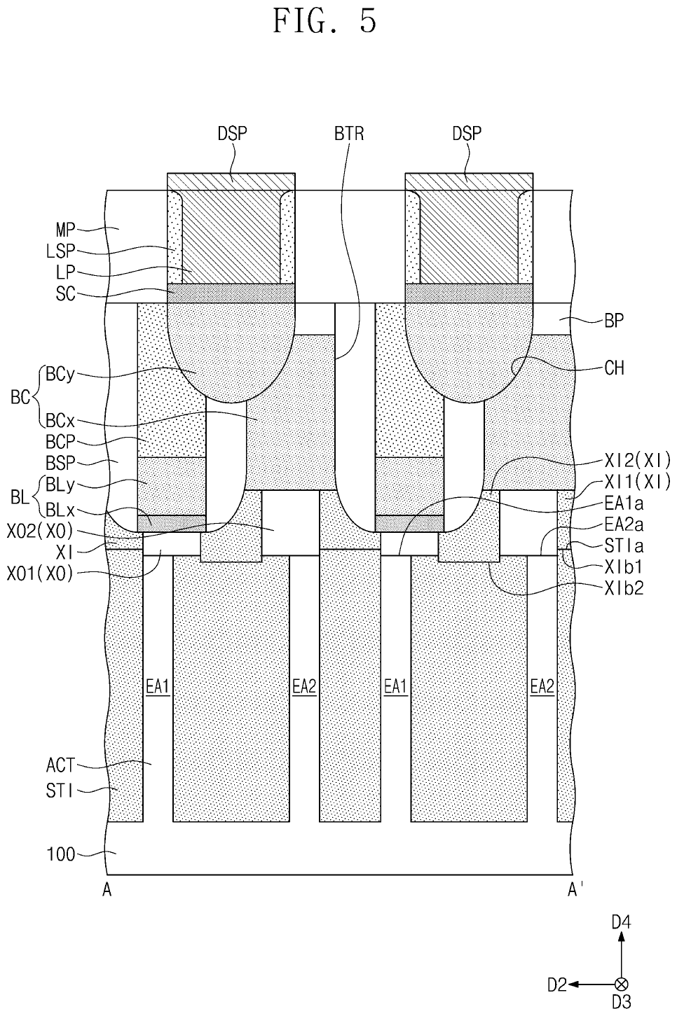

Referring to FIGS. 4 and 5, the active dielectric pattern XI may include a first active dielectric pattern XI1 and a second active dielectric pattern XI2 whose bottom surfaces are located at different levels. The first active dielectric pattern XI1 may have a bottom surface XIb1 located at a level higher than that of a bottom surface XIb2 of the second active dielectric pattern XI2. The bottom surface XIb1 of the first active dielectric pattern XI1 may be located at substantially the same level as that of the uppermost surface STIa of the device isolation pattern STI. The bottom surface XIb1 of the first active dielectric pattern XI1 may be located at a level higher than that of the top surfaces EA1a and EA2a of the first and second edge parts EA1 and EA2. The bottom surface XIb2 of the second active dielectric pattern XI2 may be located at a level lower than that of the top surfaces EA1a and EA2a of the first and second edge parts EA1 and EA2.

Referring to FIG. 4, the first active dielectric pattern XI1 may be interposed between the first active pad XO1 and the second active pad XO2 that are sequentially disposed in the second direction D2. The second active dielectric pattern XI2 may be interposed between the first active pad XO1 and the second active pad XO2 that are sequentially disposed in a direction opposite to the second direction D2.

Referring to FIG. 5, the first active dielectric pattern XI1 may be interposed between the first active pad XO1 and the second active pad XO2 that are sequentially disposed in a direction opposite to the second direction D2. The second active dielectric pattern XI2 may be interposed between the first active pad XO1 and the second active pad XO2 that are sequentially disposed in the second direction D2.

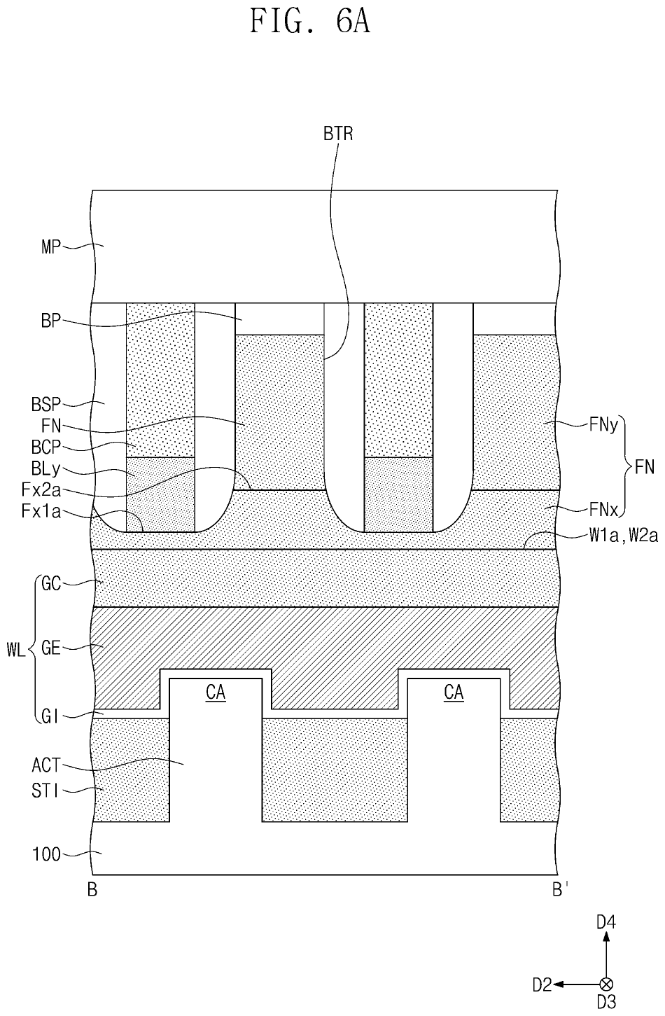

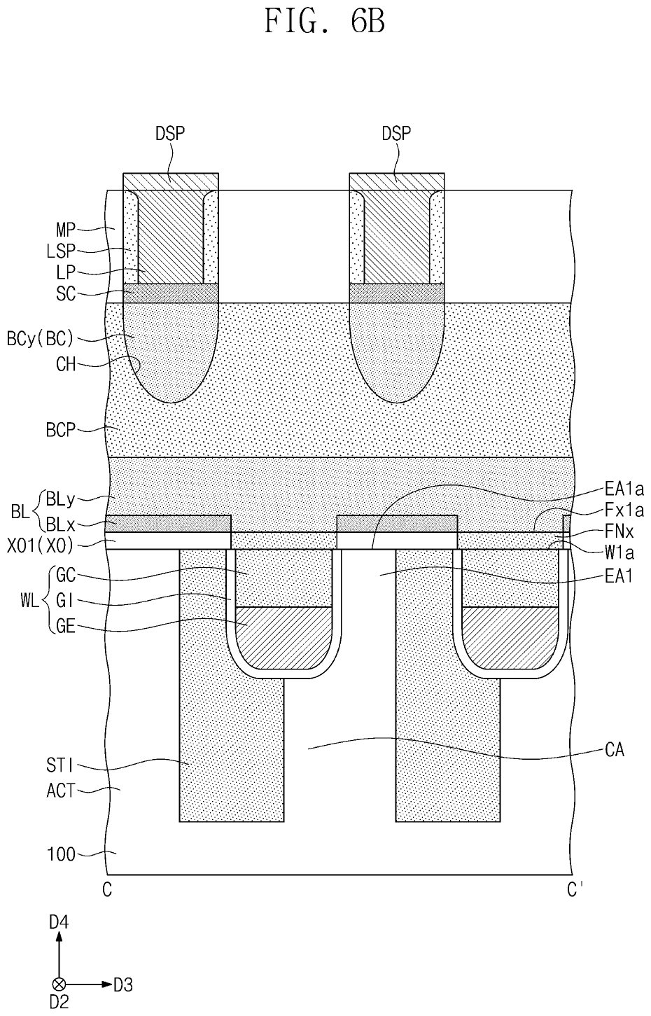

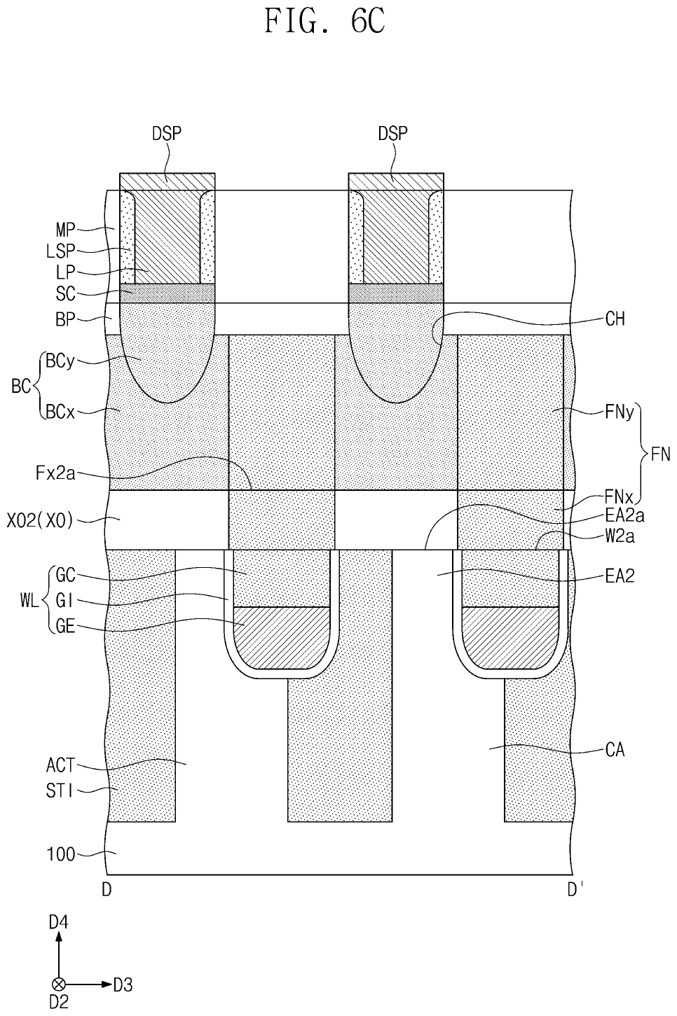

FIGS. 6A, 6B, and 6C illustrate cross-sectional views respectively taken along lines B-B′, C-C′, and D-D′ of FIG. 1A.

Referring to FIGS. 6A to 6C, the first top surface W1a of the word line WL may be located at substantially the same level as that of the second top surface W2a of the word line WL. The first top surface W1a and the second top surface W2a of the word line WL may be located at substantially the same level as that of the top surfaces EA1a and EA2a of the first and second edge parts EA1 and EA2 of the active pattern ACT.

The fence pattern FN may include an upper fence pattern FNy and a lower fence pattern FNx. The lower fence pattern FNx may be provided on the word line WL. The lower fence pattern FNx may extend along the second direction D2 on the word line WL. The lower fence pattern FNx may be interposed between the first active pads XO1 that neighbor each other in the third direction D3 and between the second active pads XO2 that neighbor each other in the third direction D3. The lower fence pattern FNx may be provided in plural. Ones of the lower fence patterns FNx may be spaced apart from each other in the third direction D3. Ones of the lower fence patterns FNx that neighbor each other in the third direction D3 may be spaced apart from each other across the first active pad XO1 or the second active pad XO2.

The lower fence pattern FNx may have a first top surface Fx1a and a second top surface Fx2a that are located at different levels. The first top surface Fx1a of the lower fence pattern FNx may be positioned below the bit line BL. The second top surface Fx2a of the lower fence pattern FNx may be positioned below the upper fence pattern FNy. The first top surface Fx1a of the lower fence pattern FNx may be located at a level lower than that of the second top surface Fx2a of the lower fence pattern FNx. The first top surface Fx1a of the lower fence pattern FNx may be located at substantially the same level as that of the top surface XO1a of the first active pad XO1. The second top surface Fx2a of the lower fence pattern FNx may be located at substantially the same level as that of the top surface XO2a of the second active pad XO2. The lower fence pattern FNx may have a bottom surface located at a level substantially the same as or lower than that of the top surfaces EA1a and EA2a of the first and second edge parts EA1 and EA2 of the active pattern ACT.

The upper fence pattern FNy may be provided on the lower fence pattern FNx. The upper fence pattern FNy and the lower fence pattern FNx may be distinguished from each other with their interface and in contact with each other via the interface.

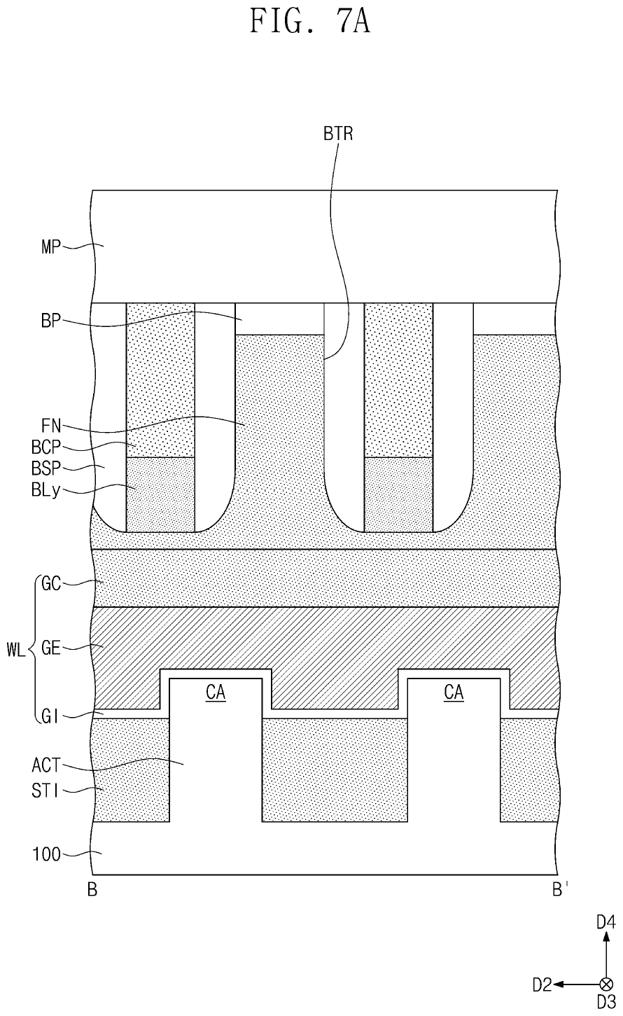

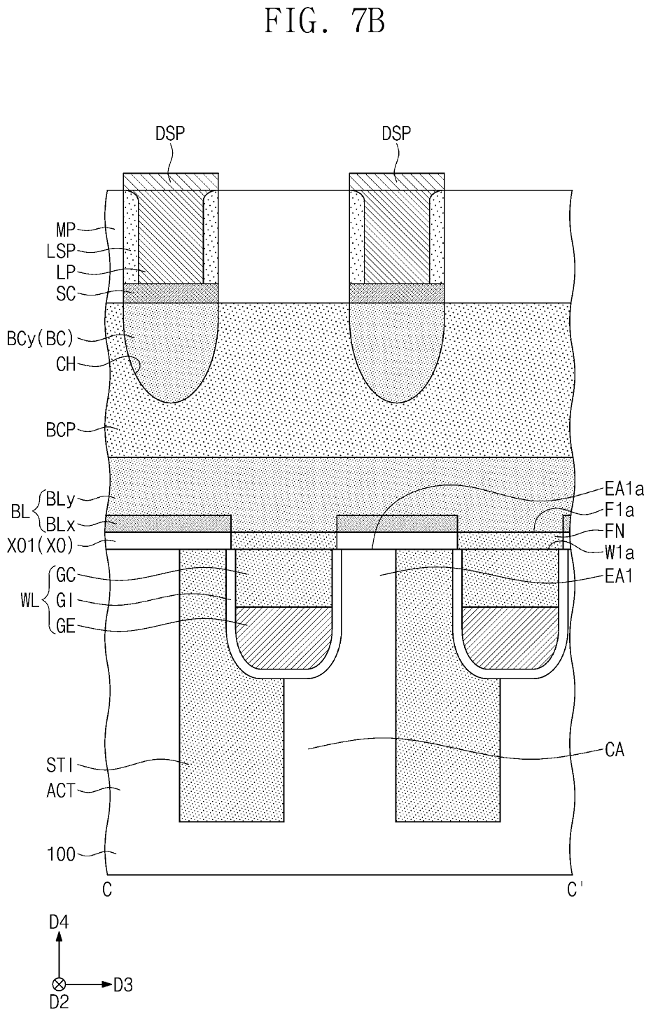

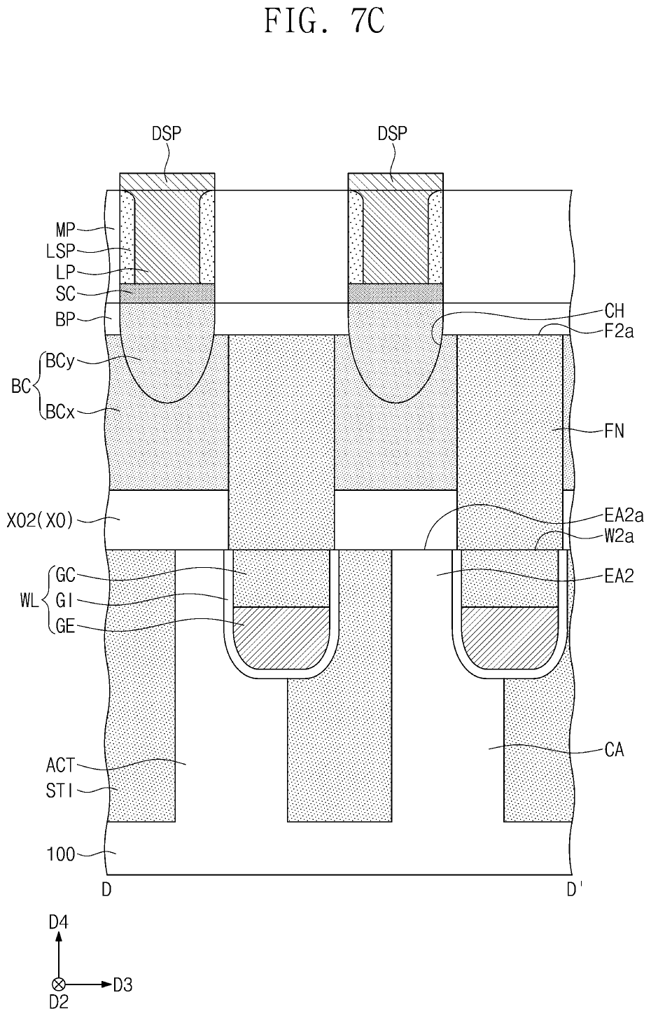

FIGS. 7A, 7B, and 7C illustrate cross-sectional views respectively taken along lines B-B′, C-C′, and D-D′ of FIG. 1A.

Referring to FIGS. 7A to 7C, the first top surface W1a and the second top surface W2a of the word line WL may have properties the same as or similar to those discussed with reference to FIGS. 6A to 6C.

The fence pattern FN may extend along the second direction D2 on the word line WL. The first active pads XO1 that neighbor each other in the third direction D3 may be spaced apart from each other across the fence pattern FN. The second active pads XO2 that neighbor each other in the third direction D3 may be spaced apart from each other across the fence pattern FN. The fence pattern FN may extend in the third direction D3 from a location between the second active pads XO2 that neighbor each other in the third direction D3 to a location between the lower storage node contacts BCx that neighbor each other in the third direction D3.

The fence pattern FN may have a first top surface Fla and a second top surface F2a that are located at different levels. The first top surface Fla and a bottom surface of the fence pattern FN may have properties the same as or similar to those of the first top surface Fx1a and the bottom surface of the lower fence pattern FNx discussed with reference to FIGS. 6A to 6C. The second top surface F2a of the fence pattern FN may be located at substantially the same level as that of the top surface of the lower storage node contact BCx.

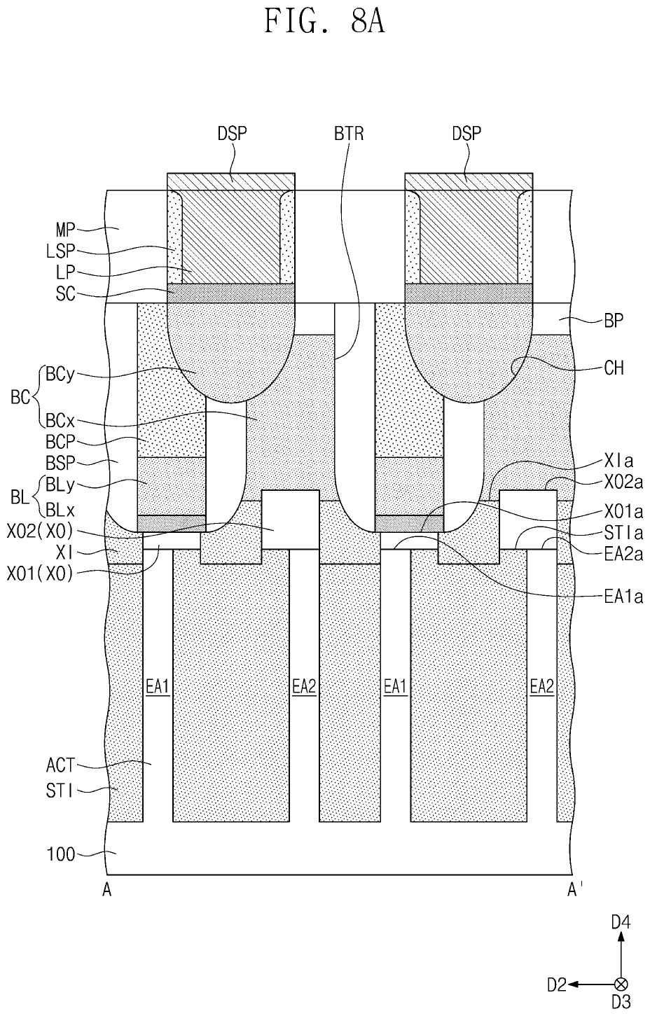

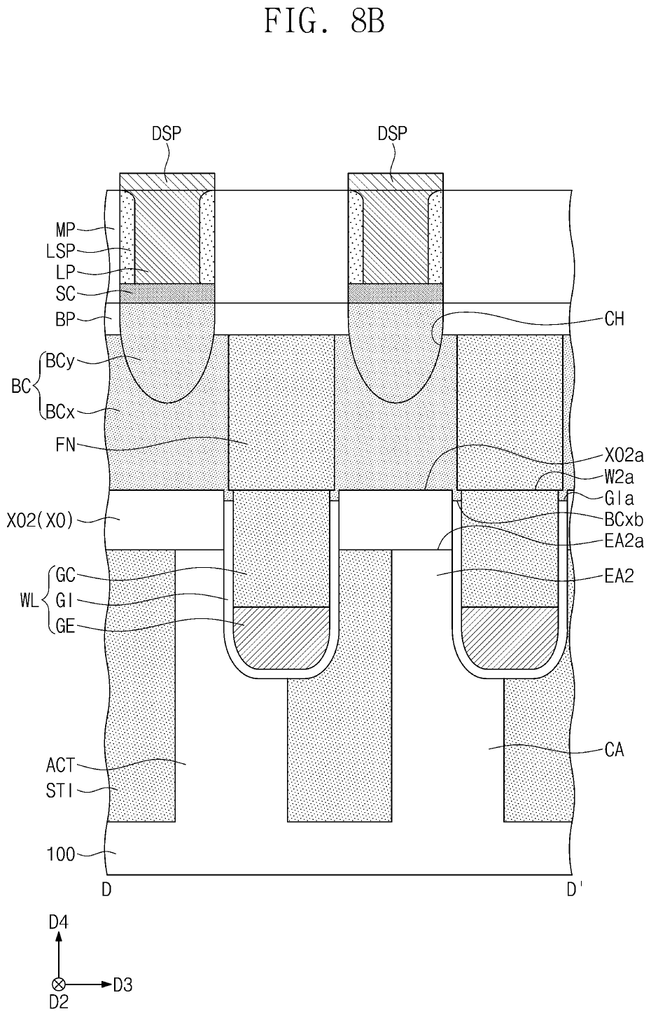

FIGS. 8A and 8B illustrate cross-sectional views respectively taken along lines A-A′ and D-D′ of FIG. 1A.

Referring to FIGS. 8A and 8B, the top surface XO2a of the second active pad XO2 may be located at a level higher than that of the top surface XIa of the active dielectric pattern XI. The top surface XO2a of the second active pad XO2 may be located at a level higher than that of a top surface GIa of the gate dielectric pattern GI.

The lower storage node contact BCx may have a bottom surface BCxb located at a level lower than that of the top surface XO2a of the second active pad XO2. The lower storage node contact BCx may cover or overlap an upper portion of the second active pad XO2. For example, the lower storage node contact BCx may completely cover or completely overlap the top surface XO2a and a lateral surface of the upper portion of the second active pad XO2. The lower storage node contact BCx may extend toward the gate dielectric pattern GI from a location between the second active pad XO2 and the gate capping pattern GC. There may thus be an increase in contact area between the second active pad XO2 and the lower storage node contact BCx. As a result, an easy electrical connection may be achieved between the lower storage node contact BCx and the second edge part EA2 of the active pattern ACT, and a semiconductor device may increase in electrical properties.

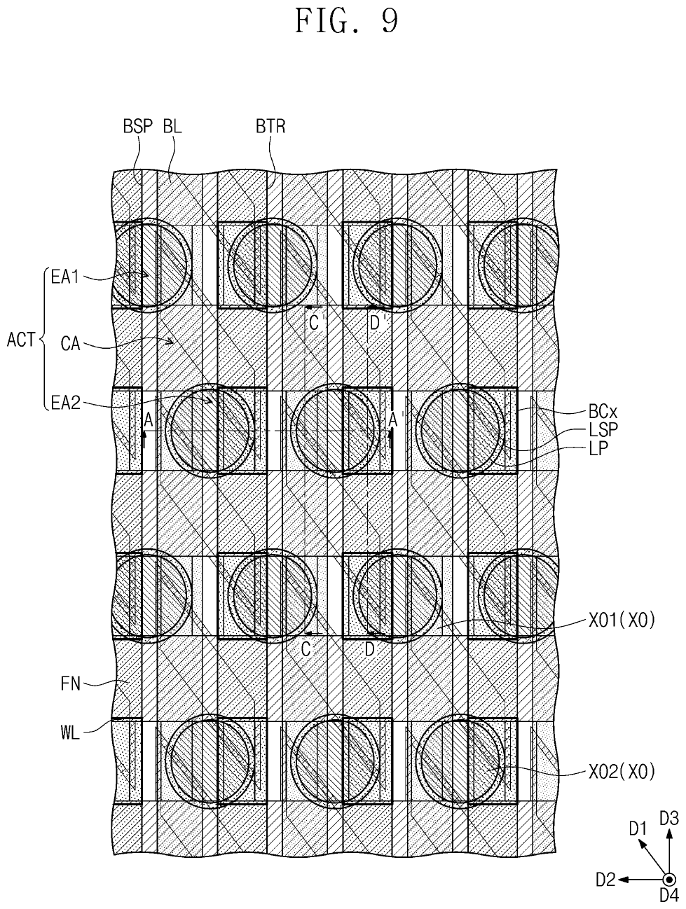

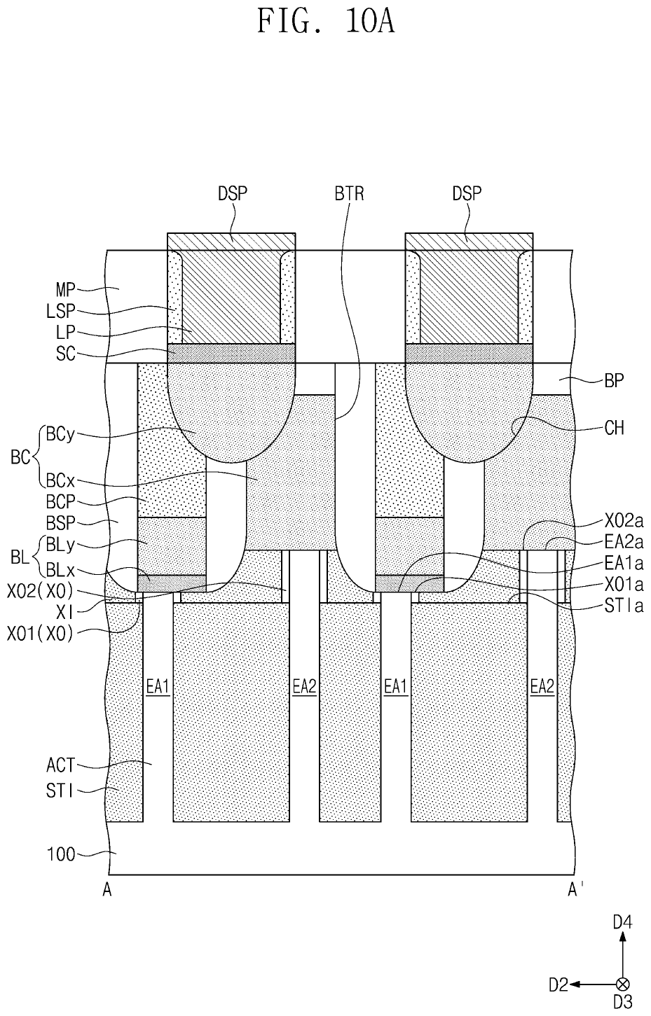

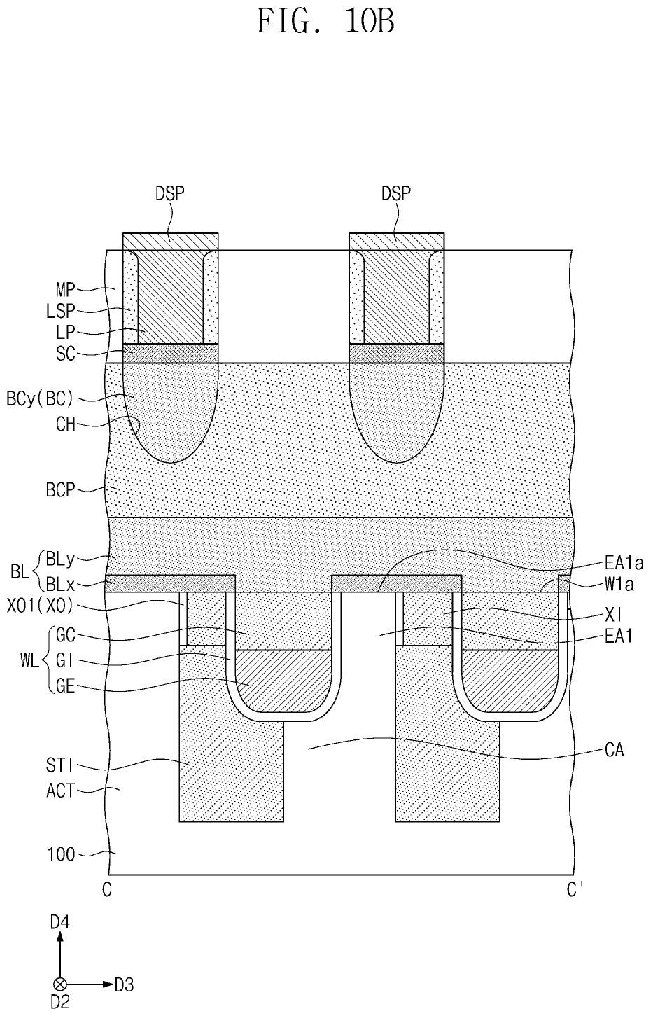

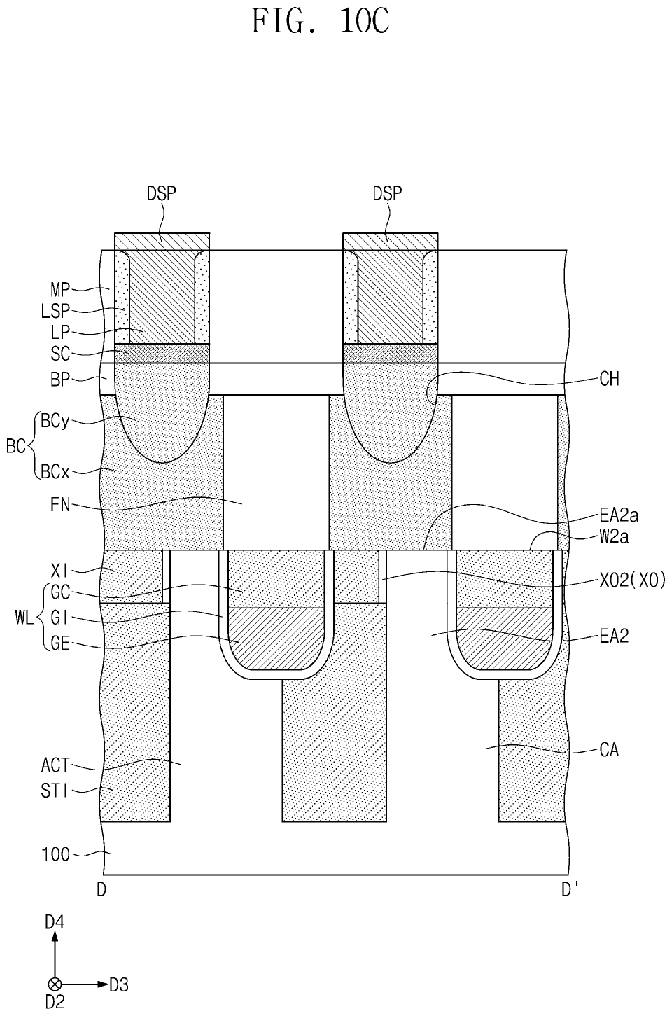

FIG. 9 illustrates a plan view showing a semiconductor device according to some embodiments of the present inventive concepts. FIGS. 10A, 10B, and 10C illustrate cross-sectional views respectively taken along lines A-A′, C-C′, and D-D′ of FIG. 9.

Referring to FIGS. 9 to 10C, the top surface EA1a of the first edge part EA1 of the active pattern ACT may be located at a level lower than that of the top surface EA2a of the second edge part EA2 of the active pattern ACT. The top surfaces EA1a and EA2a of the first and second edge parts EA1 and EA2 of the active pattern ACT may be located at a level higher than that of the uppermost surface STIa of the device isolation pattern STI.

The first active pad XO1 may surround and cover or overlap a lateral surface of the first edge part EA1 in plan view. The second active pad XO2 may surround and cover or overlap a lateral surface of the second edge part EA2 in plan view. The top surface XO1a of the first active pad XO1 may be located at a level substantially the same level as that of the top surface EA1a of the first edge part EA1 of the active pattern ACT and lower than that of the top surface EA2a of the second edge part EA2 of the active pattern ACT. The top surface XO2a of the second active pad XO2 may be located at substantially the same level as that of the top surface EA2a of the second edge part EA2 of the active pattern ACT.

The active dielectric pattern XI may be interposed between the first and second active pads XO1 and XO2. The active dielectric pattern XI may cover or overlap the uppermost surface STIa of the device isolation pattern STI. The active dielectric pattern XI may have a top surface located at substantially the same level as that of the top surface EA2a of the second edge part EA2 of the active pattern ACT.

The first top surface W1a of the word line WL may be located at substantially the same level as that of the top surface EA1a of the first edge part EA1 of the active pattern ACT. The second top surface W2a of the word line WL may be located at substantially the same level as that of the top surface EA2a of the second edge part EA2 of the active pattern ACT.

The bit line BL may be in contact with the first active pad XO1 and the first edge part EA1 of the active pattern ACT. The bit line BL may have a bottom surface located at a level lower than that of the top surface EA2a of the second edge part EA2 of the active pattern ACT.

The lower storage node contact BCx may be in contact with the second active pad XO2 and the second edge part EA2 of the active pattern ACT.

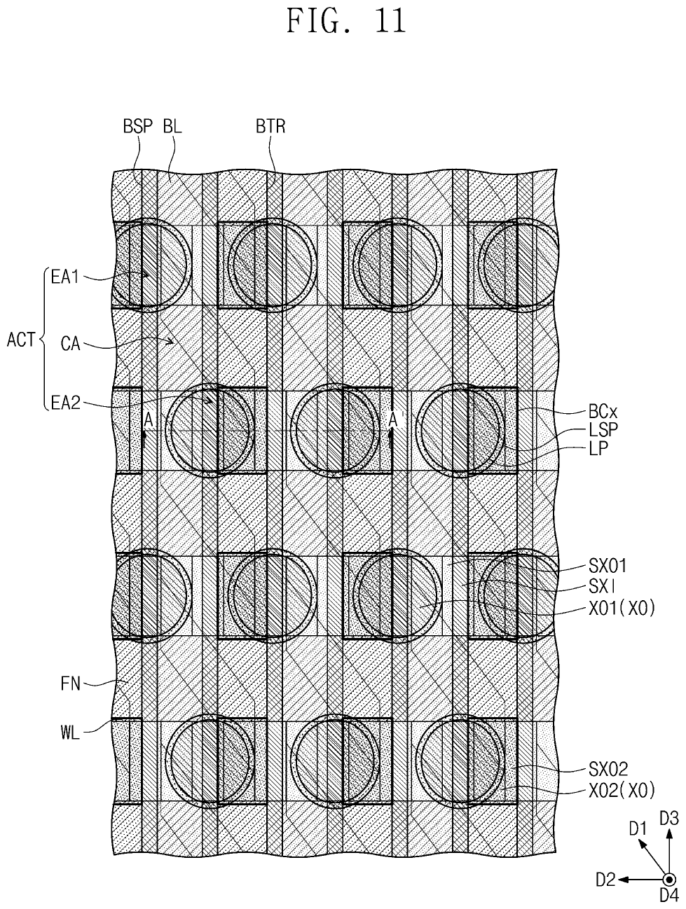

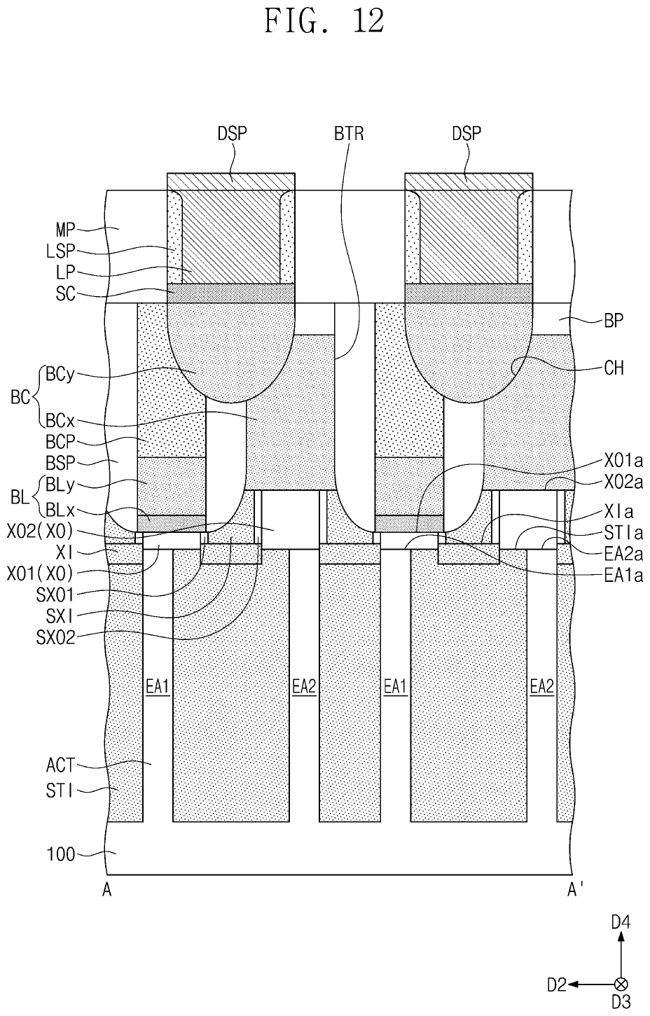

FIG. 11 illustrates a plan view showing a semiconductor device according to some embodiments of the present inventive concepts. FIG. 12 illustrates a cross-sectional view taken along line A-A′ of FIG. 11.

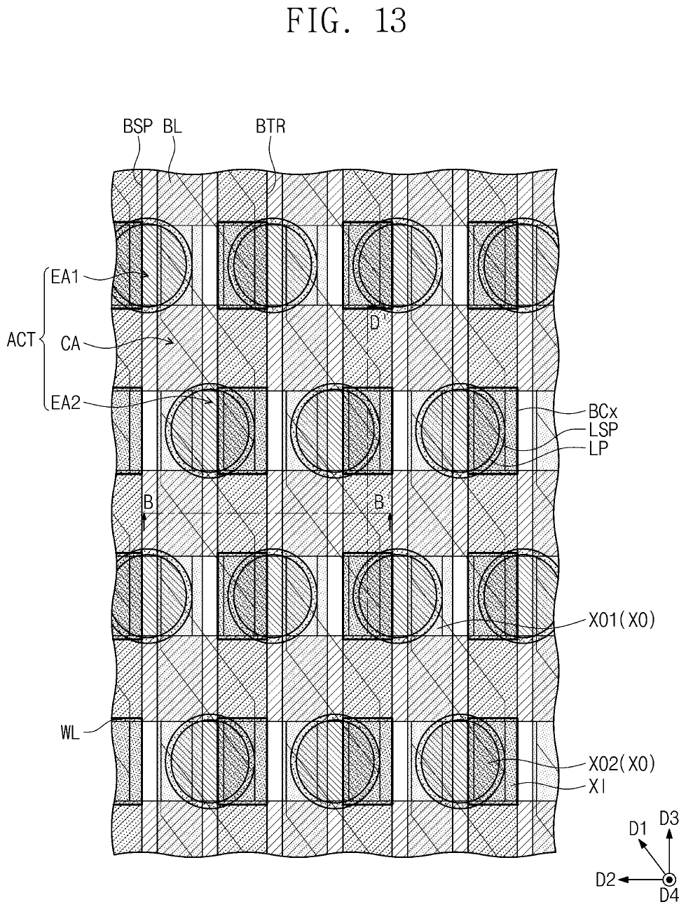

Referring to FIGS. 12 and 13, a first active additional pad SXO1 may be provided on a lateral surface of the first active pad XO1. The first active additional pad SXO1 may be provided on a top surface of the active dielectric pattern XI. The first active additional pad SXO1 may be provided in plural. Among the first active additional pads SXO1 that neighbor each other in the second direction D2, one may cover or overlap one lateral surface of the first active pad XO1, and another may cover or overlap another lateral surface of the first active pad XO1. The first active additional pads SXO1 that neighbor each other in the third direction D3 may be spaced apart from each other across the word line WL.

A second active additional pad SXO2 may be provided on a lateral surface of the second active pad XO2. The second active additional pad SXO2 may be provided on the top surface of the active dielectric pattern XI. The second active additional pad SXO2 may be provided in plural. Among a pair of second active additional pads SXO2 that neighbor each other in the second direction D2, one may cover or overlap one lateral surface of the second active pad XO2, and the other may cover or overlap another lateral surface of the second active pad XO2. The second active additional pads SXO2 that neighbor each other in the third direction D3 may be spaced apart from each other across the word line WL

The first and second active additional pads SXO1 and SXO2 may include the same material as that of the active pattern ACT. For example, the first and second active additional pads SXO1 and SXO2 may include at least one of silicon (e.g., monocrystalline silicon), germanium, and/or silicon-germanium.

The top surface XIa of the active dielectric pattern XI may be located at a level lower than that of the top surfaces XO1a and XO2a of the first and second active pads XO1 and XO2. The top surface XIa of the active dielectric pattern XI may be located at a level higher than that of the top surfaces EA1a and EA2a of the first and second edge parts EA1 and EA2, but the present inventive concepts are not limited thereto. Although not shown, the top surface XIa of the active dielectric pattern XI may be located at a level lower than that of the top surfaces EA1a and EA2a of the first and second edge parts EA1 and EA2.

An active additional dielectric pattern SXI may be provided on the active dielectric pattern XI. The active additional dielectric pattern SXI may be interposed between the first and second active additional pads SXO1 and SXO2. The active additional dielectric pattern SXI may include a dielectric material. For example, the active additional dielectric pattern SXI may include at least one of silicon oxide (SiO₂) and/or silicon nitride (SiN).

The bit line BL may be in contact with the first active additional pad SXO1. The bit line BL may have a bottom surface located at a level lower than that of a top surface of the second active additional pad SXO2. The bit line BL may be electrically connected through the first active pad XO1 and the first active additional pad SXO1 to the first edge part EA1 of the active pattern ACT.

The lower storage node contact BCx may be in contact with the second active additional pad SXO2. The active additional dielectric pattern SXI may separate the lower storage node contact BCx from the active dielectric pattern XI. The storage node contact BC may be electrically connected to the second active pad XO2 and the second active additional pad SXO2 to the second edge part EA2 of the active pattern ACT.

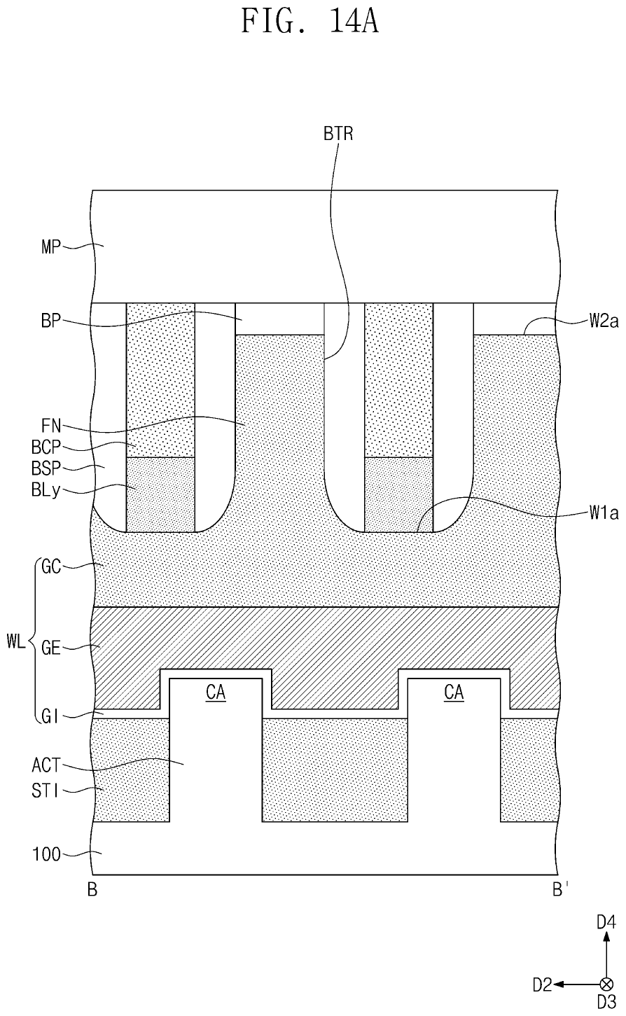

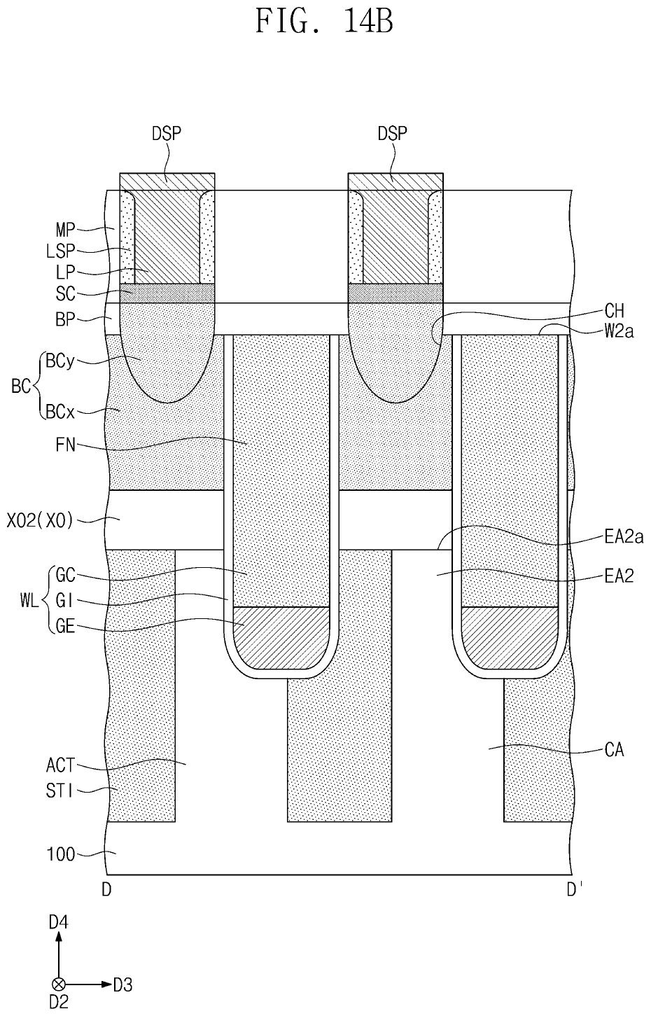

FIG. 13 illustrates a plan view showing a semiconductor device according to some embodiments of the present inventive concepts. FIGS. 14A and 14B illustrate cross-sectional views respectively taken along lines B-B′ and D-D′ of FIG. 13.

Referring to FIGS. 13 to 14B, the fence pattern FN may not be provided. The word line WL may extend in the third direction D3 between the second active pads XO2 that neighbor each other in the third direction D3, and may extend in the fourth direction D4 between neighboring lower storage node contacts BCx. The second top surface W2a of the word line WL may be located at substantially the same level as that of a top surface of the lower storage node contact BCx. The word line WL may be in contact with the buffer pattern BP. The bit-line trench regions BTR that neighbor each other in the second direction D2 may be spaced apart from each other across the word line WL. The lower storage node contacts BCx that neighbor each other in the third direction D3 may be spaced apart from each other across the word line WL.

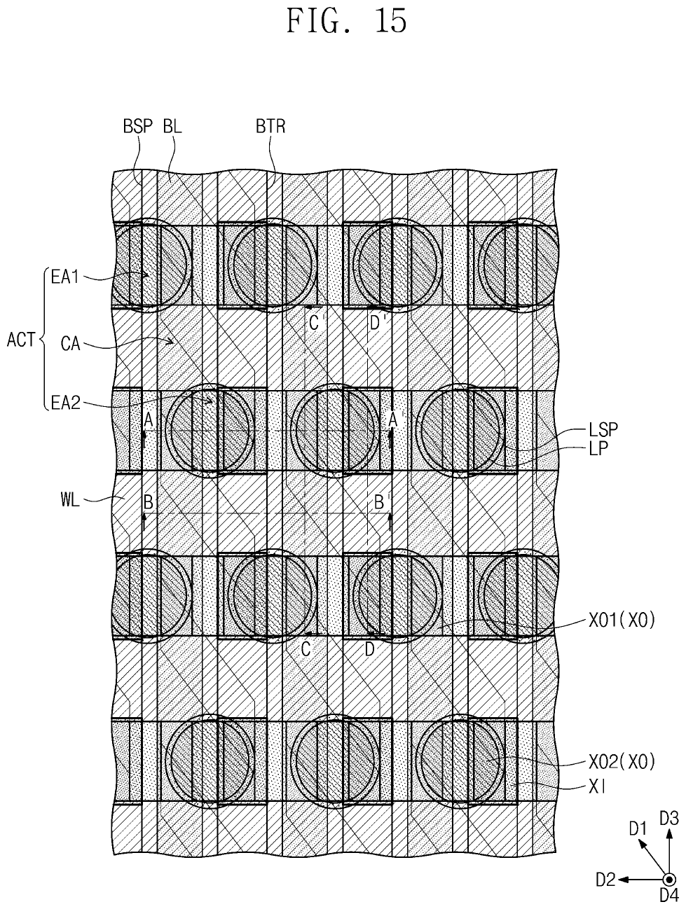

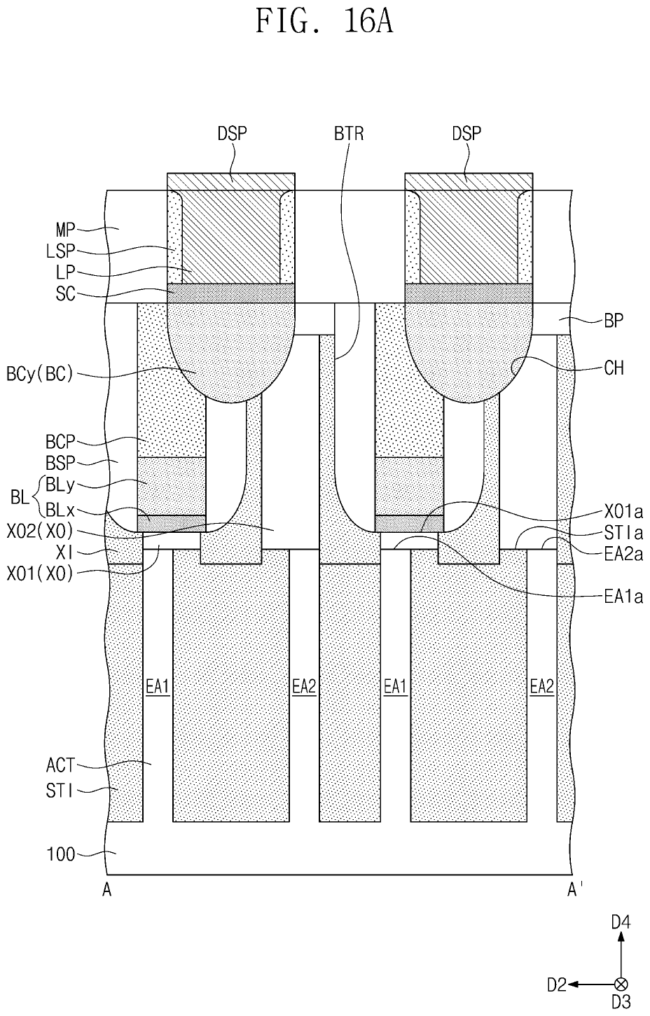

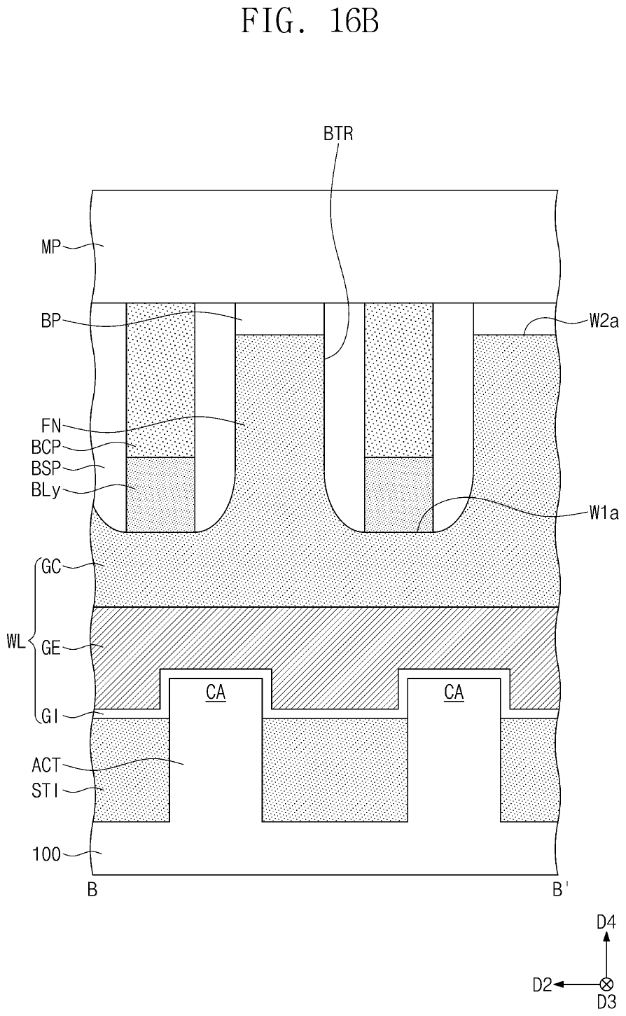

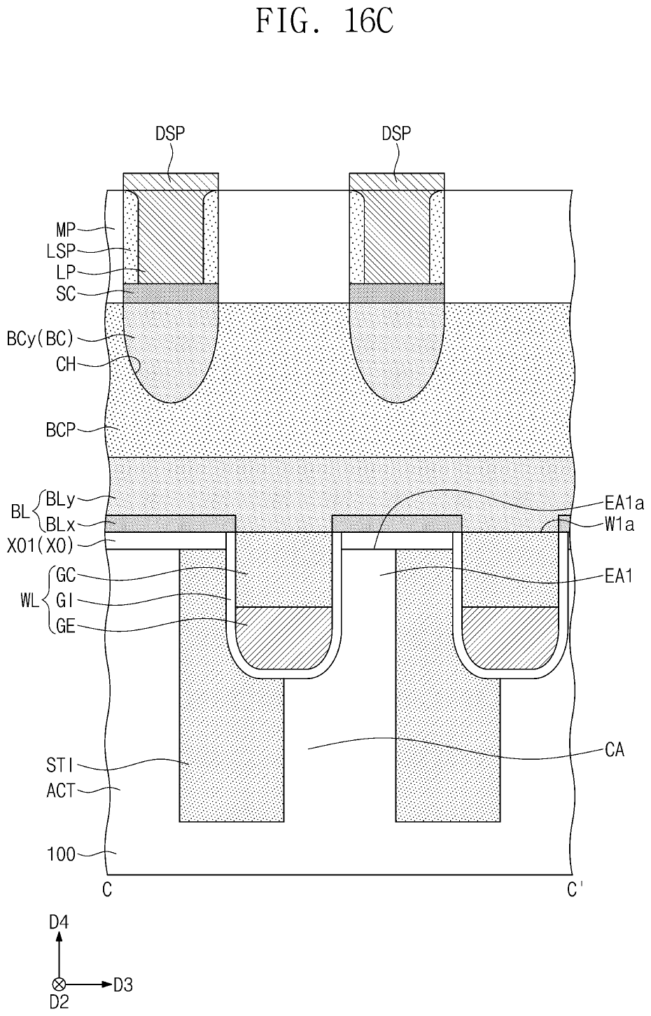

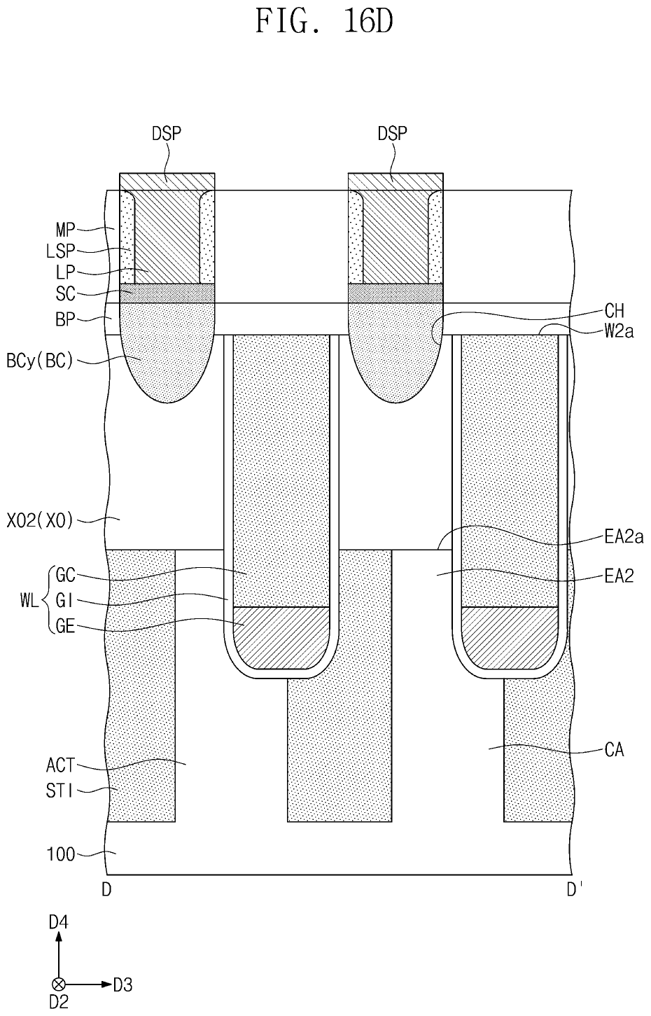

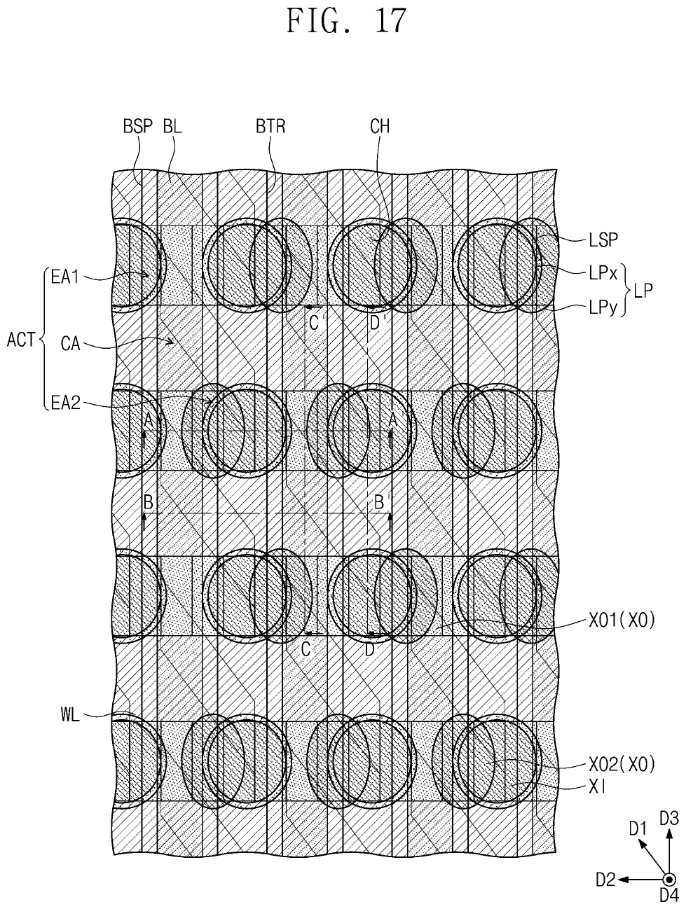

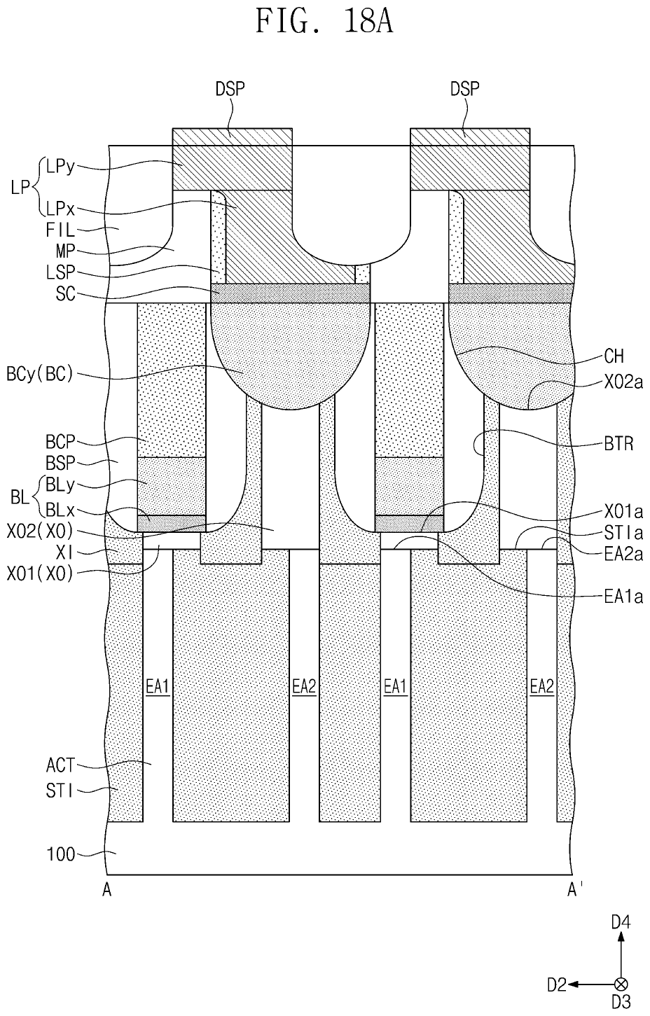

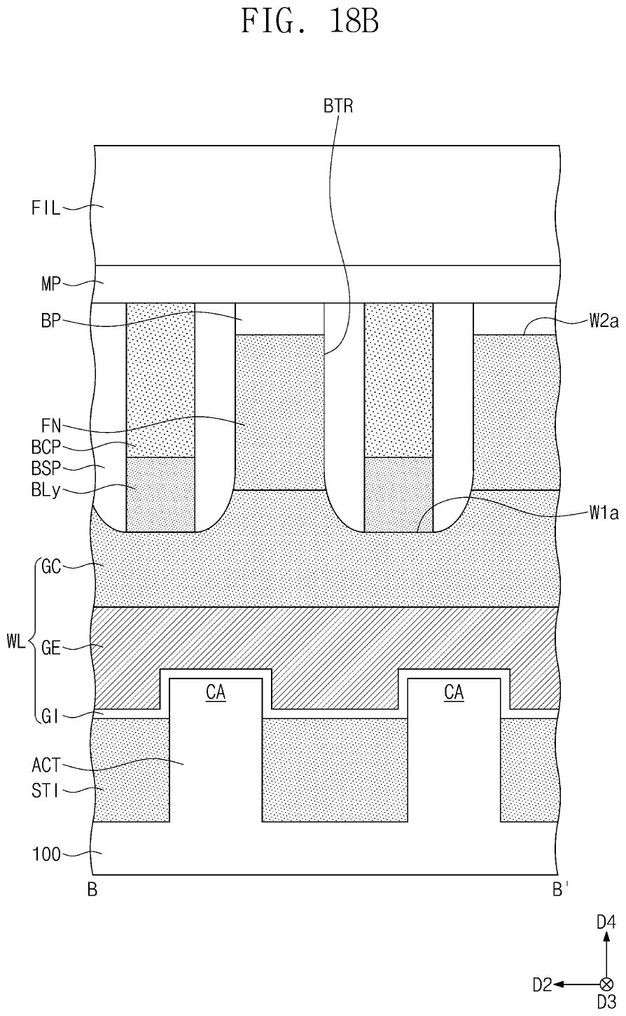

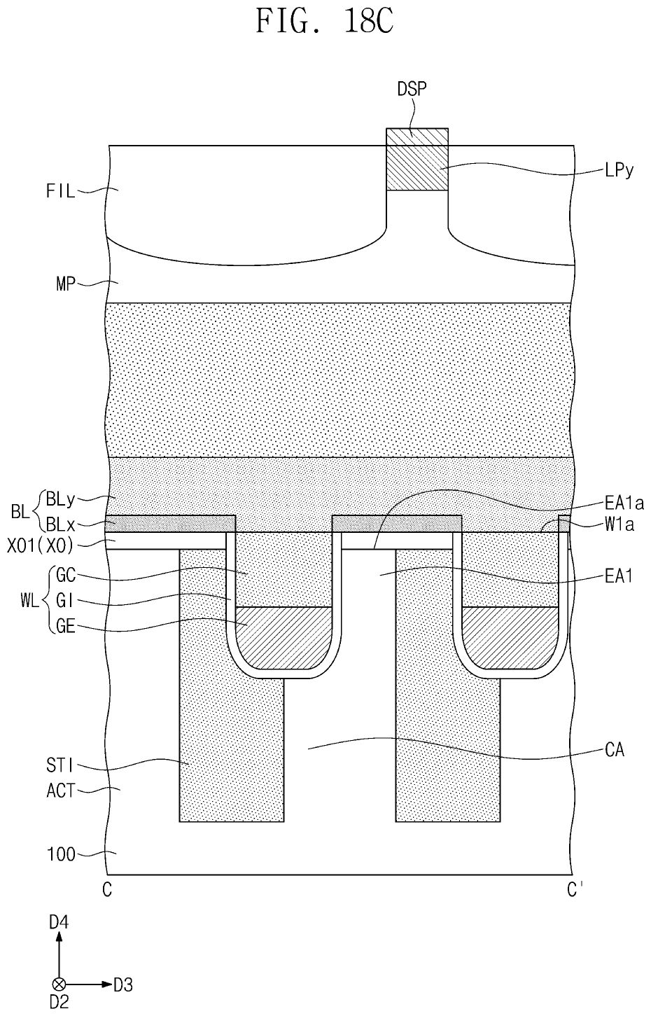

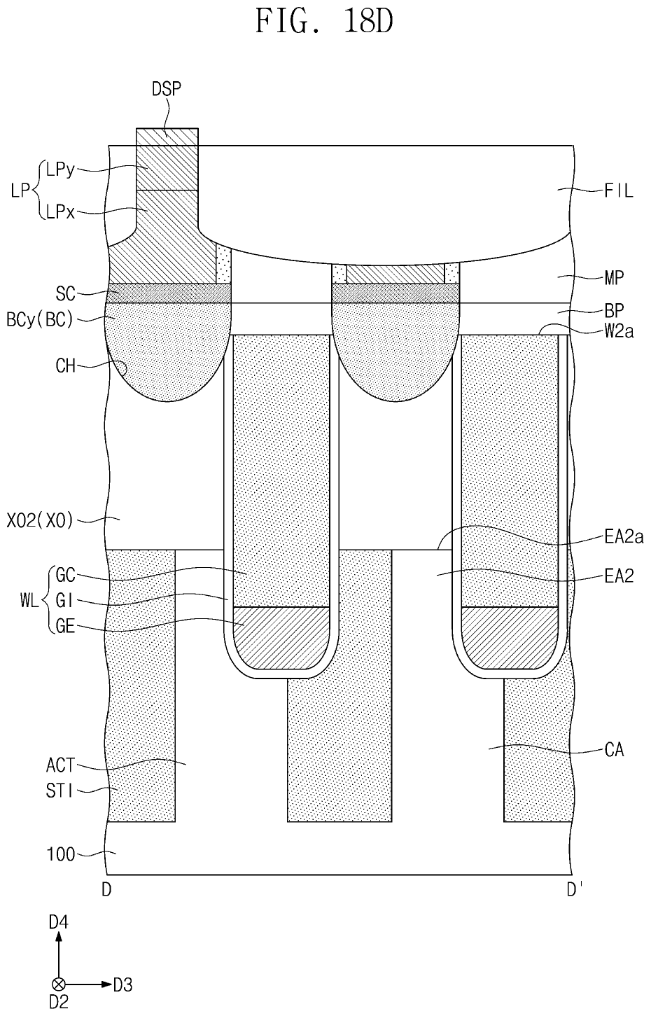

FIGS. 15 and 17 illustrate plan views showing a semiconductor device according to some embodiments of the present inventive concepts FIGS. 16A, 16B, 16C, and 16D illustrate cross-sectional views respectively taken along lines A-A′, B-B′, C-C′, and D-D′ of FIG. 15. FIGS. 18A, 18B, 18C, and 18D illustrate cross-sectional views respectively taken along lines A-A′, B-B′, C-C′, and D-D′ of FIG. 15.

Referring to FIGS. 15 to 18D, neither the fence pattern FN nor the lower storage node contact BCx may be provided.

The second active pad XO2 may be in contact with the upper storage node contact BCy and the buffer pattern BP. The top surface XO2a of the second active pad XO2 may be located at a level higher than that of the top surface of the bit line BL. The top surface XO2a of the second active pad XO2 may be located at a level higher than that of the lowermost surface of the upper storage node contact BCy.

The active dielectric pattern XI may be in contact with the upper storage node contact BCy.

The word line WL may be in contact with the buffer pattern BP. The second top surface W2a of the word line WL may be located at substantially the same as that of the top surface XO2a of the second active pad XO2.

Referring to FIGS. 17 to 18D, when viewed in plan, the contact hole CH may be interposed between the bit lines BL that neighbor each other in the second direction D2. The contact hole CH may vertically overlap the second active pad XO2. The contact holes CH may be two-dimensionally disposed along the second and third directions D2 and D3. For example, the contact holes CH in a certain queue may be disposed side by side along the second direction D2, and the contact holes CH in another queue may be disposed side by side along the third direction D3. Therefore, even when the contact holes CH are misaligned, an electrical connection between the second active pad XO2 and the upper storage node contact BCy may be easily achieved compared to the semiconductor device discussed with reference to FIGS. 15 to 16D.

When viewed in plan, the upper storage node contact BCy, the second silicide pattern SC, a subsequently described lower landing pad LPx, and the landing pad spacer LSP may be interposed between the bit lines BL that neighbor each other in the second direction D2.

The landing pad LP may include a lower landing pad LPx and an upper landing pad LPy. The lower landing pad LPx may have properties the same as or similar to those of the landing pad LP discussed with reference to FIGS. 1A to 2D. The upper landing pad LPy may be provided on the lower landing pad LPx and the mold pattern MP. The upper landing pad LPy may be shifted in the second direction D2 (or its opposite direction) from the lower landing pad LPx. A portion of the upper landing pad LPy may vertically overlap the bit line BL. The upper landing pad LPy may be provided in plural. The upper landing pads LPy may be disposed linearly in the second direction D2 and arranged in a zigzag fashion in the third direction D3. The lower landing pad LPx and the upper landing pad LPy may include the same or different materials. This, however, is not limited thereto, and a structure and material of the landing pad LP may be variously changed within a range known by a person in the skilled art.

A filling pattern FIL may surround the upper landing pad LPy. The filling pattern FIL may be interposed between neighboring upper landing pads LPy. When viewed in plan, the filling pattern FIL may have a mesh shape including holes, and the upper landing pads LPy may partially or fully fill the holes. The filling pattern FIL may penetrate the upper landing pad LPy. For example, the filling pattern FIL may include at least one of silicon nitride (SiN), silicon oxide (SiO₂), and/or silicon oxynitride (SiON). In some embodiments, the filling pattern FIL may include an empty space (or air gap) including an air layer.

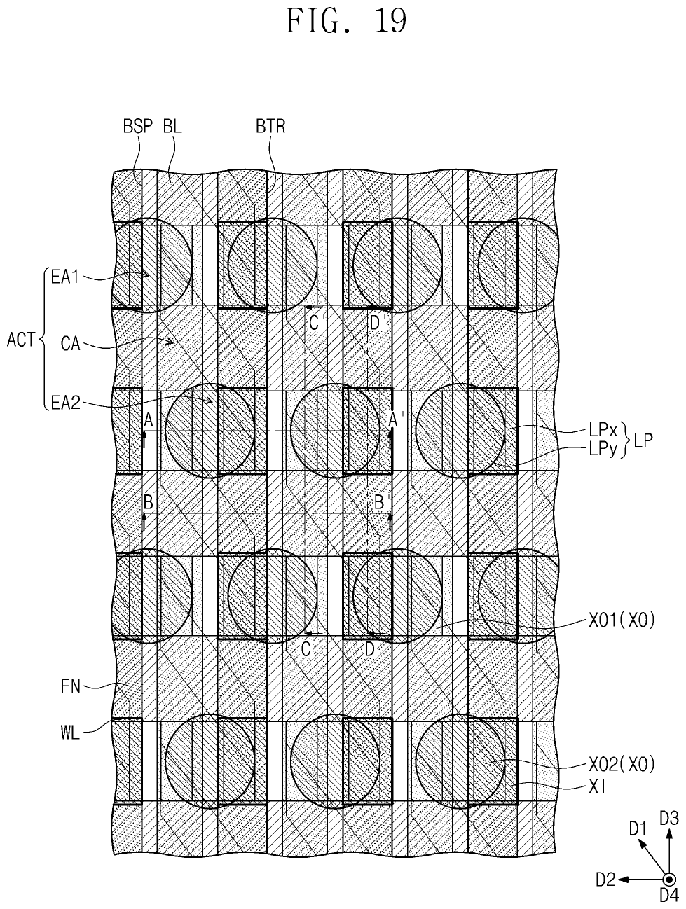

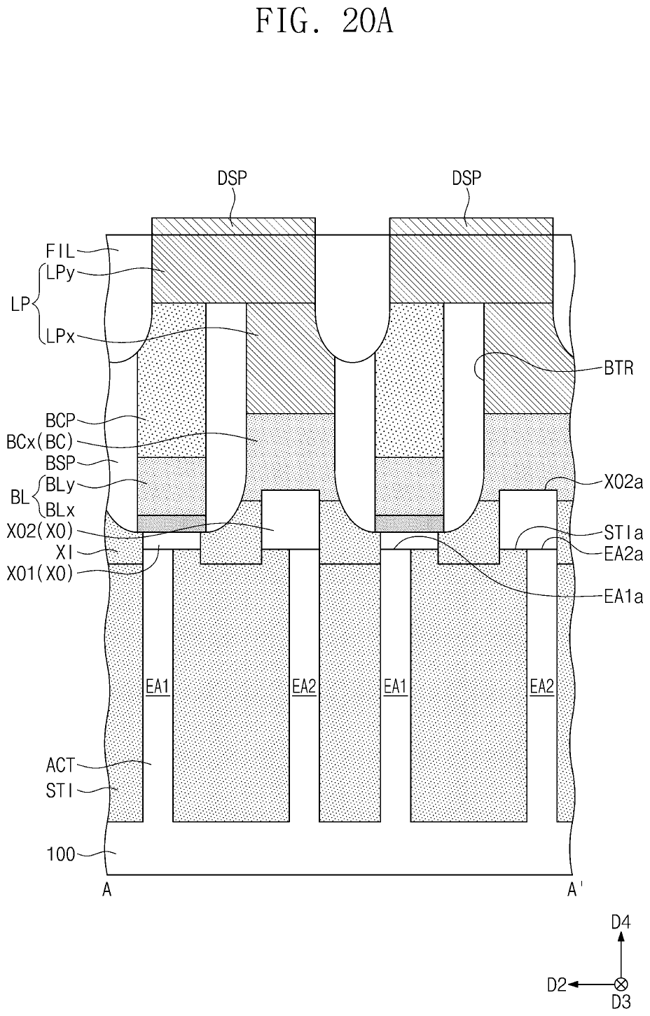

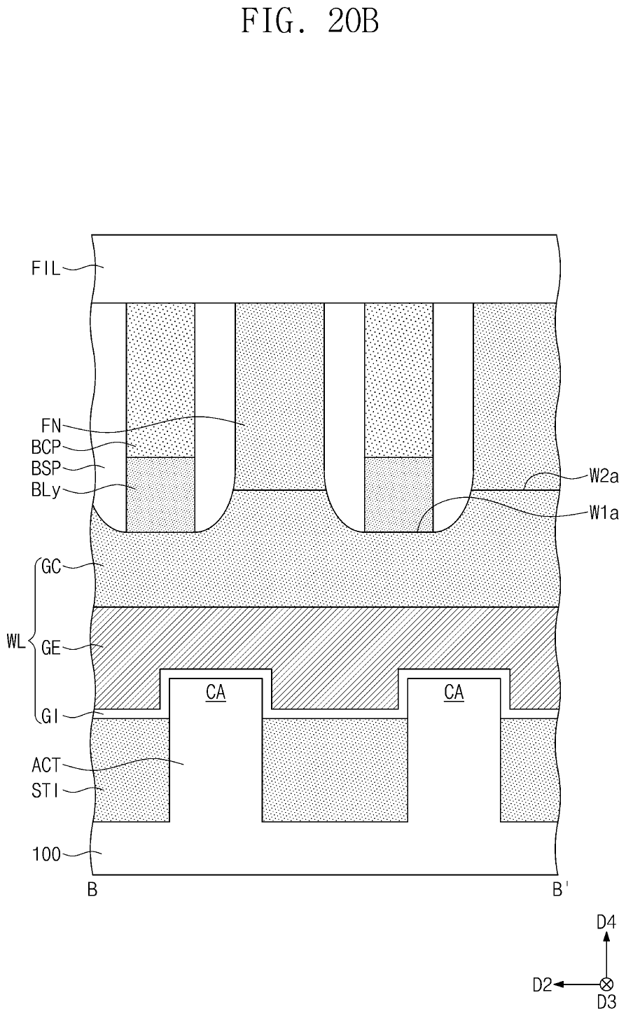

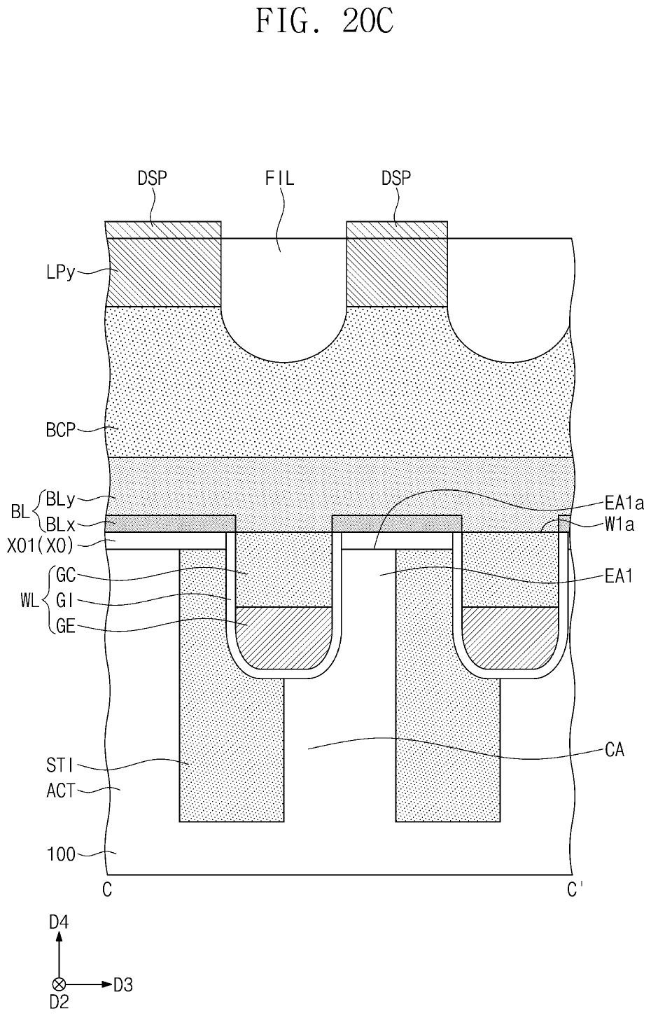

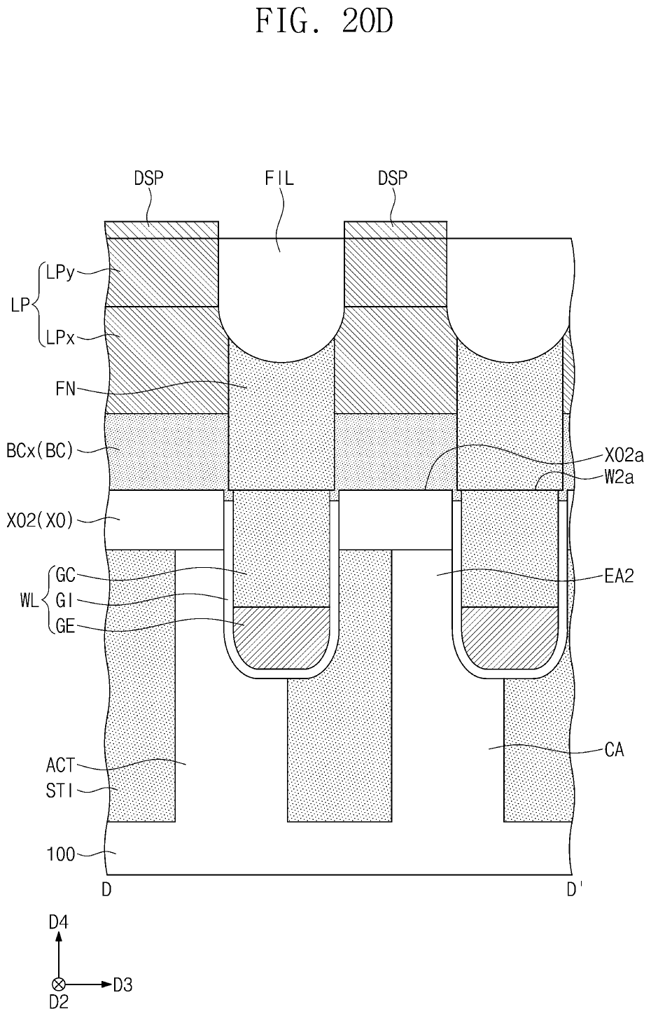

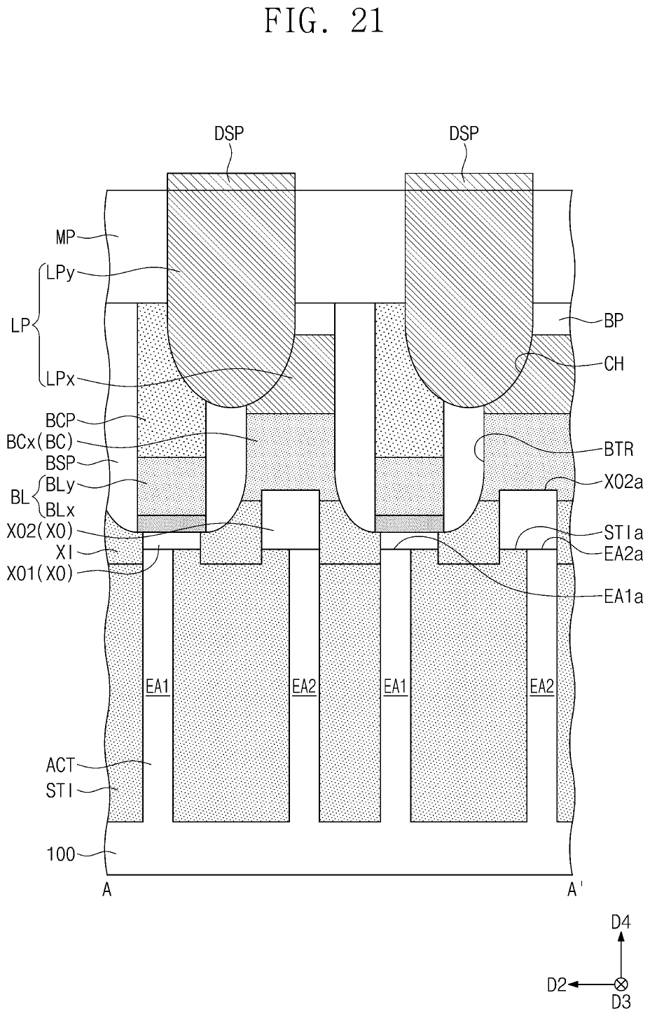

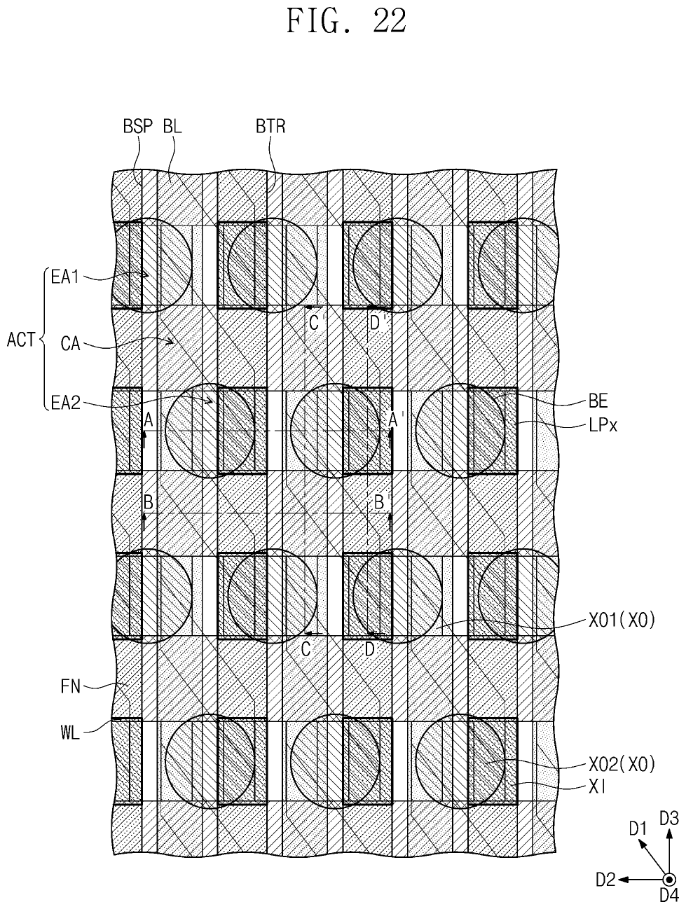

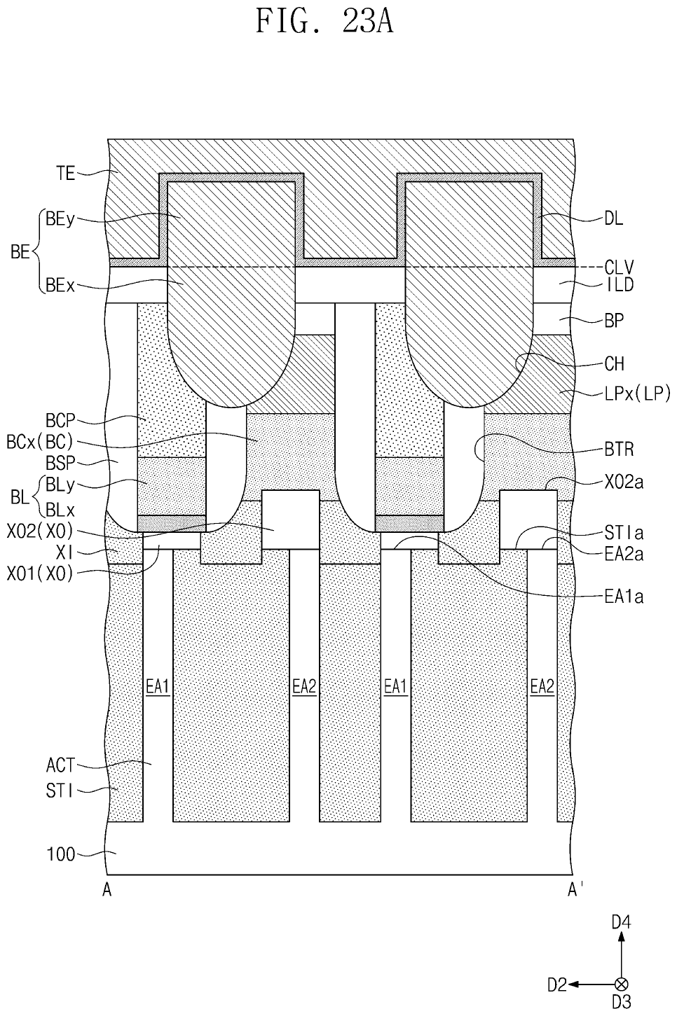

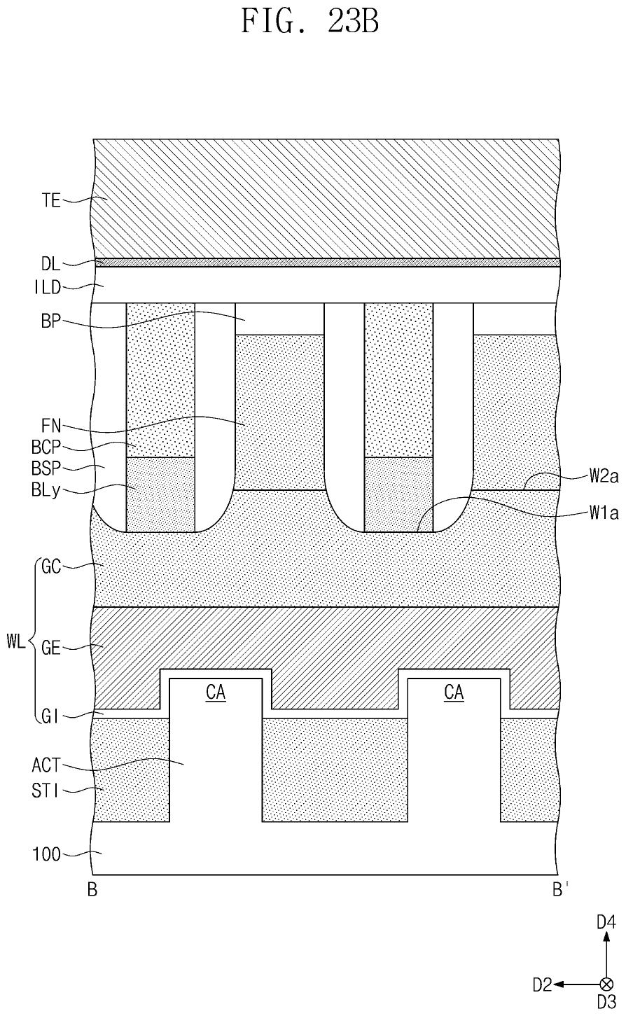

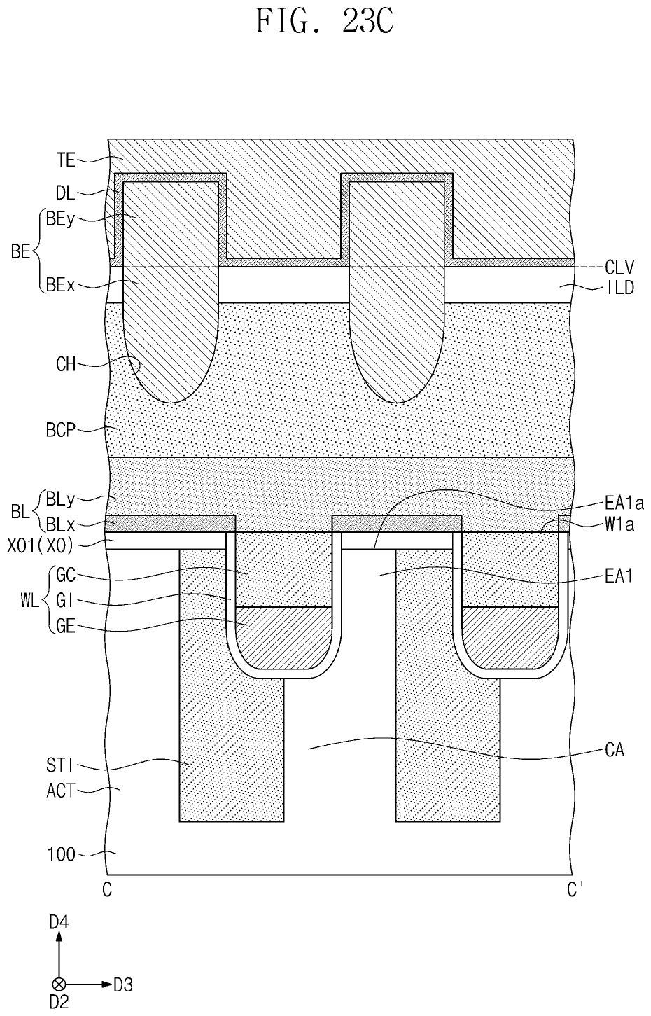

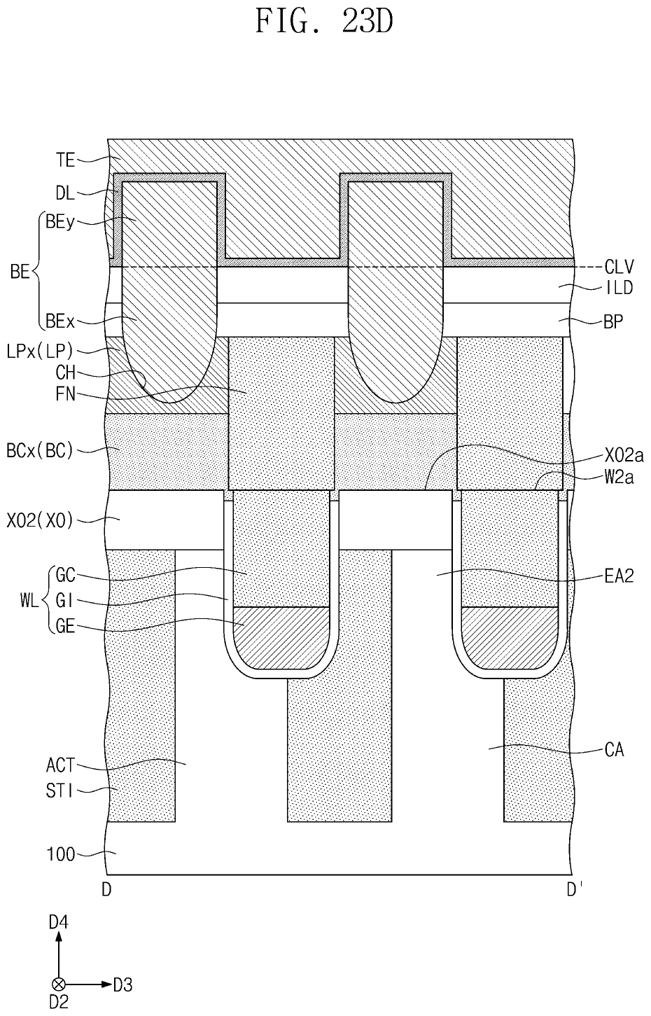

FIGS. 19 and 22 illustrate plan views showing a semiconductor device according to some embodiments of the present inventive concepts. FIGS. 20A, 20B, 20C, and 20D illustrate cross-sectional views respectively taken along lines A-A′, B-B′, C-C′, and D-D′ of FIG. 19. FIG. 21 illustrates a cross-sectional view taken along line A-A′ of FIG. 19. FIGS. 23A, 23B, 23C, and 23D illustrate cross-sectional views respectively taken along lines A-A′, B-B′, C-C′, and D-D′ of FIG. 22.

Referring to FIGS. 19 to 23D, the second active pad XO2 and the lower storage node contact BCx may have properties the same as or similar to those discussed with reference to FIGS. 8A and 8B.

The lower landing pad LPx may be provided on the lower storage node contact BCx. For example, the lower landing pad LPx may be in contact with the top surface of the lower storage node contact BCx. The lower landing pad LPx may be interposed between the bit-line capping patterns BCP that neighbor each other in the second direction D2. The lower landing pad LPx may be interposed between the fence patterns FN that neighbor each other in the third direction D3.

The lower landing pad LPx may be provided in plural. The plurality of lower landing pads LPx may be spaced apart from each other in the second and third directions D2 and D3. The lower landing pads LPx that neighbor each other in the second direction D2 may be spaced apart from each other across the bit-line capping pattern BCP. The lower landing pads LPx that neighbor each other in the third direction D3 may be spaced apart from each other across the fence pattern FN.

Referring to FIGS. 20A to 20D, the lower landing pad LPx may have a top surface located at substantially the same as that of the top surface of the bit-line capping pattern BCP. Referring to FIGS. 21 and 23A to 23D, the lower landing pad LPx may have a top surface located at a level lower than that of the top surface of the bit-line capping pattern BCP.

None of the upper storage node contact BCy, the second silicide pattern SC, and the landing pad spacer LSP may be provided, in some embodiments.

Referring to FIGS. 19 to 20D, the mold pattern MP may not be provided. The upper landing pad LPy may be provided on the lower landing pad LPx. The upper landing pad LPy may be in contact with the bit-line capping pattern BCP, the bit-line spacer BSP, and the lower landing pad LPx. The upper landing pad LPy and the filling pattern FIL may have properties the same as or similar to those discussed with reference to FIGS. 17 to 18D.

Referring to FIG. 21, the lower landing pad LPx may be interposed between the buffer pattern BP and the lower storage node contact BCx.

The upper landing pad LPy may be provided in the contact hole CH. For example, the upper landing pad LPy may partially or fully fill the contact hole CH. The upper landing pad LPy may be in contact with the bit-line capping pattern BCP and the bit-line spacer BSP. At a level lower than that of a bottom surface of the mold pattern MP, the upper landing pad LPy may be in contact with the lower landing pad LPx. The upper landing pad LPy may have a top surface located at substantially the same as that of a top surface of the mold pattern MP. The upper landing pad LPy may have a lowermost surface located at a level lower than that of a top surface of the lower landing pad LPx.

Referring to FIGS. 22 to 23D, the mold pattern MP may not be provided. An interlayer dielectric layer ILD may be provided on a front surface of the substrate 100. For example, the interlayer dielectric layer ILD may be provided on the bit-line capping pattern BCP and the buffer pattern BP. The interlayer dielectric layer ILD may include at least one of silicon nitride, silicon oxide, and/or silicon oxynitride. In some embodiments, the interlayer dielectric layer ILD may include an empty region. The contact holes CH may penetrate the interlayer dielectric layer ILD, and when viewed in plan, the interlayer dielectric layer ILD may have a mesh shape including the contact holes CH.

A bottom electrode BE may be provided on the lower landing pad LPx. The bottom electrode BE may include a lower part BEx below a contact level CLV and an upper part BEy above the contact level CLV. The contact level CLV may be defined to indicate a level at which a top surface of the interlayer dielectric layer ILD is located. For example, the lower part BEx and the upper part BEy of the bottom electrode BE may be distinguished from each other without their interface and in contact with each other, but the present inventive concepts are not limited thereto.

The lower part BEx of the bottom electrode BE may be provided in the contact hole CH. The lower part BEx of the bottom electrode BE may partially or fully fill the contact hole CH. The lower part BEx of the bottom electrode BE may be in contact with the bit-line capping pattern BCP, the bit-line spacer BSP, and the lower landing pad LPx. The lower part BEx of the bottom electrode BE may have a lowermost surface located at a level lower than that of a top surface of the lower landing pad LPx.

The upper part BEy of the bottom electrode BE may be provide don the lower part BEx of the bottom surface BE. The upper part BEy of the bottom electrode BE may have a pillar shape. In some embodiments, the upper part BEy of the bottom electrode BE may have a hollow cylindrical shape whose one end is closed. According to some embodiments, although not shown, the upper part BEy of the bottom electrode BE may have a pillar-shaped lower portion and a hollow cylinder-shaped upper portion.

The bottom electrode BE may be provided in plural. The bottom electrodes BE may be spaced apart from each other in the second and third directions D2 and D3. When viewed in plan, the bottom electrodes BE may be arranged to have a honeycomb shape. For example, six bottom electrodes BE may be disposed to constitute or form a hexagon that surrounds one bottom electrode BE located at the center of the hexagon.

A top electrode TE may be provided on the bottom electrode BE. For example, the top electrode TE may cover or overlap a top surface of the upper part BEy of the bottom electrode BE, and may surround and cover or overlap a lateral surface of the upper part BEy of the bottom electrode BE. The top electrode TE may partially or fully fill a space between the upper part BEy of the bottom electrodes BE.

Each of the bottom electrode BE and the top electrode TE may include a conductive material. For example, each of the bottom electrode BE and the top electrode TE may include at least one of impurity-doped silicon (Si), impurity-doped silicon-germanium (SiGe), metallic materials (e.g., Ti, Mo, W, Cu, Al, Ta, Ru, Ir, Co, Pt, Au, and/or Ag), metal nitride (e.g., nitride of one or more of Ti, Mo, W, Cu, Al, Ta, Ru, Ir, Co, Pt, Au, and/or Ag), titanium silicon nitride (e.g., TiSiN), titanium aluminum nitride (e.g., TiAlN), tantalum aluminum nitride (e.g., TaAlN), conductive oxides (e.g., PtO, RuO₂, IrO₂, SRO(SrRuO₃), BSRO((Ba,Sr) RuO₃), CRO(CaRuO₃), and/or LSCo), and/or metal silicide. Each of the bottom electrode BE and the top electrode TE may be a single layer formed of one material or a multiple layer formed of two or more materials.

A dielectric layer DL may be interposed between the top electrode TE and each of the upper parts BEy of the bottom electrodes BE and between the top electrode TE and the interlayer dielectric layer ILD. The dielectric layer DL may conformally cover or overlap the upper parts BEy of the bottom electrodes BE. For example, the dielectric layer DL may include at least one metal oxide, such as HfO₂, ZrO₂, Al₂O₃, La₂O₃, Ta₂O₃, and TiO₂, and/or perovskite dielectric materials, such as SrTiO₃(STO), (Ba,Sr)TiO₃(BST), BaTiO₃, PZT, and/or PLZT.

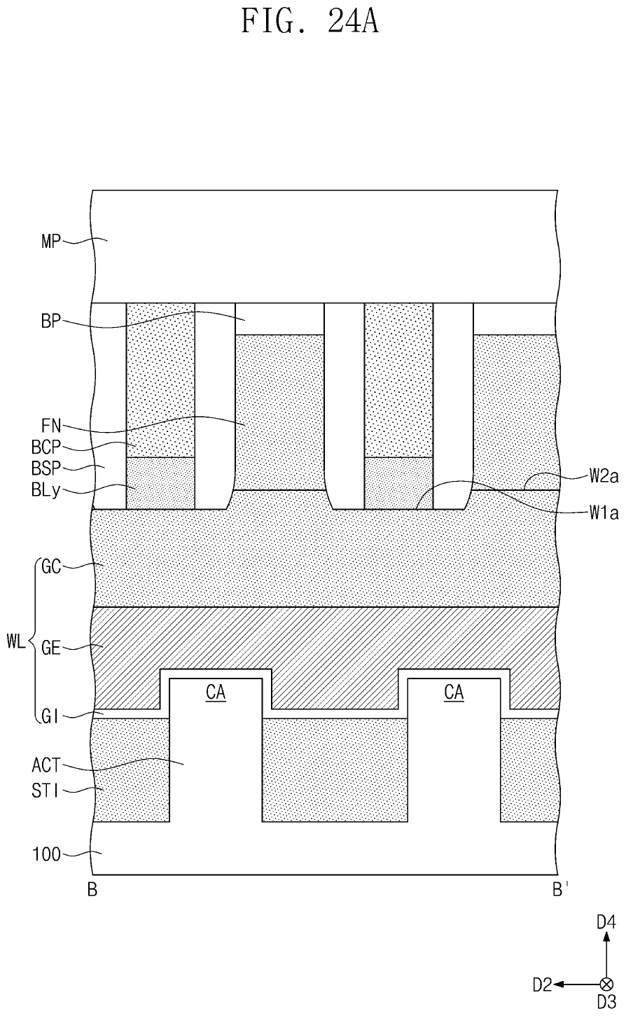

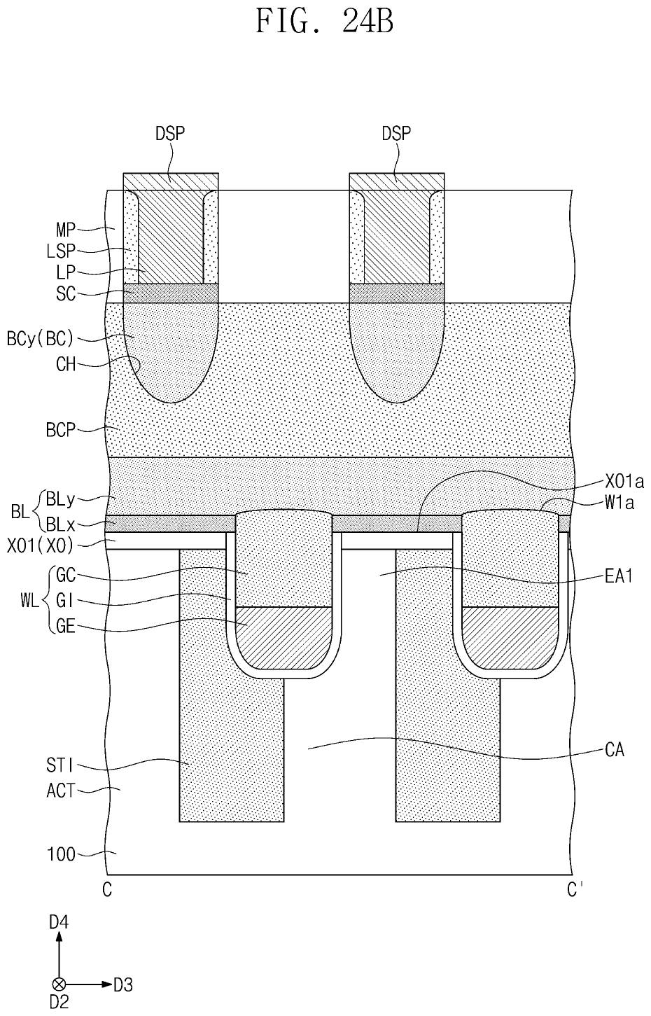

FIGS. 24A and 24B illustrate cross-sectional views respectively taken along lines B-B′ and C-C′ of FIG. 1.

Referring to FIGS. 24A and 24B, the first top surface W1a of the word line WL may be located at a level higher than that of the top surface XO1a of the first active pad XO1. The first top surface W1a of the word line WL may be located at a level higher than that of a top surface of the lower bit line BLx. Therefore, the upper bit line BLy and the gate electrode GE may have an increased spacing distance and a reduced electrical interference. As a result, a semiconductor device may have increased electrical properties.

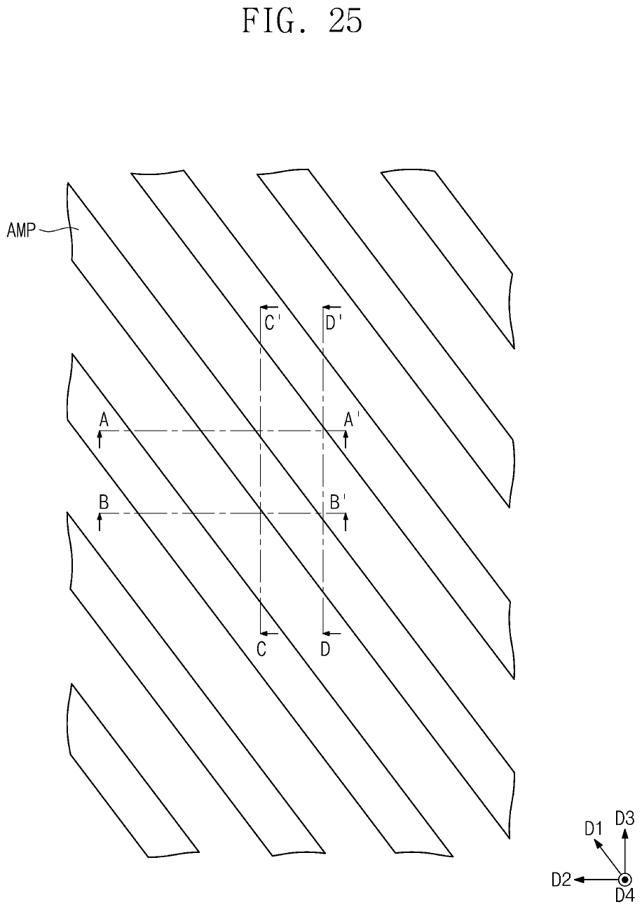

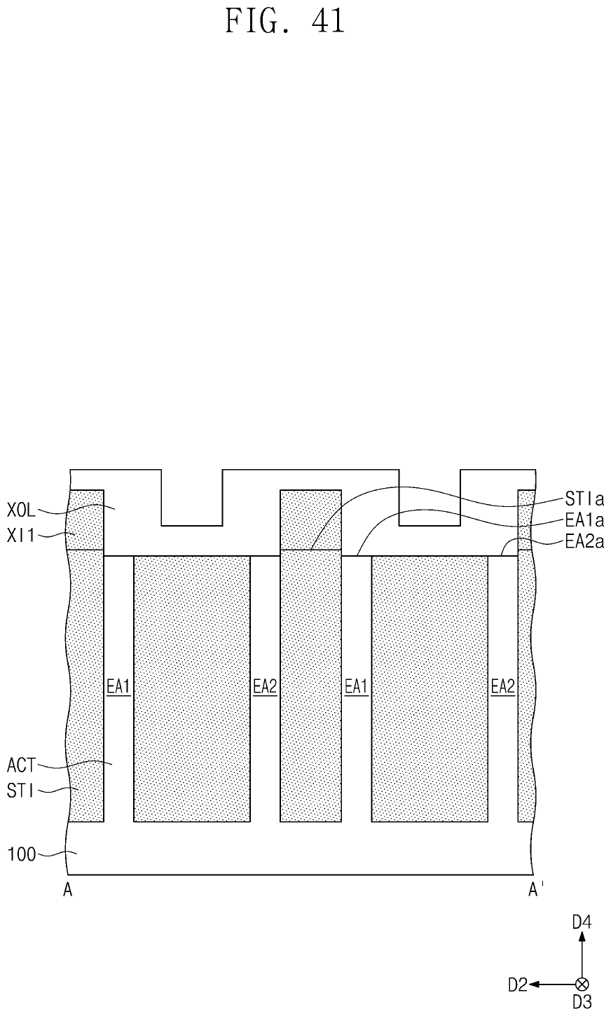

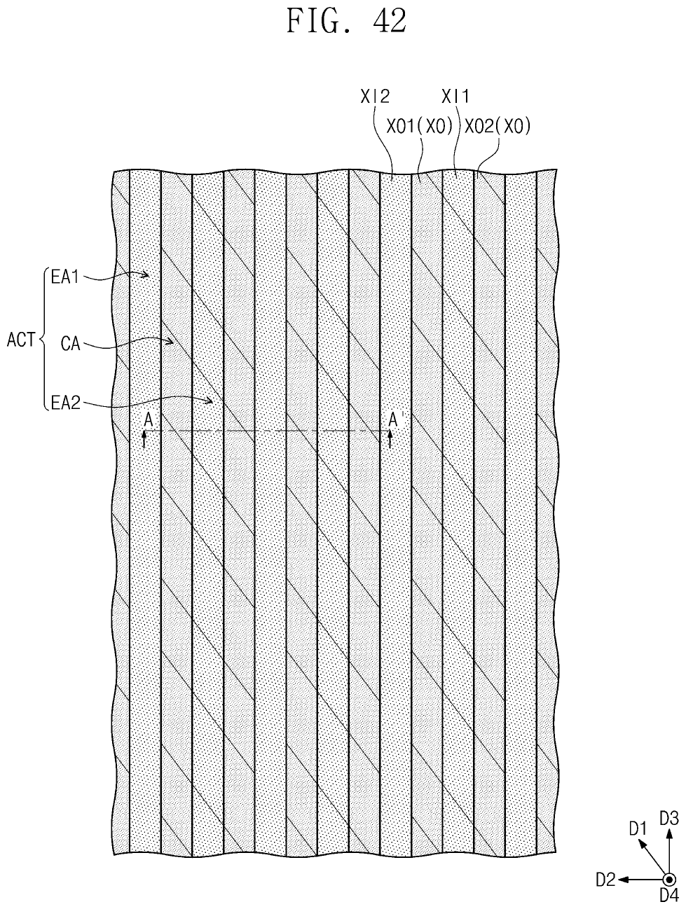

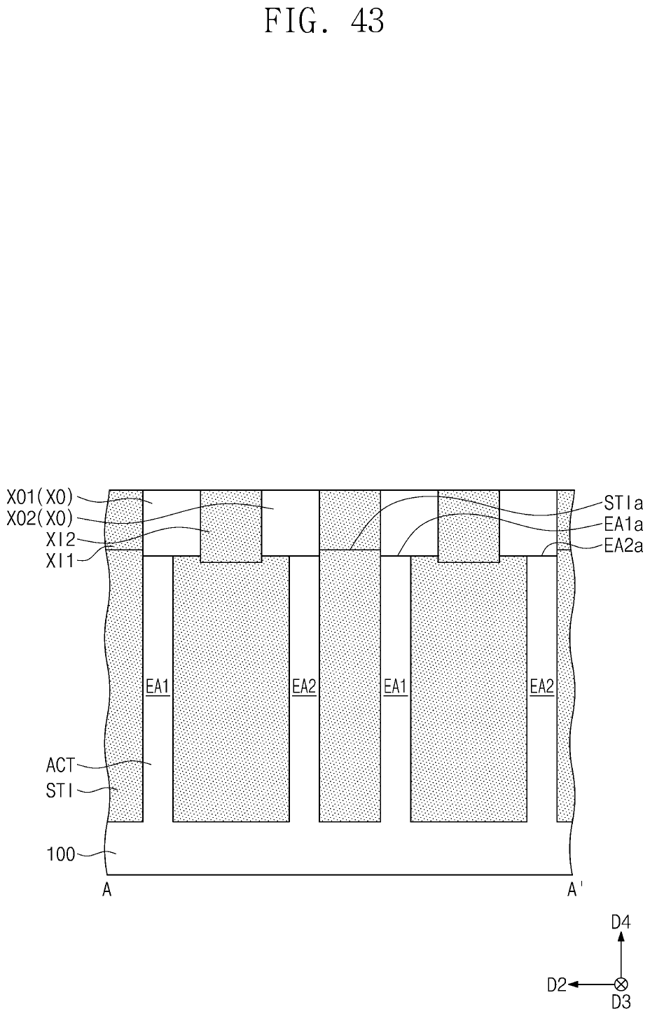

With reference to FIGS. 25 to 69B, the following will describe in detail a method of fabricating a semiconductor device according to some embodiments of the present inventive concepts. For brevity of description, an explanation of components repetitive to those discussed above will be omitted, and a difference thereof will be discussed in detail.

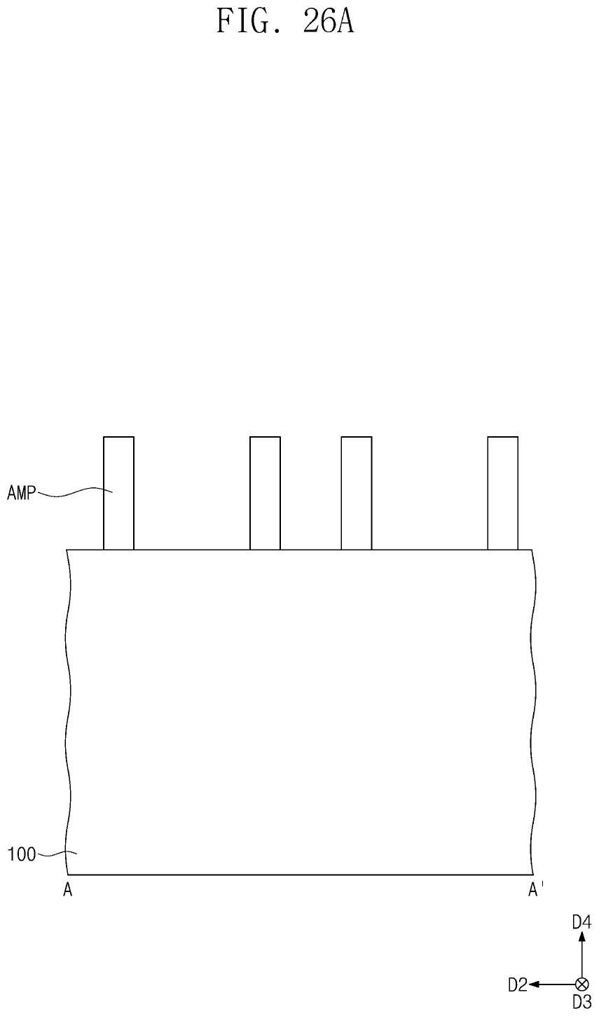

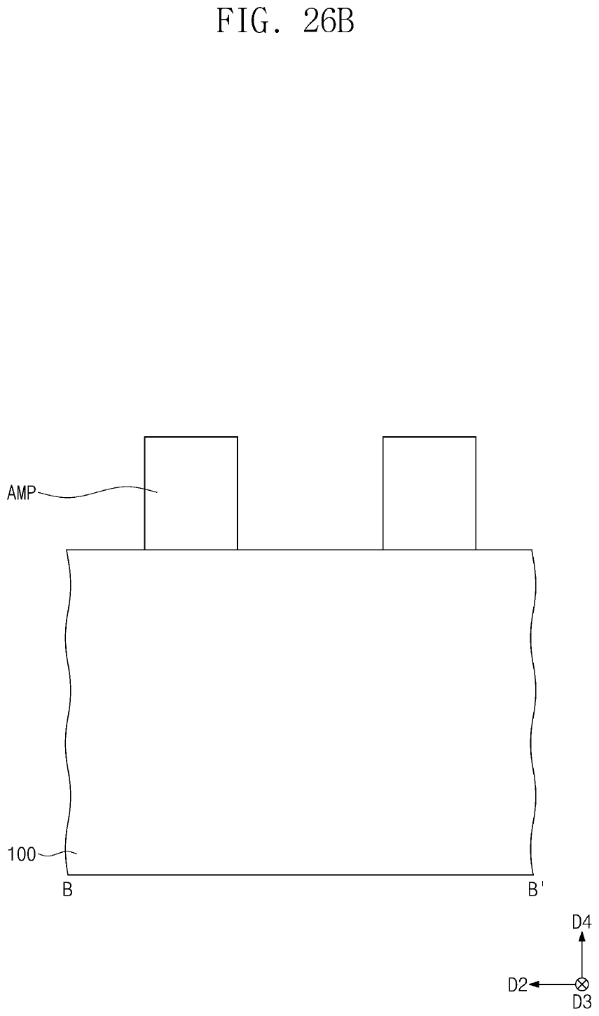

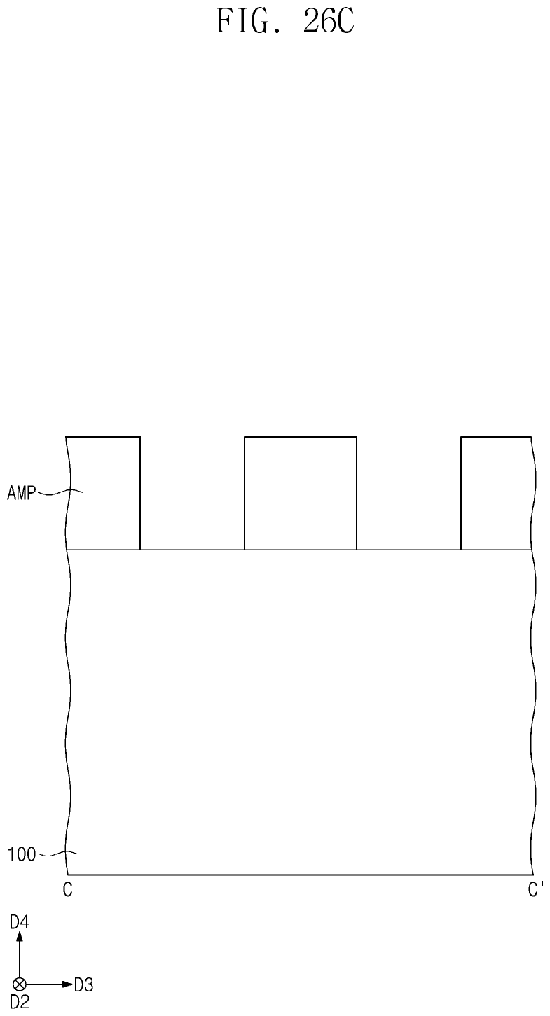

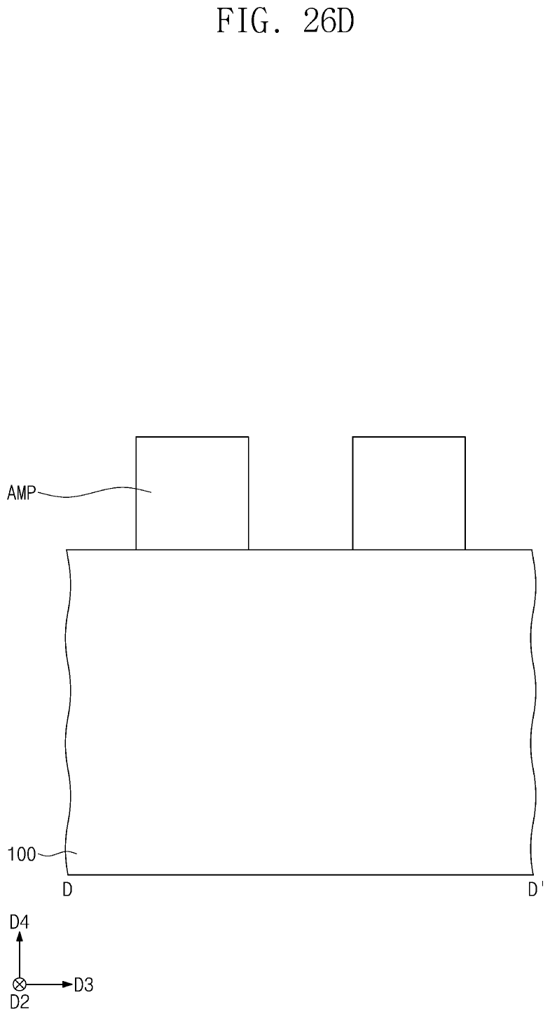

FIGS. 25 to 34D illustrate plan and cross-sectional views showing a method of fabricating a semiconductor device according to some embodiments of the present inventive concepts. For example, FIGS. 25, 27, 29, 31, and 33 illustrate plan views showing a method of fabricating a semiconductor device according to some embodiments of the present inventive concepts. FIGS. 26A, 28A, 30A, 32A, and 34A illustrate cross-sectional views taken along line A-A′ of FIGS. 25, 27, 29, 31, and 33, respectively. FIGS. 26B, 28B, 30B, 32B, and 34B illustrate cross-sectional views taken along line B-B′ of FIGS. 25, 27, 29, 31, and 33, respectively. FIGS. 26C, 28C, 30C, 32C, and 34C illustrate cross-sectional views taken along line C-C′ of FIGS. 25, 27, 29, 31, and 33, respectively. FIGS. 26D, 28D, 30D, 32D, and 34D illustrate cross-sectional views taken along line D-D′ of FIGS. 25, 27, 29, 31, and 33, respectively.

Referring to FIGS. 25 to 26D, a substrate 100 may be prepared. A first active mask pattern AMP may be formed on the substrate 100. The first active mask pattern AMP may include a plurality of patterns elongated in a first direction D1 and a plurality of trench regions between the plurality of patterns. For example, the plurality of patterns may have lateral surfaces each of which has a straight profile.

The first active mask pattern AMP may be formed by using a patterning process performed on an active mask layer. For example, the patterning process may include performing an exposure process once. In some embodiments, the patterning process may include performing an exposure process twice or more, for example, performing multi-patterning technology.

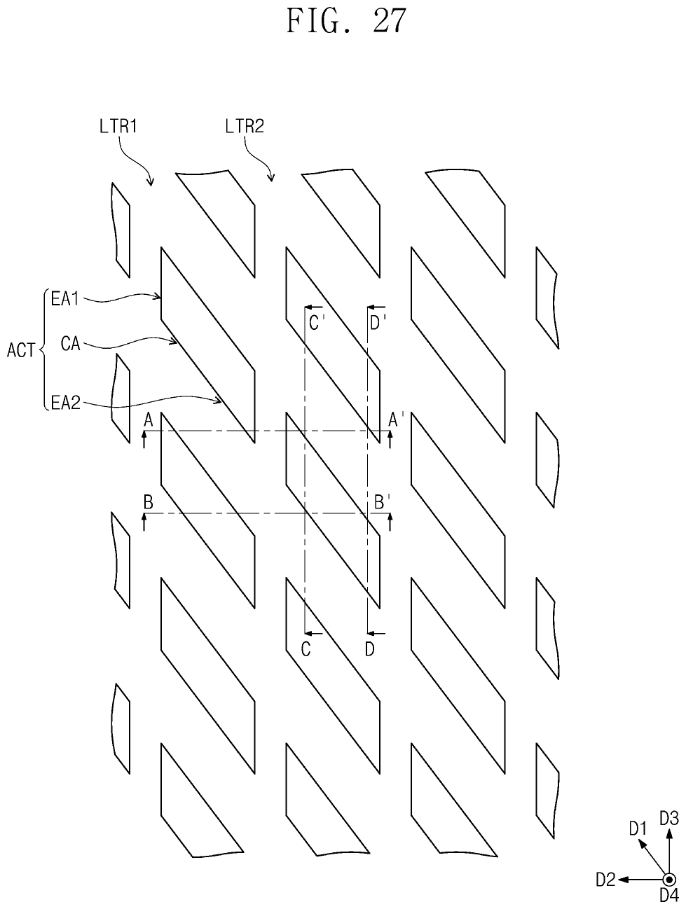

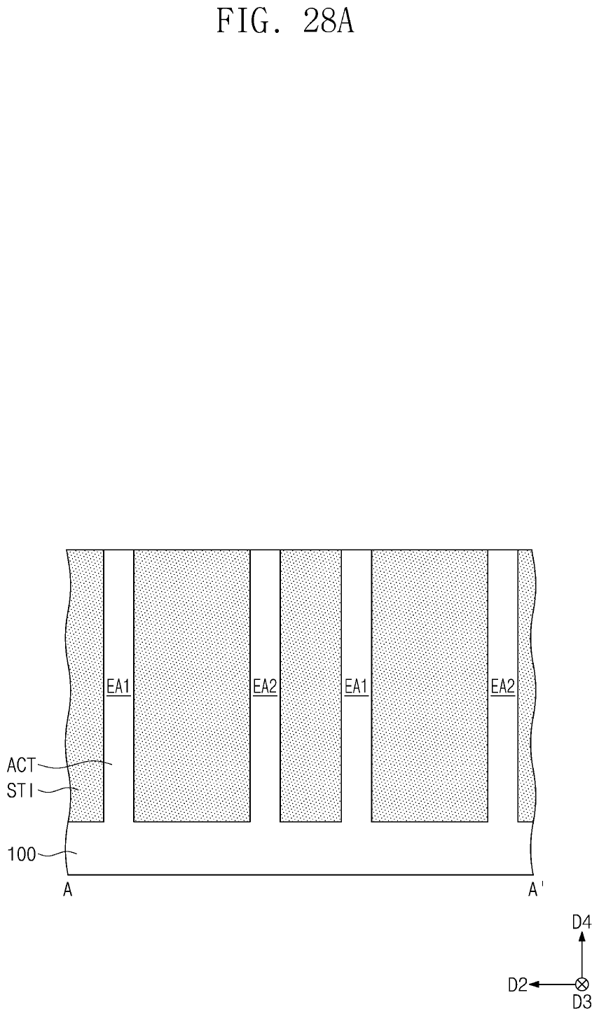

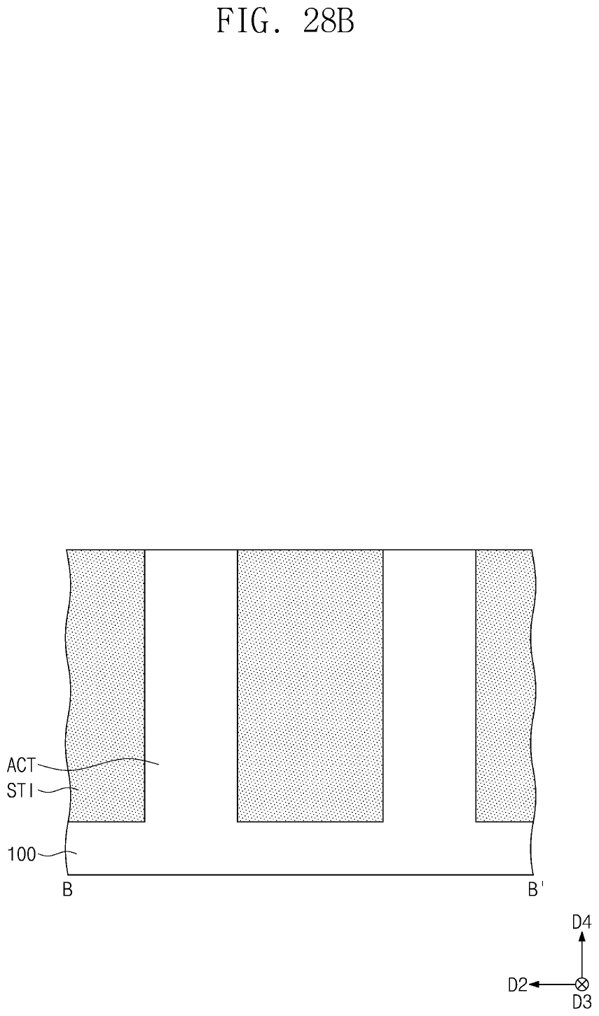

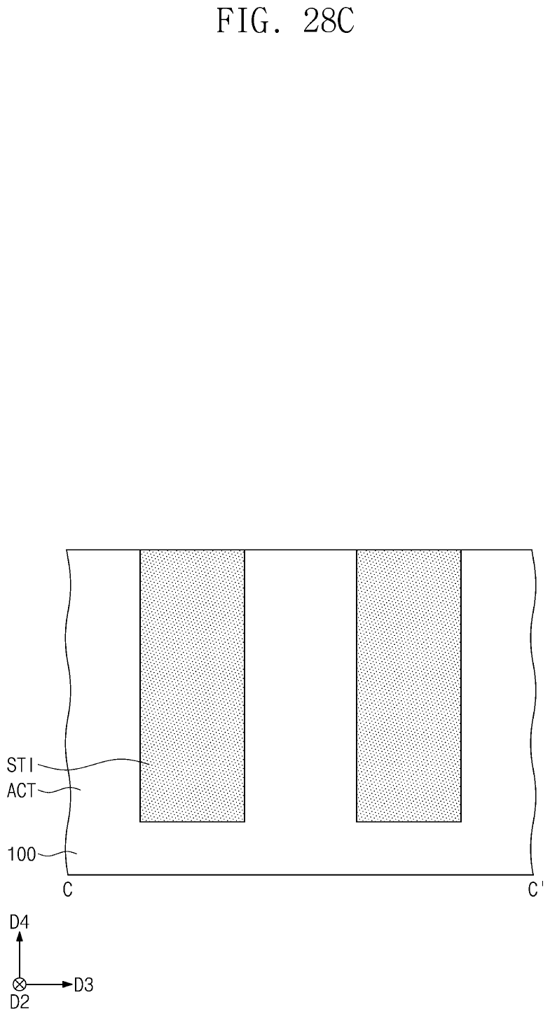

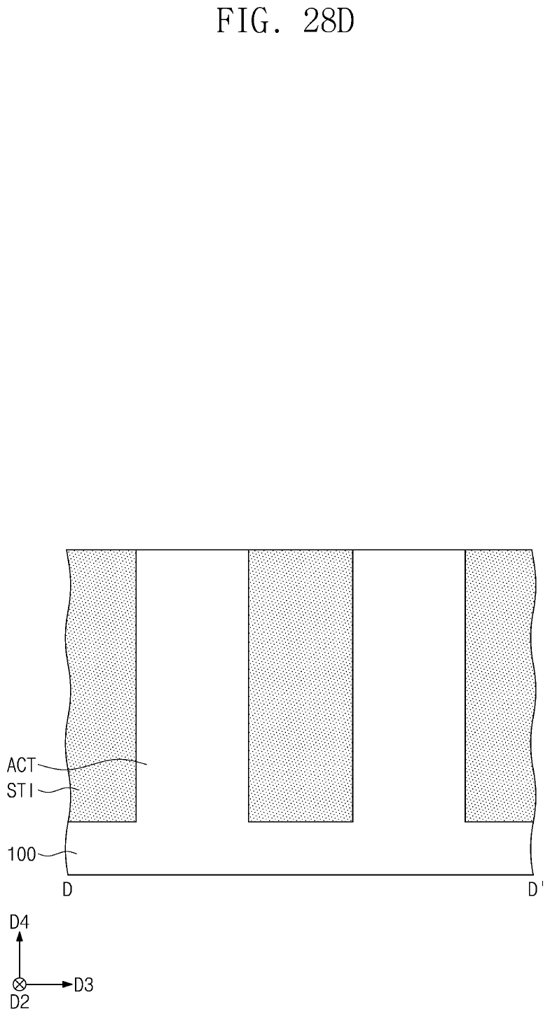

Referring to FIGS. 27 to 28D, a second active mask pattern (not shown) may be provided on the substrate 100. The second active mask pattern may include a plurality of patterns elongated in a third direction D3 and a plurality of trench regions between the plurality of patterns.

The substrate 100 may undergo a removal process to form active patterns ACT. The removal process may include using the first active mask pattern AMP and the second active mask pattern as an etching mask to perform an etching process on the substrate 100. In the etching process, a first line trench region LTR1 and a second line trench region LTR2 may be formed between the active patterns ACT. The trench region of the first active mask pattern AMP may be caused to form the first line trench region LTR1. The first line trench region LTR1 may extend along the first direction D1 between the active patterns ACT. The trench region of the second active mask pattern may be caused to form the second line trench region LTR2. The second line trench region LTR2 may extend along the third direction D3 between the active patterns ACT.

A device isolation pattern STI may be formed to partially or fully fill the first and second line trench regions LTR1 and LTR2. The formation of the device isolation pattern STI may include performing a physical vapor deposition (PVD) process, a chemical vapor deposition (CVD) process, or an atomic layer deposition (ALD) process.

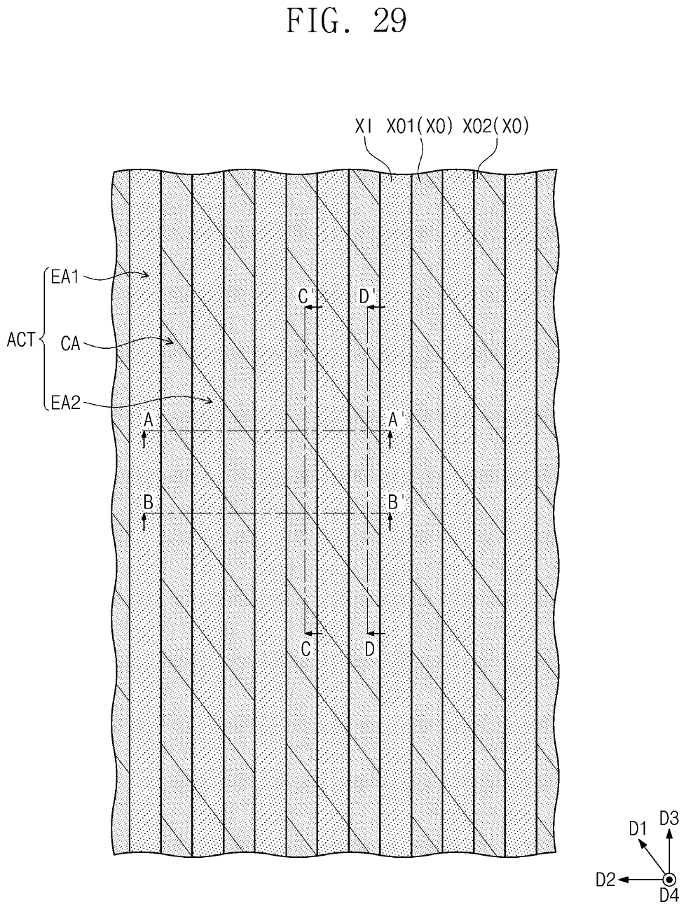

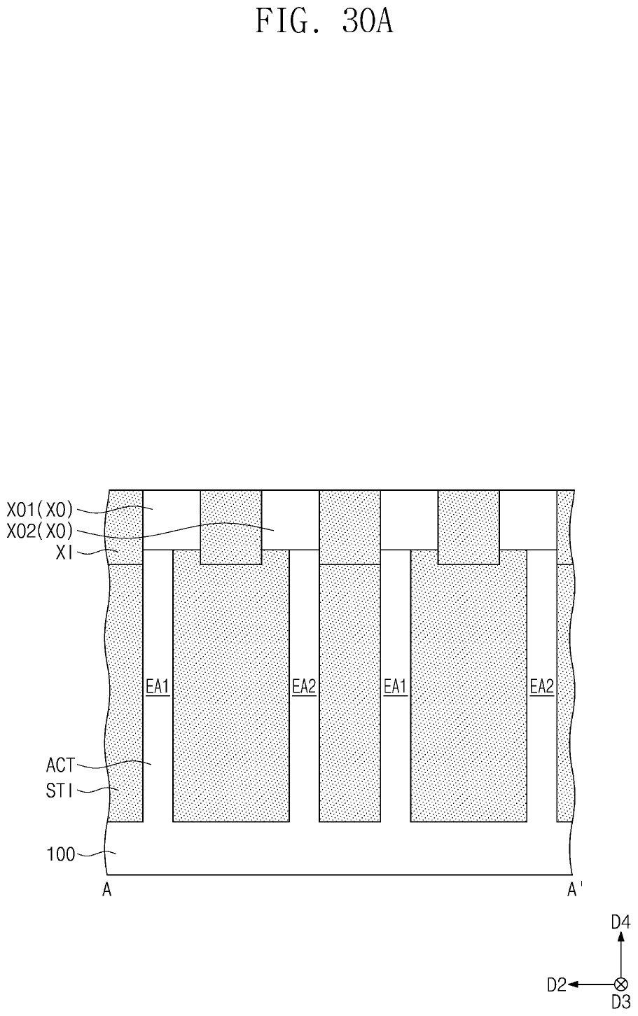

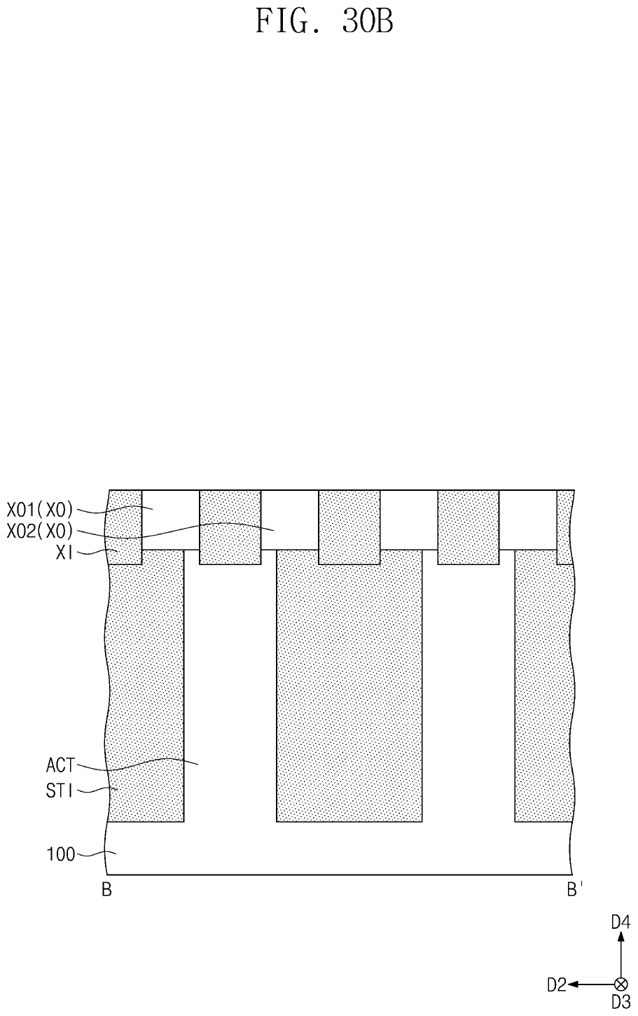

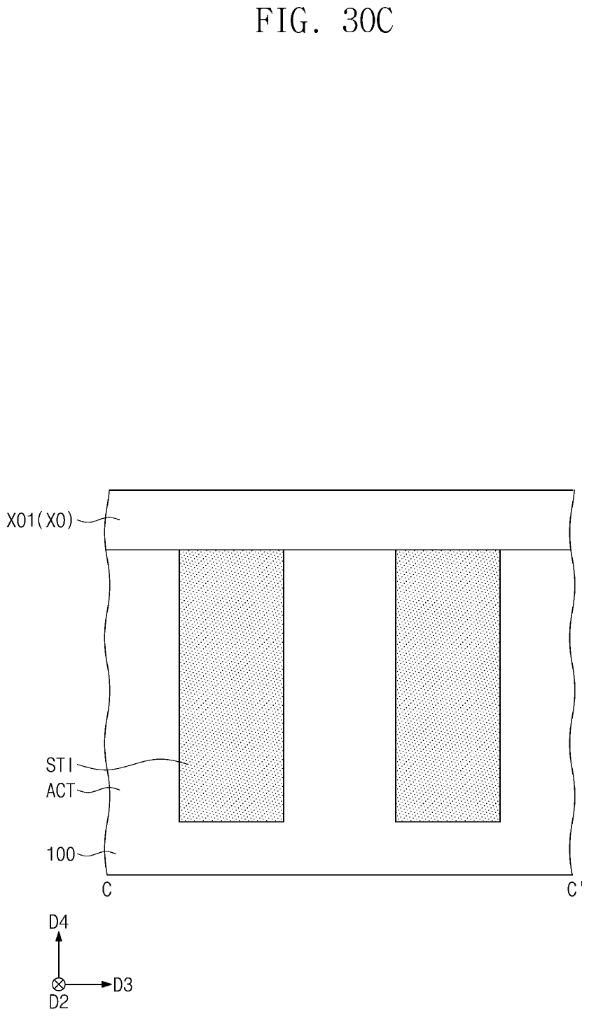

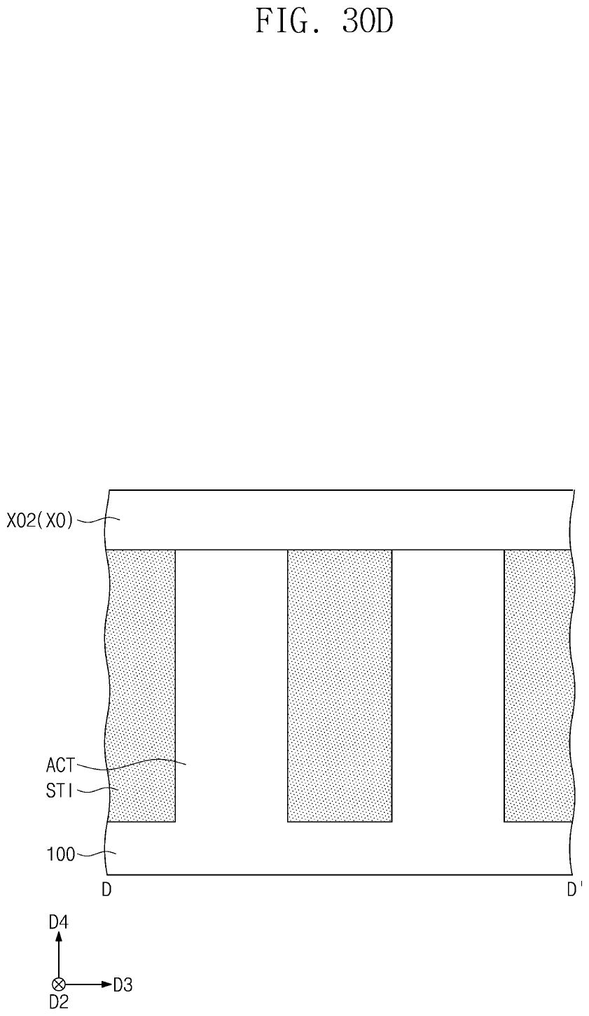

Referring to FIGS. 29 to 30D, first active pads XO1 may be formed to extend along the third direction D3 on first edge parts EA1 of the active patterns ACT. Second active pads XO2 may be formed to extend along the third direction D3 on second edge parts EA2 of the active patterns ACT. The formation of the first and second active pads XO1 and XO2 may include performing an embossing process in which an active pad layer (not shown) is used. For example, the active pad layer may be formed on a front surface of the substrate 100, and then the active pad layer may be removed to form the first and second active pads XO1 and XO2. The first active pad XO1 may have a top surface located at substantially the same as that of a top surface of the second active pad XO2.

When the etching process is performed, an upper portion of the device isolation pattern STI may be recessed to a certain depth. After the etching process, trench regions may be formed between the first active pad XO1 and the second active pad XO2. A portion of the trench regions may extend in the third direction D3 on a central part CA of the active pattern ACT. Another portion of the trench regions may extend in the third direction D3 between the active patterns ACT that neighbor each other in the first direction D1.

An active dielectric pattern XI may be formed to partially or fully fill the trench regions between the first active pad XO1 and the second active pad XO2. The active dielectric pattern XI may have a top surface that is located at substantially the same level as that of the top surfaces of the first and second active pads XO1 and XO2, and may be coplanar with the top surfaces of the first and second active pads XO1 and XO2.

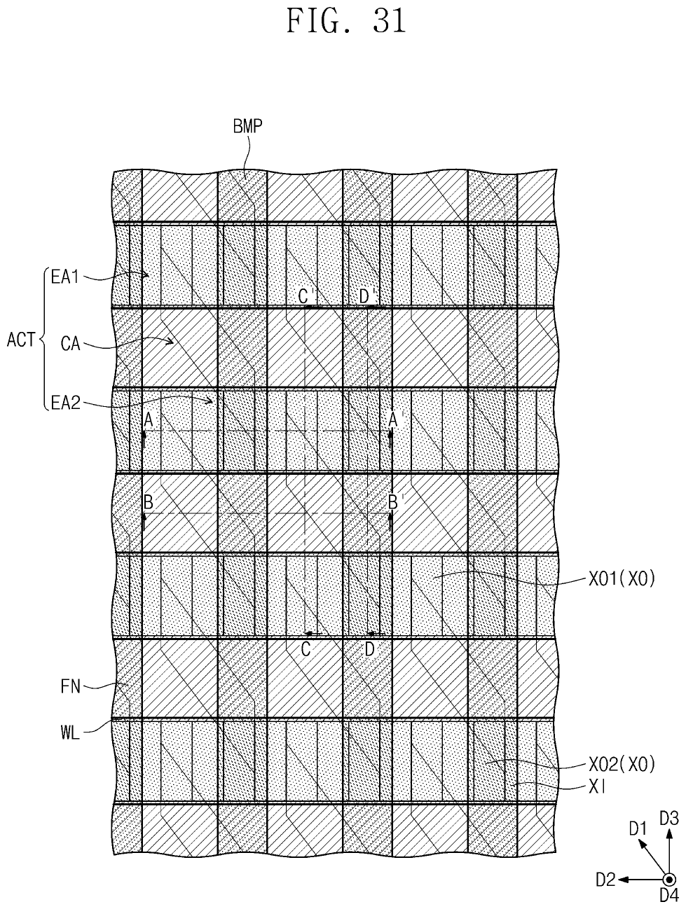

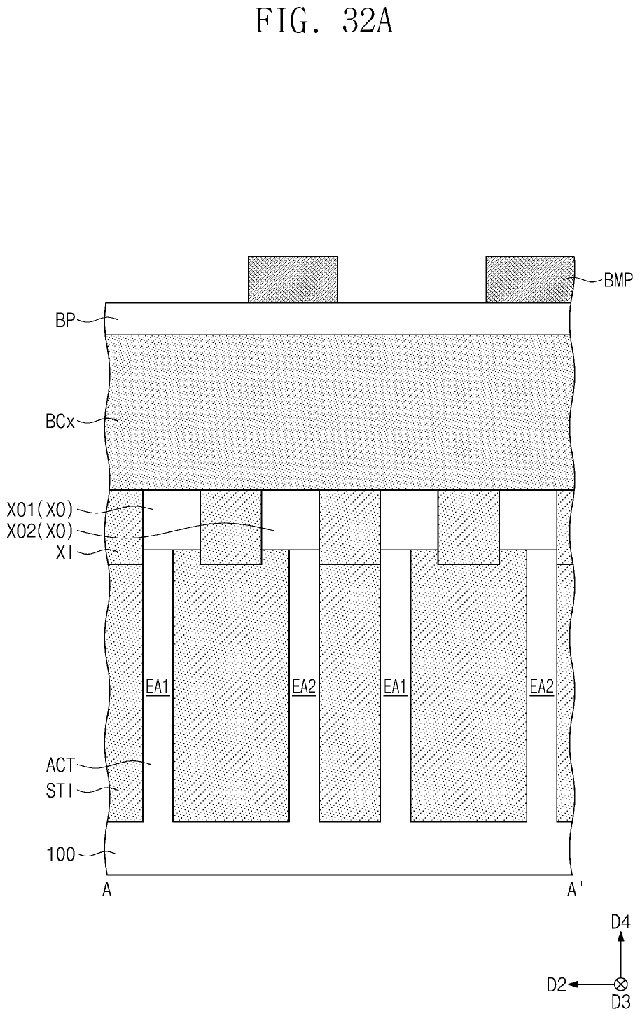

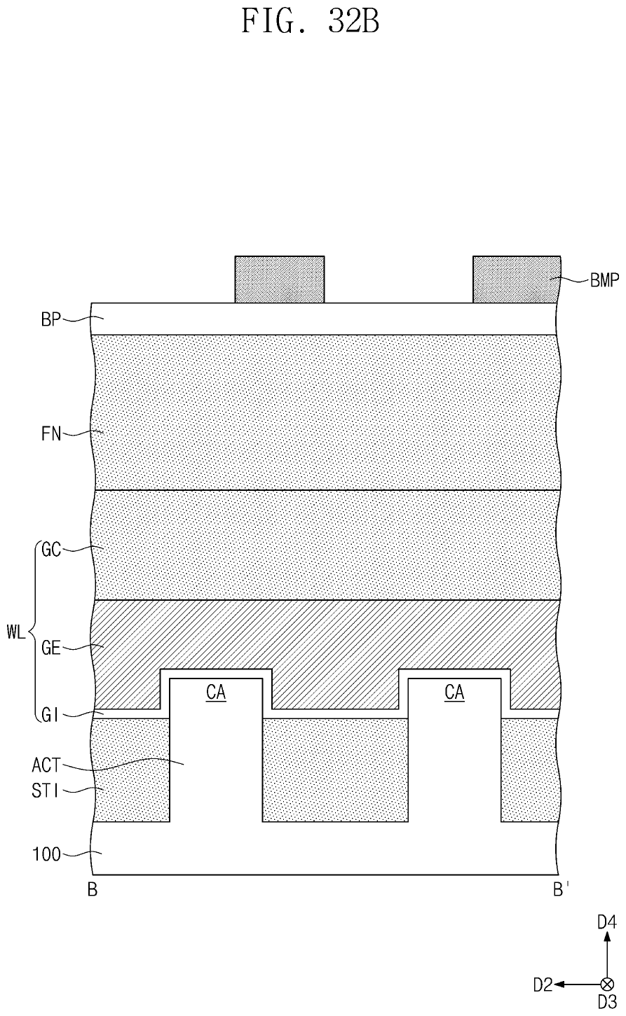

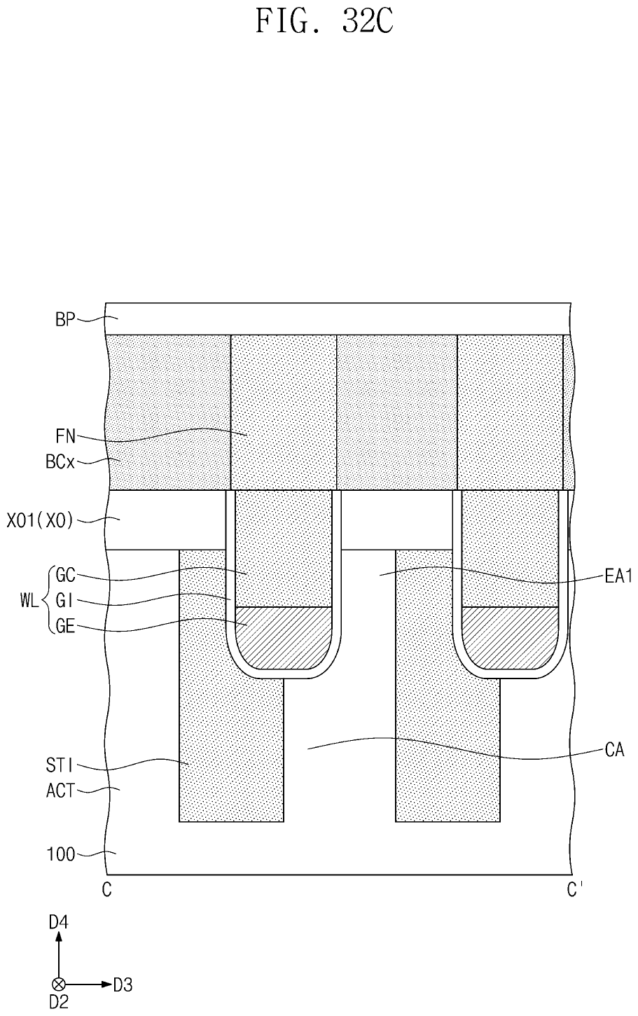

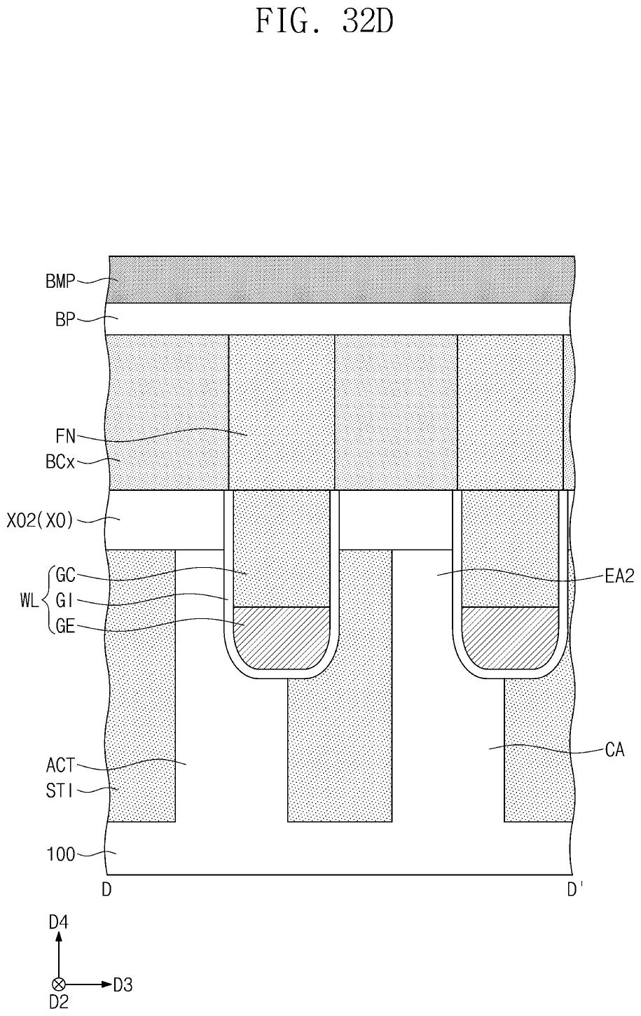

Referring to FIGS. 31 to 32D, a word line WL may be formed to run across the active pattern ACT and the device isolation pattern STI. The word line WL may be formed to penetrate the first and second active pads XO1 and XO2. Therefore, one first active pad XO1 may be divided into a plurality of first active pads XO1 that are spaced apart from each other in the third direction D3, and one second active pattern XO2 may be divided into a plurality of second active pads XO2 that are spaced apart from each other in the third direction D3.

The formation of the word line WL may include forming a mask pattern on the active pattern ACT and the device isolation pattern STI, using the mask pattern to perform an anisotropic etching process by which a trench region is formed to run across the active pattern ACT and the device isolation pattern STI, and partially or fully filling the trench region with the word line WL. The word line WL may be formed on the central part CA of the active pattern ACT and between the first edge part EA1 and the second edge part EA2.

The partially or fully filling of the trench region with the word line WL may include, for example, conformally depositing a gate dielectric pattern GI on an inner surface of the trench region, partially or fully filling the trench region with a conductive layer, allowing the conductive layer to undergo an etch-back process and/or a polishing process to form a gate electrode GE, and forming on the gate electrode GE a gate capping pattern GC that partially or fully fills an unoccupied portion of the trench region.

Lower storage node contacts BCx and fence patterns FN may be formed arranged alternately along the third direction D3 on the substrate 100. The lower storage node contacts BCx may be formed to extend along a second direction D2 on the second edge parts EA2 of the active patterns ACT. The fence patterns FN may be formed to extend along the second direction D2 on the central parts CA of the active patterns ACT. For example, the formation of the lower storage node contacts BCx and the fence patterns FN may include forming a lower storage node contact layer (not shown) to form the front surface of the substrate 100, and forming the fence pattern FN to divide the lower storage node contact layer into a plurality of lower storage node contacts BCx that are spaced apart from each other in the third direction D3. Afterwards, a buffer pattern BP may be formed to cover or overlap the front surface of the substrate 100.

A bit-line mask pattern BMP may be formed on the buffer pattern BP. The bit-line mask pattern BMP may include a plurality of mask patterns which are spaced apart from each other in the second direction D2 and each of which extends along the third direction D3. The bit-line mask pattern BMP may be formed on the second edge part EA2 of the active pattern ACT. For example, the bit-line mask pattern BMP may completely cover or overlap a top surface EA2a of the second edge part EA2. The bit-line mask pattern BMP may be formed not to vertically overlap the first edge part EA1, and when viewed in plan, may be formed to be shifted in the second direction D2 from the first edge part EA1.

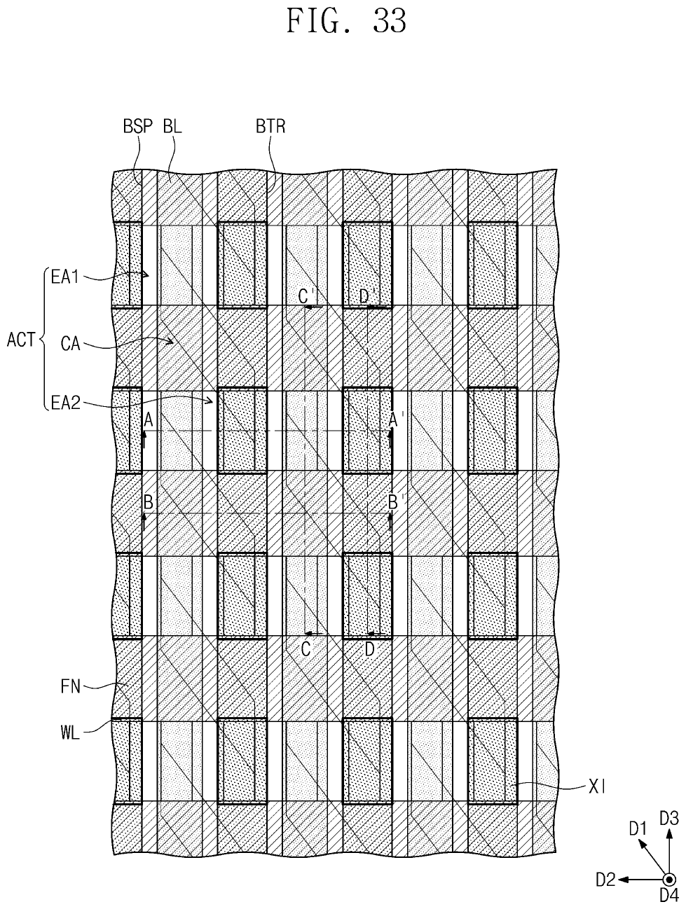

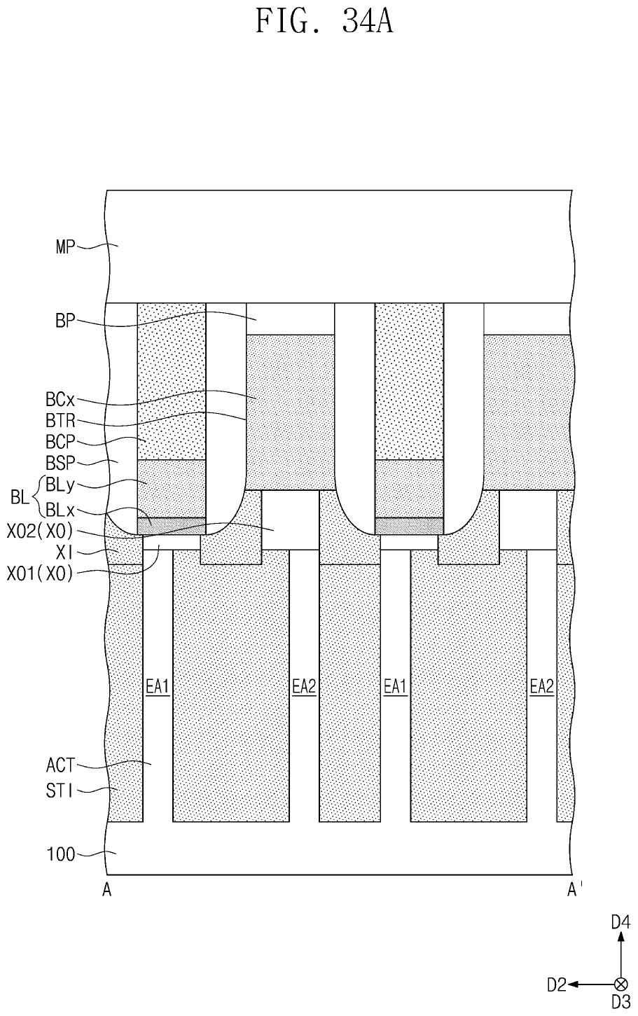

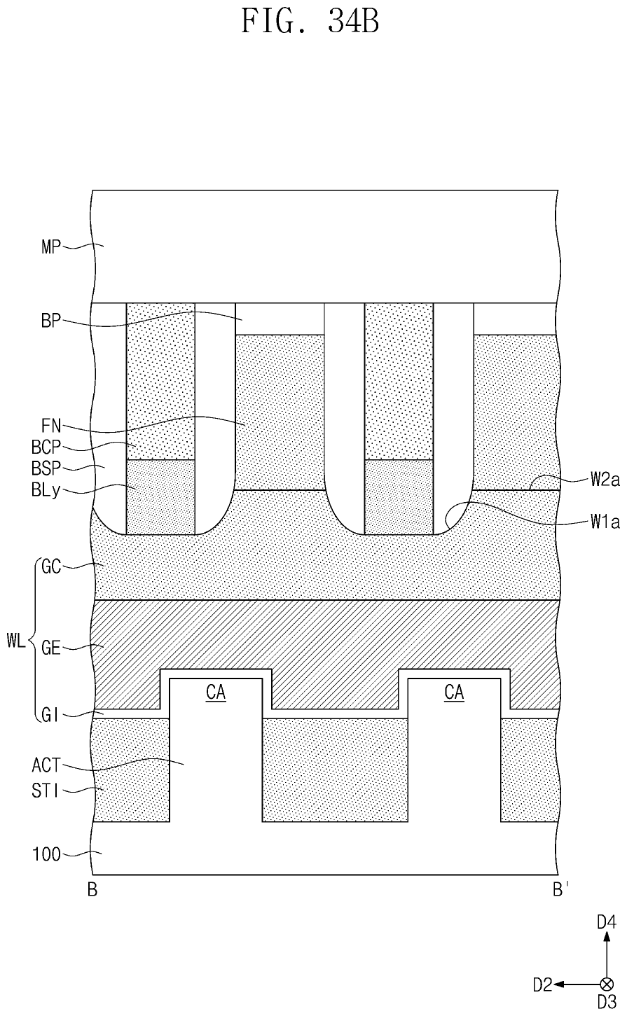

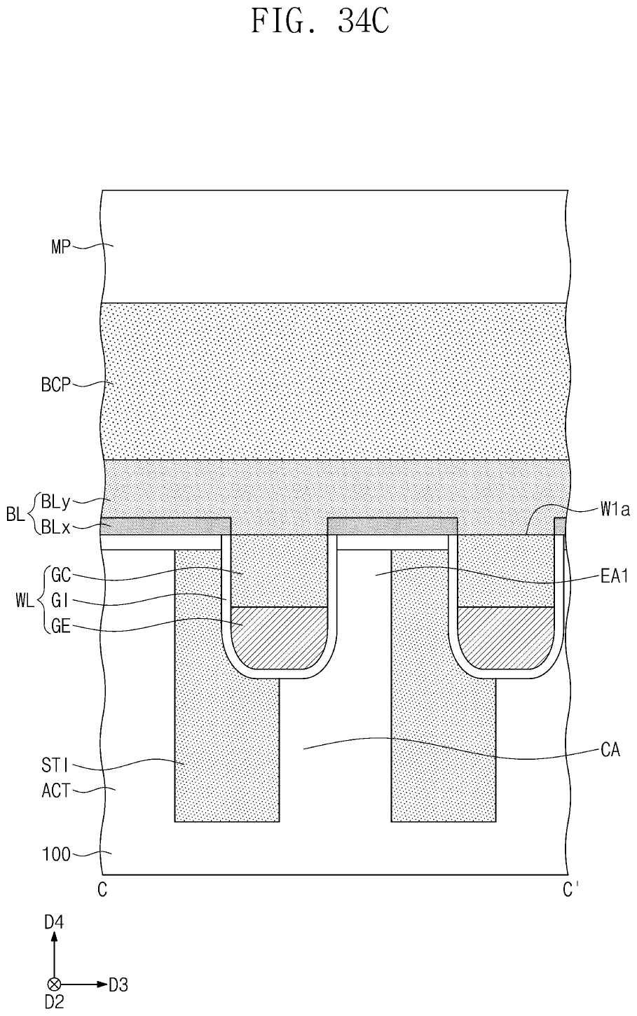

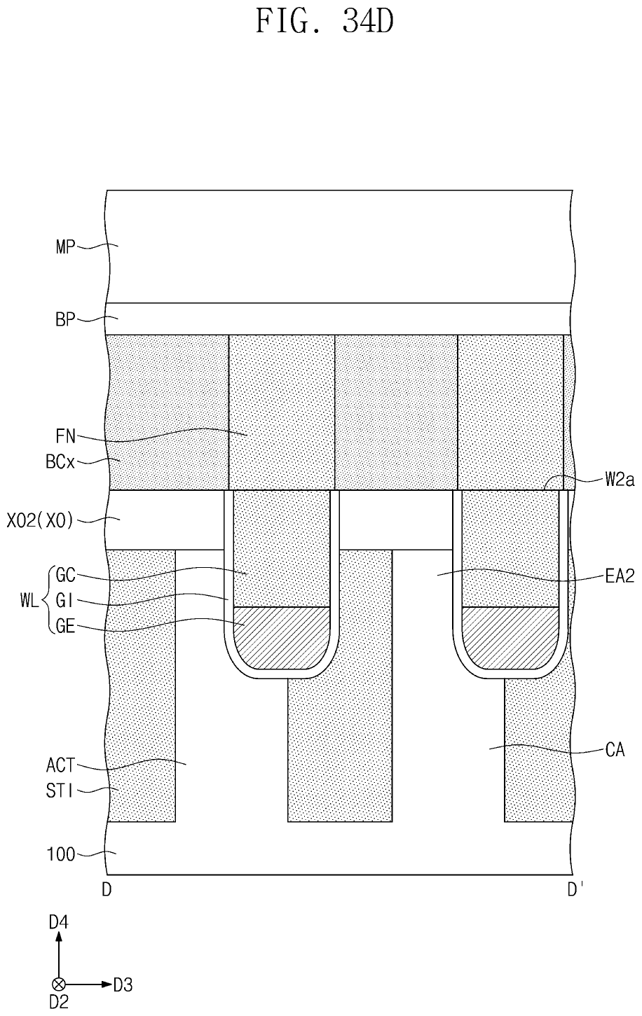

Referring to FIGS. 33 to 34D, the bit-line mask pattern BMP may be used as an etching mask to performing a removal process that removes the buffer pattern BP, the lower storage node contact BCx, the fence pattern FN, an upper portion of the word line WL, an upper portion of the active dielectric pattern XI, and an upper portion of the first active pad XO1, with the result that bit-line trench regions BTR may be formed on the first edge parts EA1 of the active patterns ACT. The bit-line trench regions BTR may be formed to extend along the third direction D3 on the first edge parts EA1 of the active patterns ACT. The bit-line trench regions BTR may separate one lower storage node contact BCx into a plurality of lower storage node contacts BCx that are spaced apart from each other in the second direction D2. The bit-line trench regions BTR may separate one fence pattern FN into a plurality of fence patterns FN that are spaced apart from each other in the second direction D2. The bit-line trench regions BTR may separate one buffer pattern BP into a plurality of buffer patterns BP that are spaced apart from each other in the second direction D2. When the bit-line trench region BTR is formed, a top surface of the word line WL may be partially recessed. Thus, the top surface of the word line WL may be separated into a first top surface W1a and a second top surface W2a. The lower storage node contacts BCx, the buffer patterns BP, and the fence patterns FN may have lateral surfaces that are outwardly exposed on inner lateral surfaces of the bit-line trench regions BTR. The active dielectric patterns XI and the first active pads XO1 may have upper portions that are outwardly exposed on inner bottom surfaces of the bit-line trench regions BTR. The first top surface W1a of the word line WL may be outwardly exposed on the inner bottom surface of the bit-line trench region BTR.

A bit-line spacer BSP may be formed in the bit-line trench region BTR. The bit-line spacer BSP may be formed to cover or overlap the inner lateral surface of the bit-line trench region BTR. For example, a pair of bit-line spacers BSP may cover or overlap opposite lateral surfaces of the bit-line trench region BTR. The formation of the bit-line spacer BSP may include, for example, forming a bit-line spacer layer (not shown) to cover or overlap inner surfaces of the bit-line trench regions BTR and a top surface of the buffer pattern BP, and removing a portion of the bit-line spacer layer. The bit-line spacer BSP may be constituted or formed by a residue of the bit-line spacer layer that is not removed on the inner lateral surface of the bit-line trench region BTR.

A lower bit line BLx may be formed between the pair of bit-line spacers BSP in the bit-line trench region BTR. The lower bit line BLx may be formed on the first active pad XO1. For example, the lower bit line BLx may be formed by selective epitaxial growth. The selective epitaxial growth may be one of deposition methods by which a specific material is grown only on a particular region.

An upper bit line BLy and a bit-line capping pattern BCP may be formed to be sequentially stacked on the lower bit line BLx. The formation of the bit-line capping pattern BCP may include, for example, forming a bit-line capping layer (not shown) to partially or fully fill the bit-line trench regions BTR and to cover or overlap the front surface of the substrate 100, and removing an upper portion of the bit-line capping layer to form the bit-line capping patterns BCP that are separated from each other. The removing the upper portion of the bit-line capping layer may include performing a chemical mechanical polishing process on the bit-line capping layer. After the removal process, the bit-line capping pattern BCP may have a top surface that is located at substantially the same as that of a top surface of each of the buffer pattern BP and the bit-line spacer BSP and is coplanar with the top surface of each of the buffer pattern BP and the bit-line spacer BSP. Afterwards, a mold pattern MP may be formed to cover or overlap the front surface of the substrate 100.

Referring to FIGS. 1A and 2A to 2D, contact holes CH may be formed to penetrate the mold pattern MP. For example, the formation of the contact holes CH may include forming a mask pattern (not shown) including holes (not shown) to cover or overlap a top surface of the mold pattern MP, and using the mask pattern as an etching mask to perform a removal process on the mold pattern MP. When the removal process is performed, the buffer pattern BP, the bit-line capping pattern BCP, the bit-line spacer BSP, and the lower storage node contact BCx may also be partially removed, and remaining portions of the buffer pattern BP, the bit-line capping pattern BCP, the bit-line spacer BSP, and the lower storage node contact BCx may be outwardly exposed on inner surfaces of the contact holes CH.

Upper storage node contacts BCy may be correspondingly formed in the contact holes CH. For example, the formation of the upper storage node contacts BCy may include forming an upper storage node contact layer (not shown) to partially or fully fill the contact holes CH and to cover or overlap the top surface of the mold pattern MP, removing the upper storage node contact layer on the top surface of the mold pattern MP to form the upper storage node contacts BCy that are separated from each other, and removing an upper portion of each of the upper storage node contacts BCy. The removal of the upper storage node contact layer on the top surface of the mold pattern MP may include performing a chemical mechanical polishing process on the upper storage node contact layer. The removal of the upper portions of the upper storage node contacts BCy may include performing an etch-back process on the upper storage node contacts BCy. Therefore, the upper storage node contact BCy may have a top surface located at a level lower than that of the top surface of the mold pattern MP.

A second silicide pattern SC may be formed on the upper storage node contact BCy in the contact hole CH. The second silicide pattern SC may be formed by selective epitaxial growth. A second barrier pattern (not shown) may further be formed together with the second silicide pattern SC.

A landing pad spacer LSP (as shown in FIG. 2A and/or FIG. 4) may be formed to cover or overlap the inner surface of the contact hole CH on the second silicide pattern SC. For example, the formation of the landing pad spacer LSP may include forming a landing pad spacer layer (not shown) to conformally cover or overlap the inner surfaces of the contact holes CH and the top surface of the mold pattern MP, and etching the landing pad spacer layer to form the landing pad spacer LSP.

Thereafter, landing pads LP (as shown in FIG. 2A and/or FIG. 4) may be formed to partially or fully fill unoccupied portions of the contact holes CH. For example, the formation of the landing pads LP may include forming a landing pad layer (not shown) to partially or fully fill the unoccupied portions of the contact holes CH and to cover or overlap the top surface of the mold pattern MP, and removing an upper portion of the landing pad layer to form the landing pads LP that are separated from each other. The removal of the upper portion of the landing pad layer may include performing a chemical mechanical polishing process on the landing pad layer. Therefore, the landing pad LP may have a top surface located at a level that is substantially the same as that of the top surface of the mold pattern MP and is coplanar with the top surface of the mold pattern MP.

Afterwards, data storage patterns DSP may be correspondingly formed on the landing pads LP.

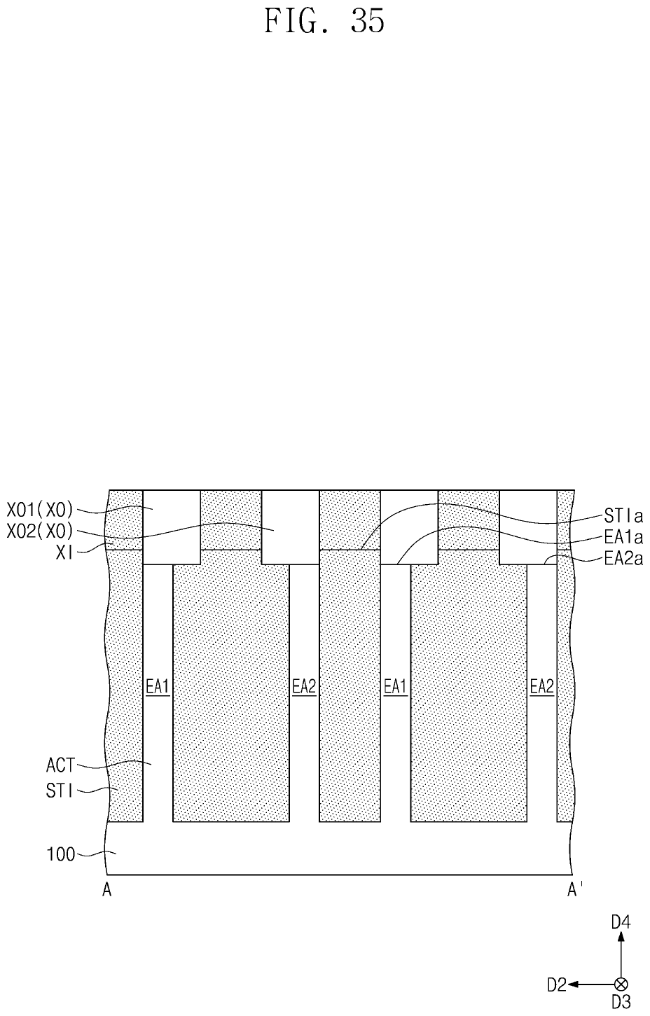

FIG. 35 illustrates a cross-sectional view showing a method of fabricating a semiconductor device according to some embodiments of the present inventive concepts.

Referring to FIG. 35, after the formation of the active pattern ACT and the device isolation pattern STI discussed with reference to FIGS. 27 to 28D, a first active pad XO1 may be formed on the first edge part EA1 of the active pattern ACT. A second active pad XO2 may be formed on the second edge part EA2 of the active pattern ACT. The formation of the first and second active pads XO1 and XO2 may include performing an engraving process in which an active dielectric layer (not shown) is used. For example, after the formation of the active dielectric layer on the front surface of the substrate 100, the active dielectric layer may be removed to form active dielectric patterns XI, and the first and second active pads XO1 and XO2 may be formed between the active dielectric patterns XI.

When the removal process is performed, the first and second edge parts EA1 and EA2 of the active pattern ACT may also be partially removed. Thus, the first and second edge parts EA1 and EA2 of the active pattern ACT may have top surfaces EA1a and EA2a that are located at a level lower than that of an uppermost surface STIa of the device isolation pattern STI. Each of the first and second active pads XO1 and XO2 may have a bottom surface located at a level lower than that of a bottom surface of the active dielectric pattern XI.

Thereafter, a semiconductor fabrication method mentioned above may be used to fabricate a semiconductor device discussed with reference to FIG. 3.

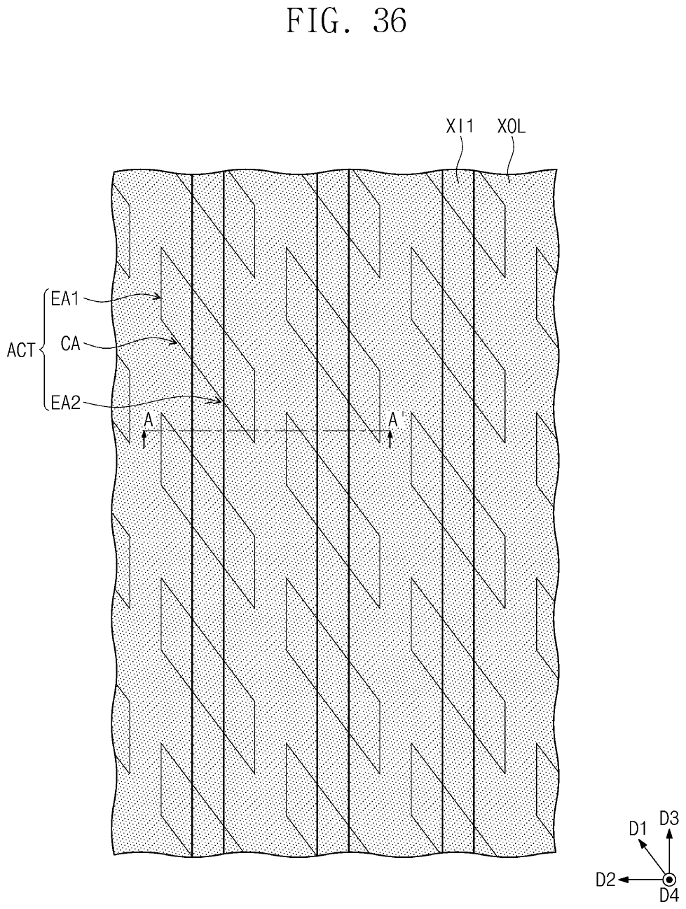

FIGS. 36 to 39 illustrate plan and cross-sectional views showing a method of fabricating a semiconductor device according to some embodiments of the present inventive concepts.

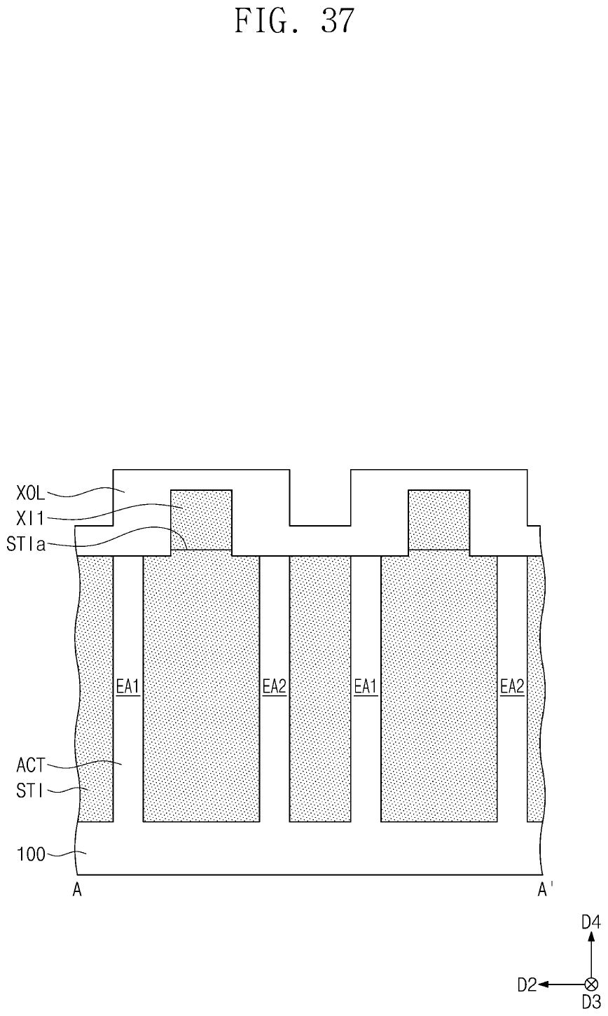

Referring to FIGS. 36 and 37, after the formation of the active pattern ACT and the device isolation pattern STI discussed with reference to FIGS. 27 to 28D, a first active dielectric pattern XI1 may be formed to extend along the third direction D3 on the central part CA of the active pattern ACT. The formation of the first active dielectric pattern XI1 may include forming an active dielectric layer (not shown) to cover or overlap the front surface of the substrate 100, and removing the active dielectric layer to form the first active dielectric pattern XI1. When the removal process is performed, the device isolation pattern STI and the first and second edge parts EA1 and EA2 of the active pattern ACT may also be partially removed, and this procedure may outwardly expose a top surface of the device isolation pattern STI and top surfaces EA1a and EA2a of the first and second edge parts EA1 and EA2 of the active pattern ACT. Therefore, the exposed top surface of the device isolation pattern STI and the exposed top surfaces EA1a and EA2a of the first and second edge parts EA1 and EA2 of the active pattern ACT may be located at a level lower than that of an uppermost surface STIa of the device isolation pattern STI. The top surfaces EA1a and EA2a of the first and second edge parts EA1 and EA2 of the active pattern ACT may be located at a level lower than that of the central part CA of the active pattern ACT.

An active pad layer XOL may be formed to cover or overlap the top surfaces EA1a and EA2a of the first and second edge parts EA1 and EA2 of the active pattern ACT, the exposed device isolation pattern STI, and the first active dielectric pattern XI1.

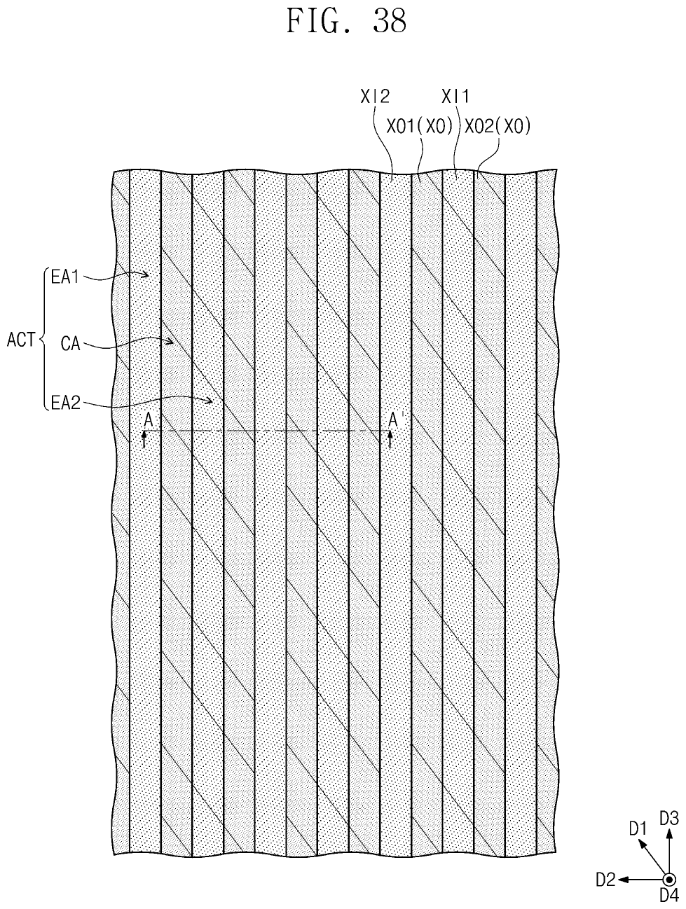

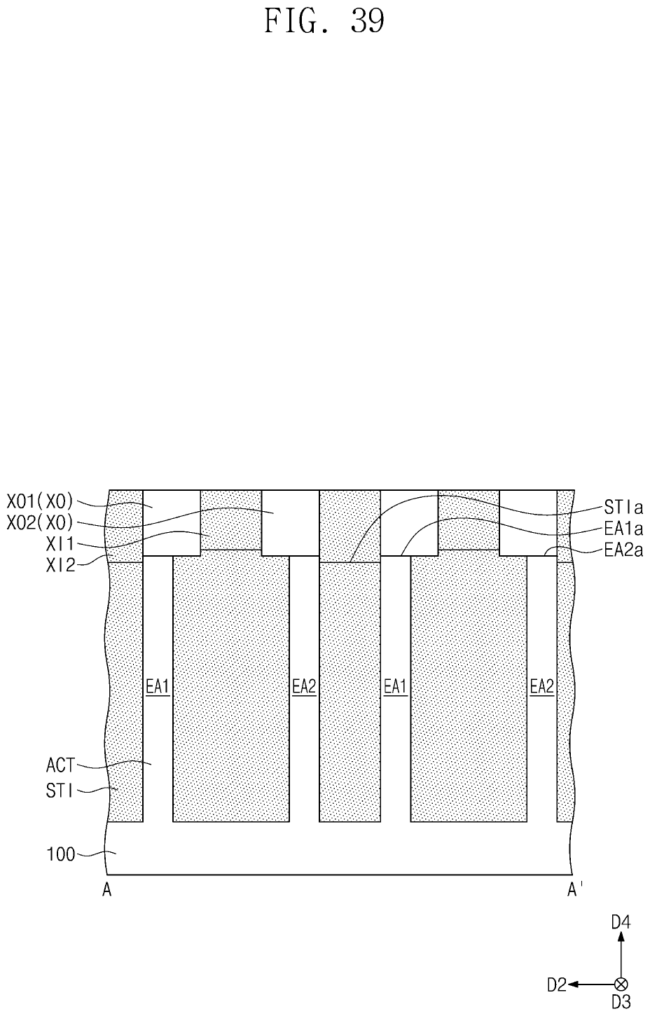

Referring to FIGS. 38 and 39, a removal process may be performed on the active pad layer XOL. The removal process may include an anisotropic etching process, and thus a portion of the active pad layer XOL may remain without being removed on a lateral surface of the first active dielectric pattern XI1. The portion of the active pad layer XOL may remain on the first and second edge parts EA1 and EA2, and may constitute or form first and second active pads XO1 and XO2. When the removal process is performed, a portion of the device isolation pattern STI may also be removed, and the top surface STIa of the device isolation pattern STI may be outwardly exposed. The exposed top surface STIa of the device isolation pattern STI may be located at a level lower than that of the top surfaces EA1a and EA2a of the first and second edge parts EA1 and EA2 of the active pattern ACT.

A second active dielectric pattern XI2 may be formed to extend along the third direction D3 between the active patterns ACT that neighbor each other in the first direction D1. The second active dielectric pattern XI2 may be formed to cover or overlap the exposed top surface STIa of the device isolation pattern STI.

Thereafter, a semiconductor fabrication method discussed above may be used to fabricate a semiconductor device discussed with reference to FIG. 4.

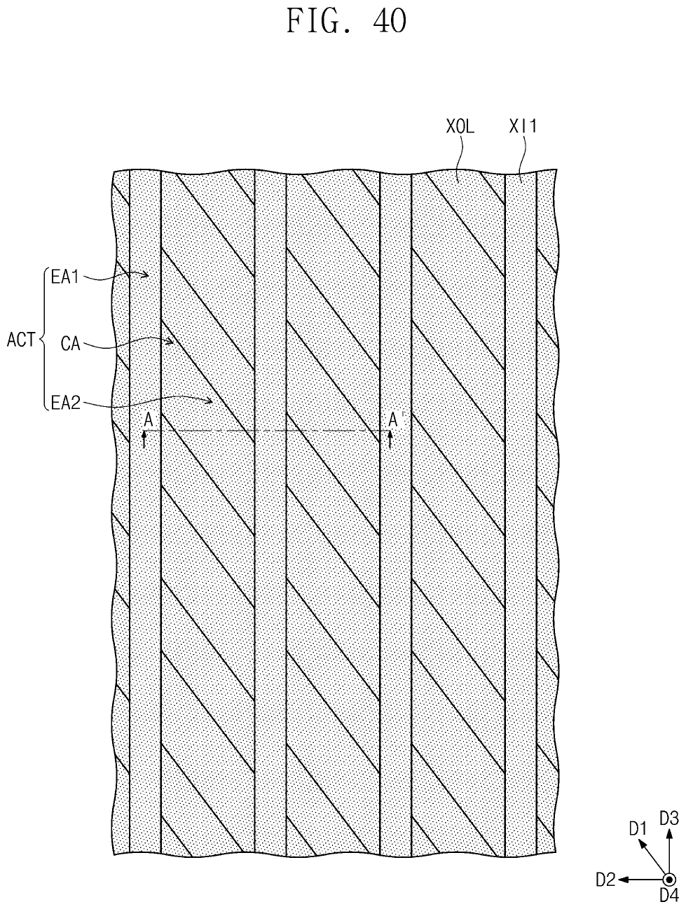

FIGS. 40 to 43 illustrate plan and cross-sectional views showing a method of fabricating a semiconductor device according to some embodiments of the present inventive concepts.

Referring to FIGS. 40 to 43, after the formation of the active pattern ACT and the device isolation pattern STI discussed with reference to FIGS. 27 to 28D, a first active dielectric pattern XI1 may be formed to extend along the third direction D3 between the active patterns ACT that neighbor each other in the first direction D1. The formation of the first active dielectric pattern XI1 may be similar to that discussed with reference to FIGS. 36 and 37.

A first active pad XO1 may be formed on the first edge part EA1 of the active pattern ACT. A second active pad XO2 may be formed on the second edge part EA2 of the active pattern ACT. The formation of the first and second active pads XO1 and XO2 may be similar to that discussed with reference to FIGS. 38 and 39. A second active dielectric pattern XI2 may be formed to extend along the third direction D3 on the central part CA of the active pattern ACT.

The device isolation pattern STI and the first and second edge parts EA1 and EA2 of the active pattern ACT may have properties similar to those discussed with reference to FIGS. 36 to 39.

Thereafter, a semiconductor fabrication method discussed above may be used to fabricate a semiconductor device discussed with reference to FIG. 5.

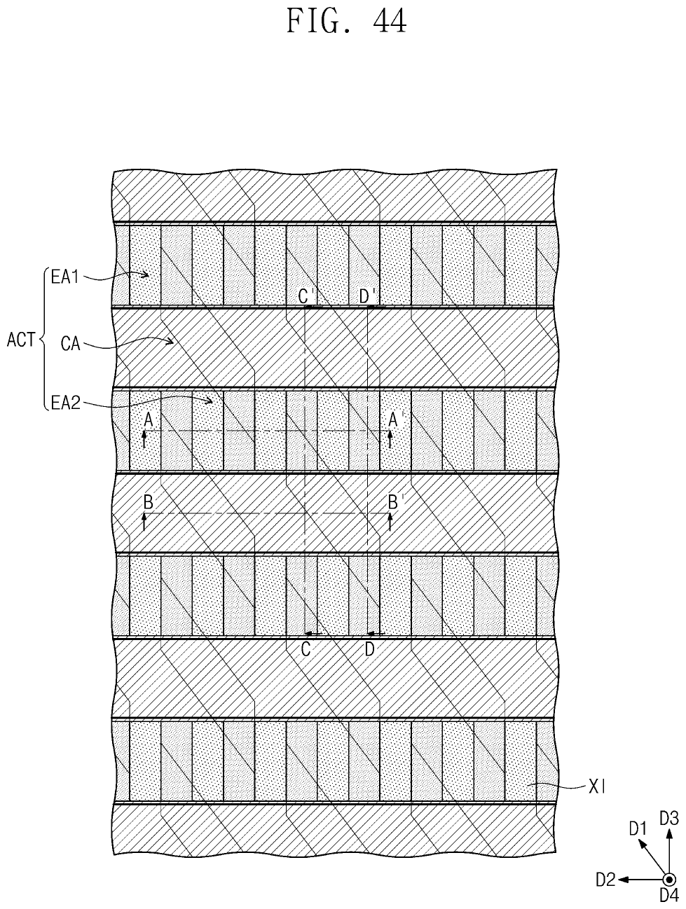

FIGS. 44 to 47C illustrate plan and cross-sectional views showing a method of fabricating a semiconductor device according to some embodiments of the present inventive concepts.

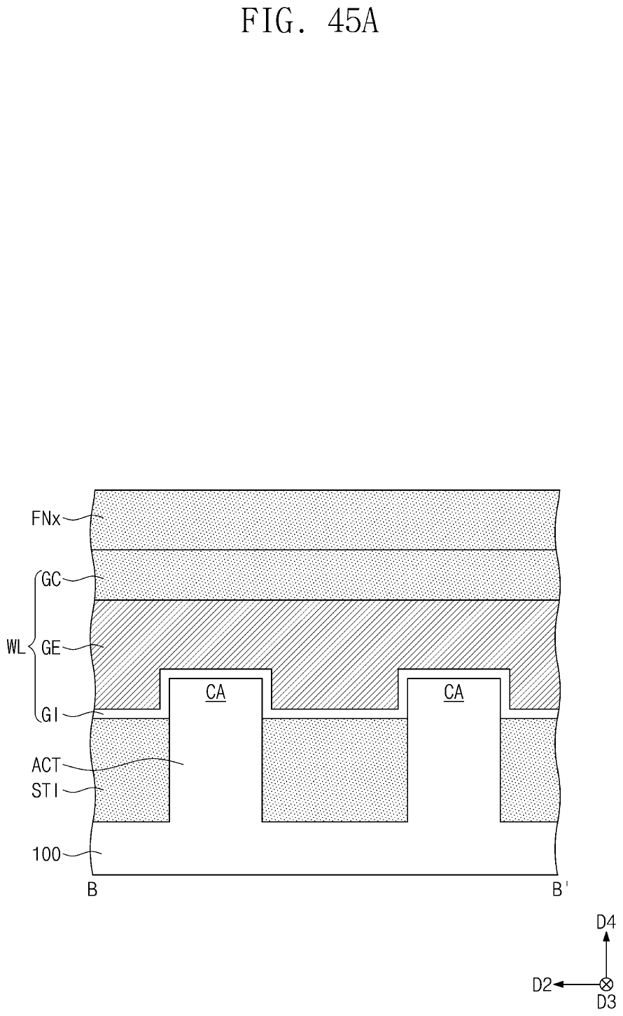

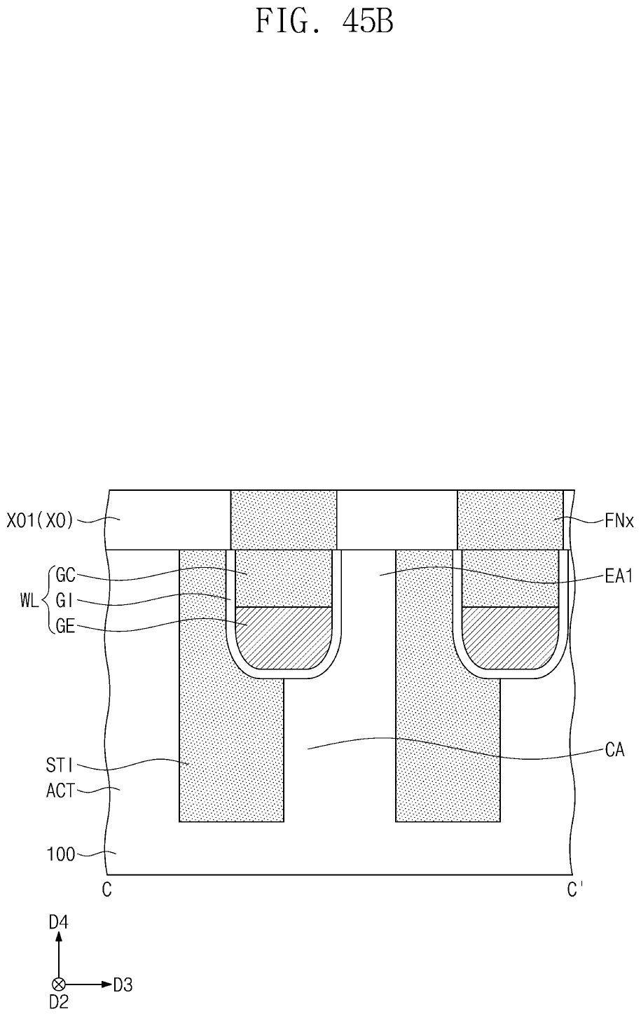

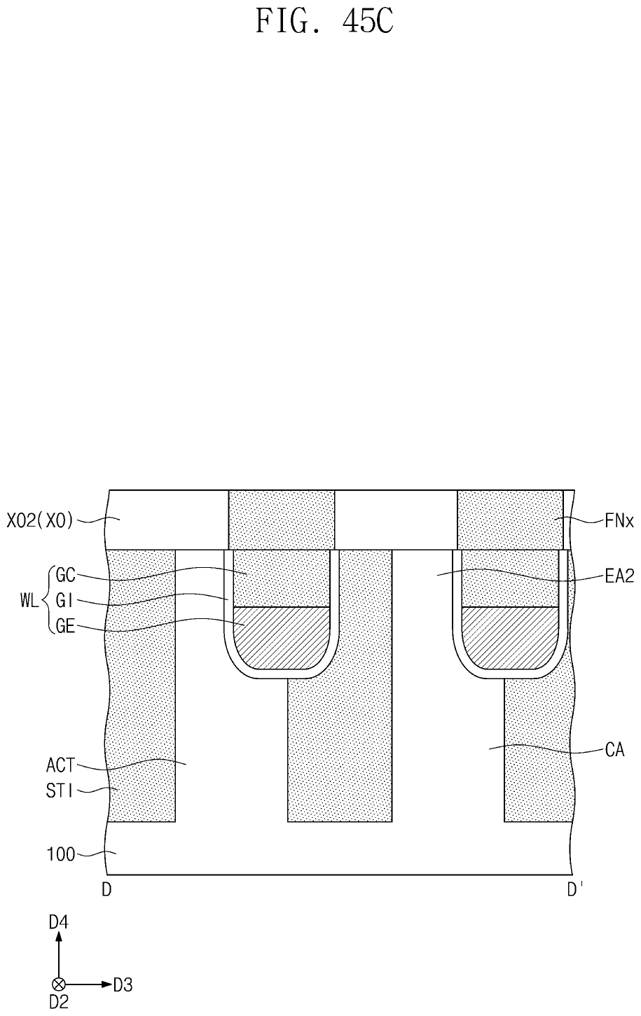

Referring to FIGS. 44 to 45C, after the formation of the active pattern ACT and the device isolation pattern STI discussed with reference to FIGS. 27 to 28D, a word line WL may be formed to run across the active pattern ACT and the device isolation pattern STI. The formation of the word line WL may be similar to that discussed with reference to FIGS. 31 to 32D. Afterwards, first and second active pads XO1 and XO2 may be formed. The formation of the first and second active pads XO1 and XO2 may be similar to that discussed with reference to FIGS. 29 to 30D. As the formation of the word line WL is followed by the formation of the first and second active pads XO1 and XO2, the first and second active pads XO1 and XO2 may have top surfaces located at a level higher than that of a top surface of the word line WL.

On the word lines WL, lower fence patterns FNx may be formed to penetrate the first and second active pads XO1 and XO2. The lower fence pattern FNx may be formed to extend along the second direction D2 on the word line WL.

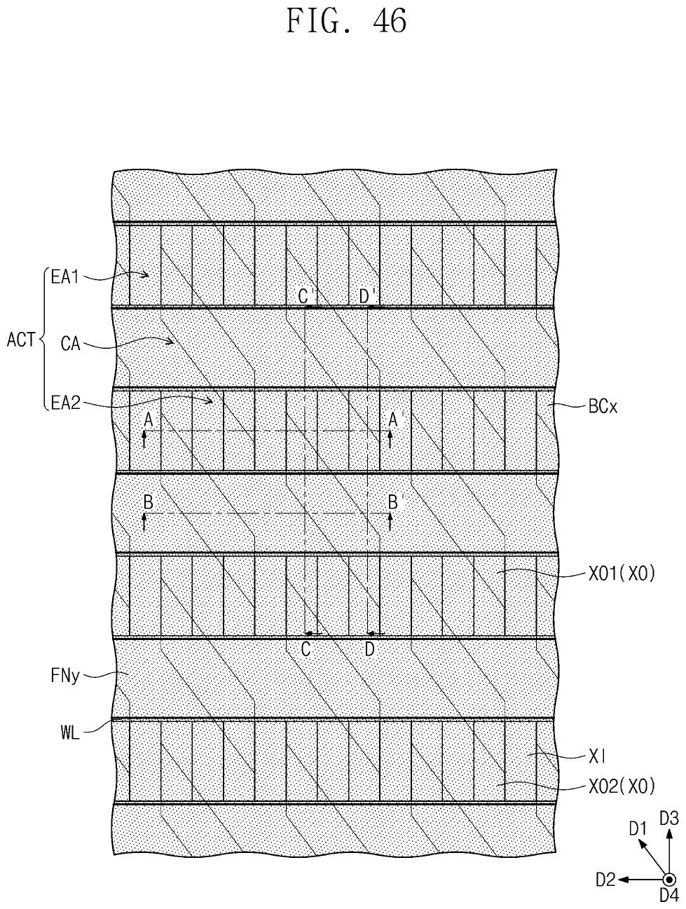

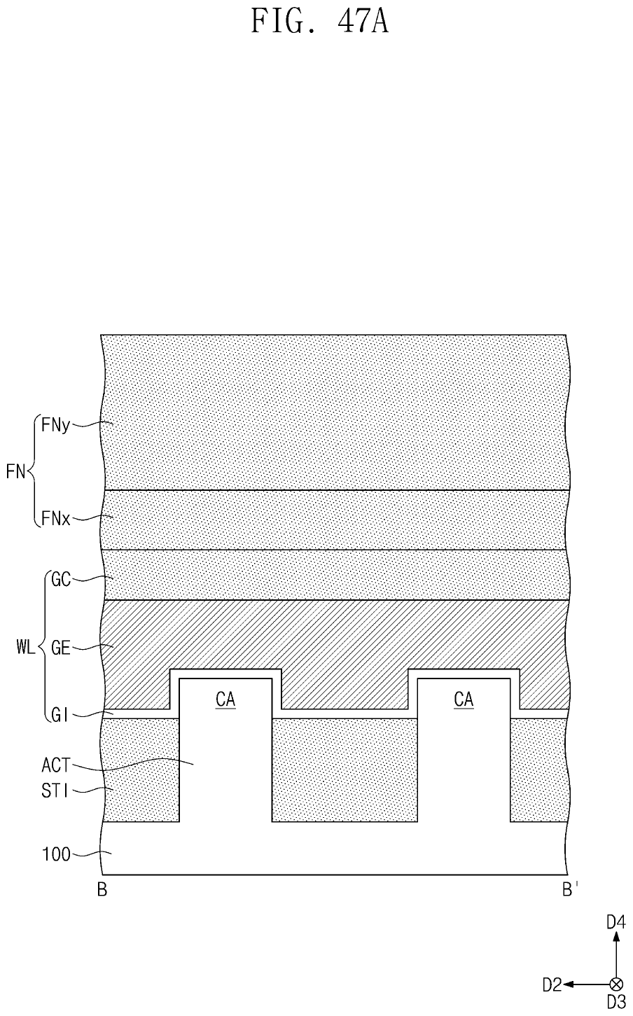

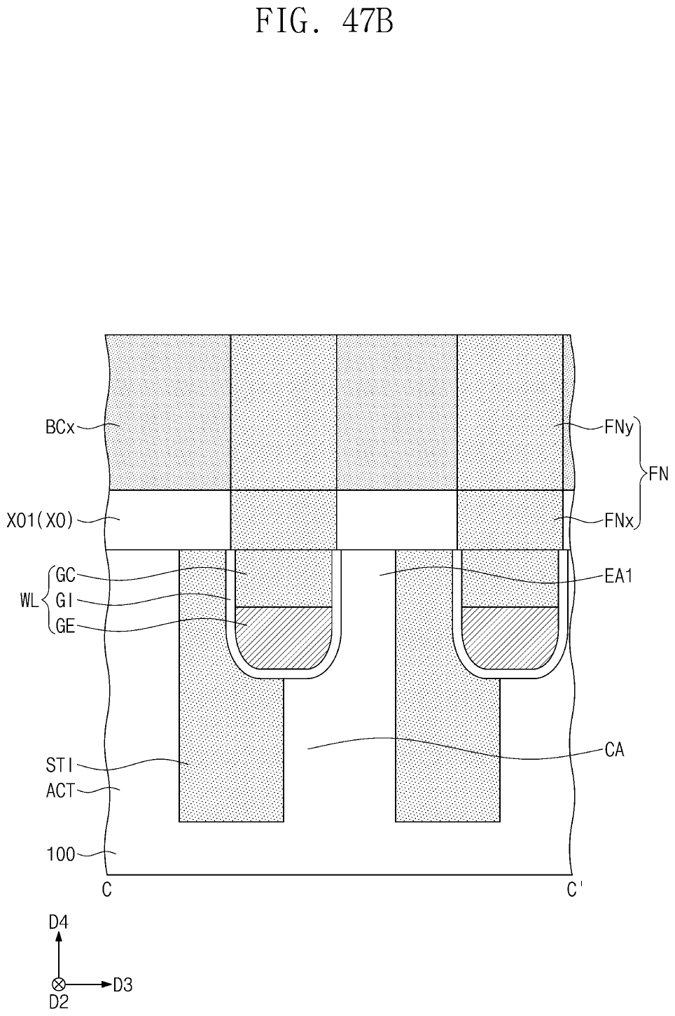

Referring to FIGS. 46 to 47C, lower storage node contacts BCx and upper fence patterns FNy may be formed arranged alternately along the third direction D3 on the substrate 100. The lower storage node contacts BCx may be formed to extend along the second direction D2 on the second edge parts EA2 of the active patterns ACT. The upper fence patterns FNy may be formed to extend along the second direction D2 on the lower fence patterns FNx. For example, the formation of the lower storage node contacts BCx and the upper fence patterns FNy may be similar to the formation of the lower storage node contacts BCx and the fence patterns FN discussed with reference to FIGS. 32A to 32D.

Thereafter, a semiconductor fabrication method mentioned above may be used to fabricate a semiconductor device discussed with reference to FIGS. 6A to 6C.

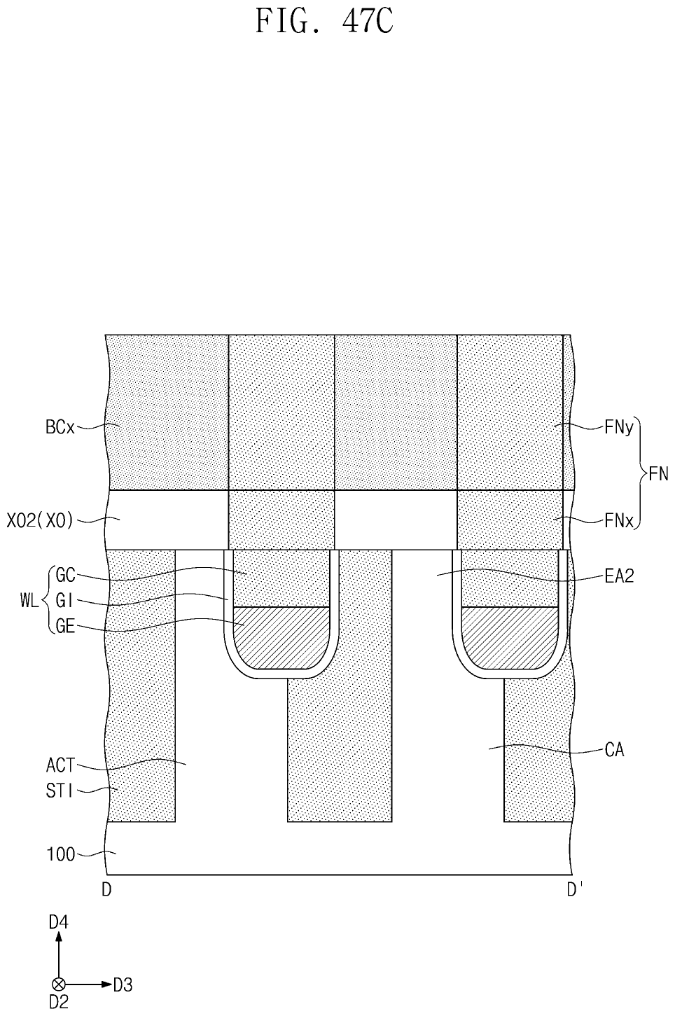

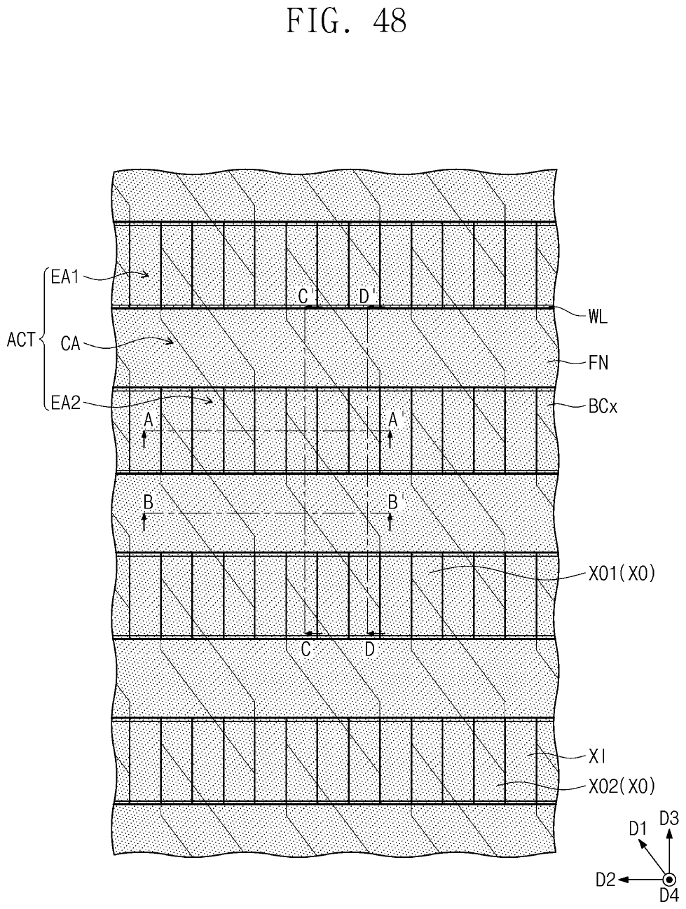

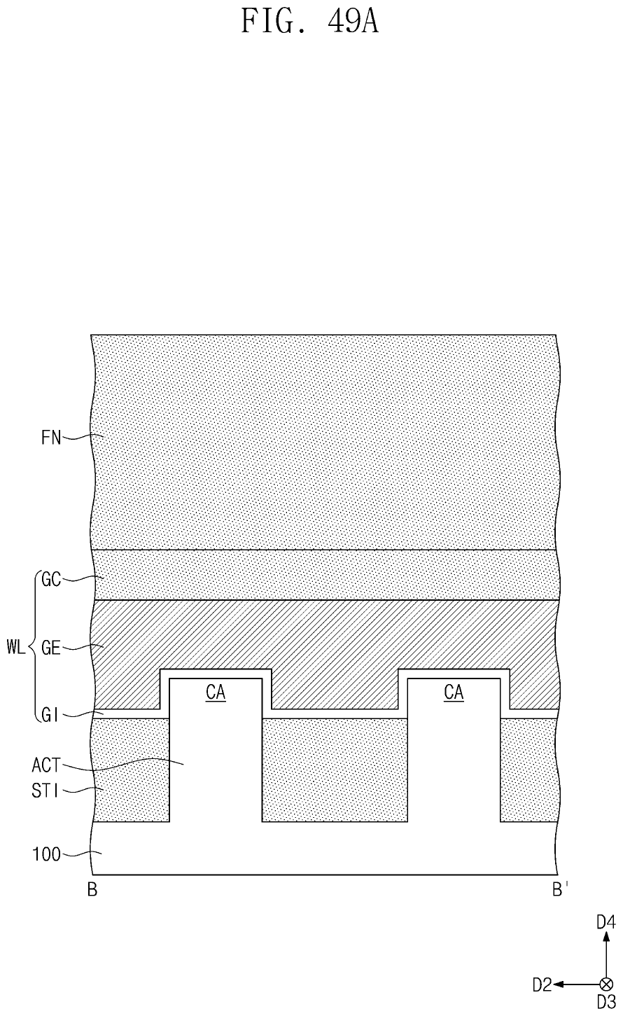

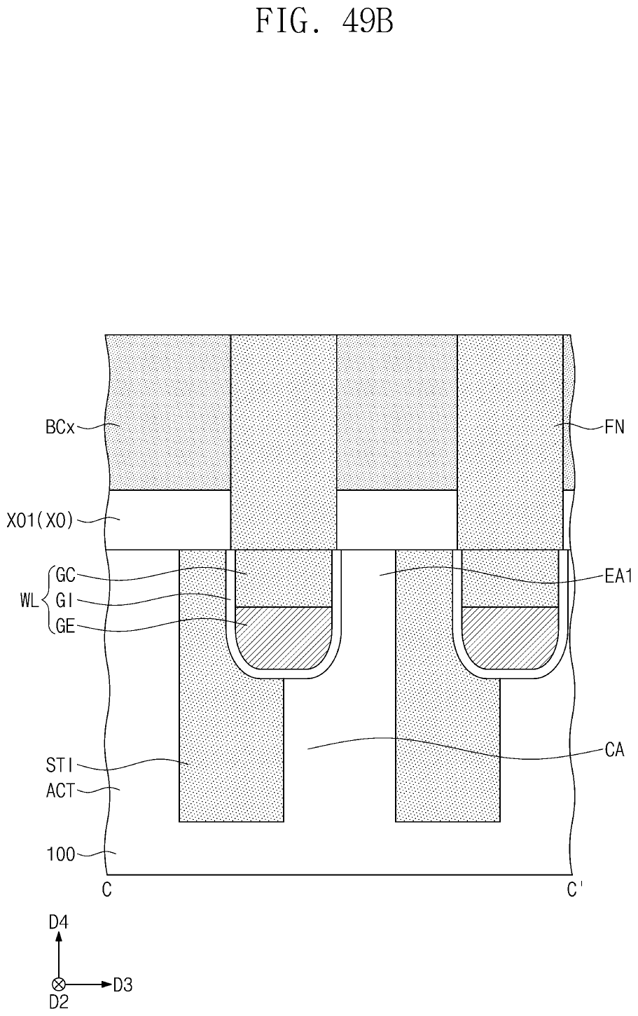

FIGS. 48 to 49C illustrate plan and cross-sectional views showing a method of fabricating a semiconductor device according to some embodiments of the present inventive concepts.

Referring to FIGS. 48 to 49D, after the formation of the first and second active pads XO1 and XO2 discussed with reference to FIGS. 44 to 45C, lower storage node contacts BCx and fence patterns FN may be formed arranged alternately along the third direction D3 on the substrate 100. For example, the formation of the lower storage node contacts BCx and the fence patterns FN may be similar to that discussed with reference to FIGS. 32A to 32D.

The fence patterns FN may be formed to penetrate the first and second active pads XO1 and XO2. Therefore, the fence patterns FN may separate the first active pads XO1 from each other in the third direction D3 and may also separate the second active pads XO2 from each other in their direction D3.

Thereafter, a semiconductor fabrication method mentioned above may be used to fabricate a semiconductor device discussed with reference to FIGS. 7A to 7C.

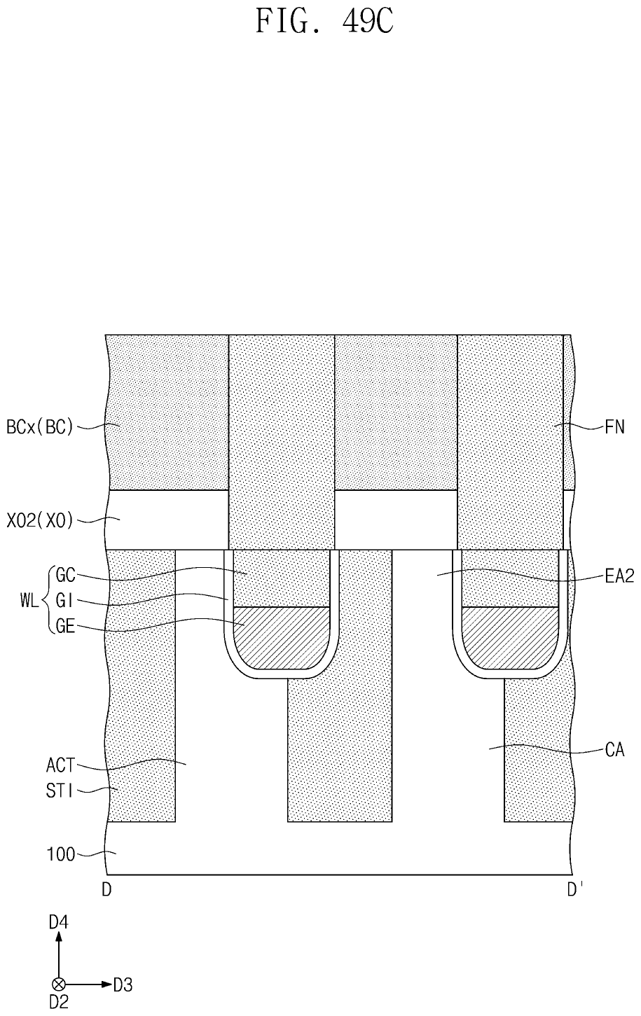

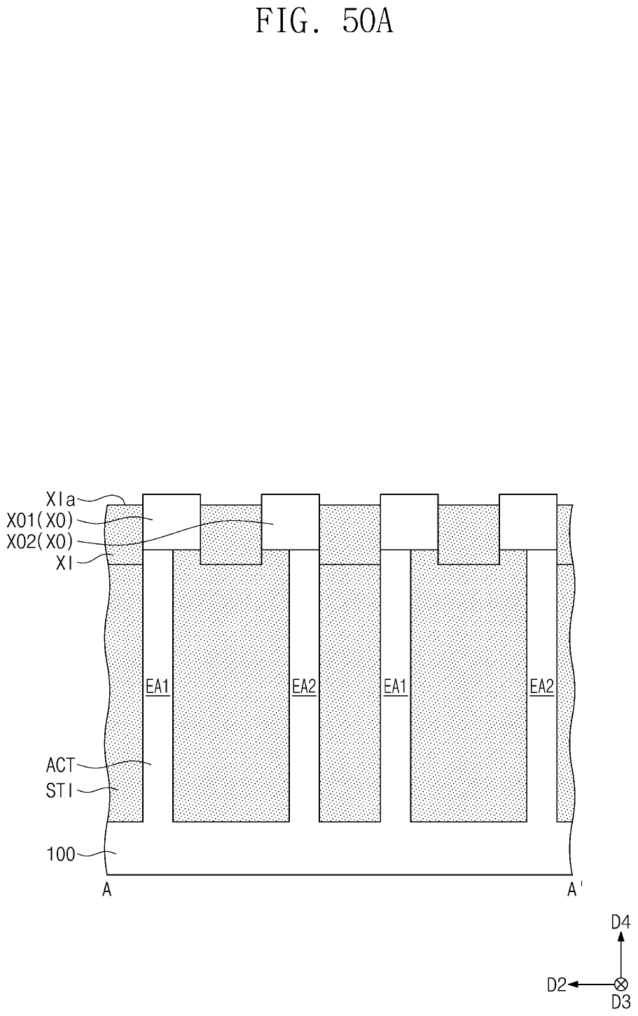

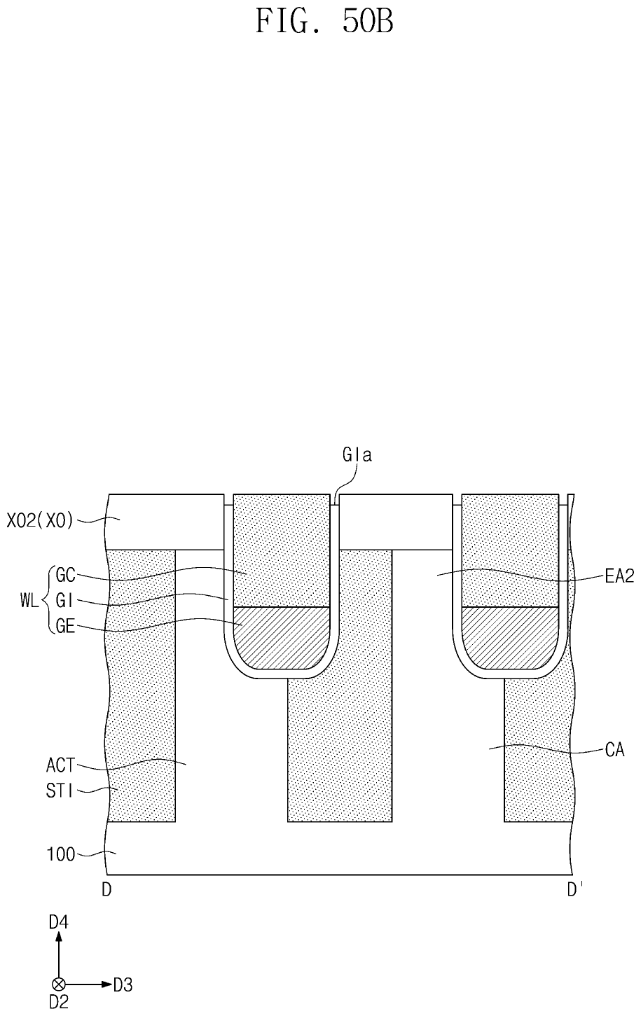

FIGS. 50A and 50B illustrate cross-sectional views showing a method of fabricating a semiconductor device according to some embodiments of the present inventive concepts.

Referring to FIGS. 50A and 50B, after the formation of the word line WL discussed with reference to FIGS. 31 to 32D, a removal process may be performed on an upper portion of each of the active dielectric pattern XI and the gate dielectric pattern GI. Each of the active dielectric pattern XI and the gate dielectric pattern GI may have an etch selectivity with respect to surrounding components (e.g., the gate capping pattern GC and the first and second active pads XO1 and XO2). Thus, although the active dielectric pattern XI and the gate dielectric pattern GI are each removed when the removal process is performed, the surrounding components may not be removed or may be less removed. Each of the first and second active pads XO1 and XO2 may be outwardly exposed at a top surface thereof and a lateral surface of an upper portion thereof.

The active dielectric pattern XI and the gate dielectric pattern GI may have top surfaces XIa and GIa that are located at a level lower than that of top surfaces XO1a and XO2a of the first and second active pads XO1 and XO2.

Afterwards, a semiconductor fabrication method discussed above may be used to fabricate a semiconductor device discussed with reference to FIGS. 8A and 8B.

FIGS. 51 to 54C illustrate plan and cross-sectional views showing a method of fabricating a semiconductor device according to some embodiments of the present inventive concepts.

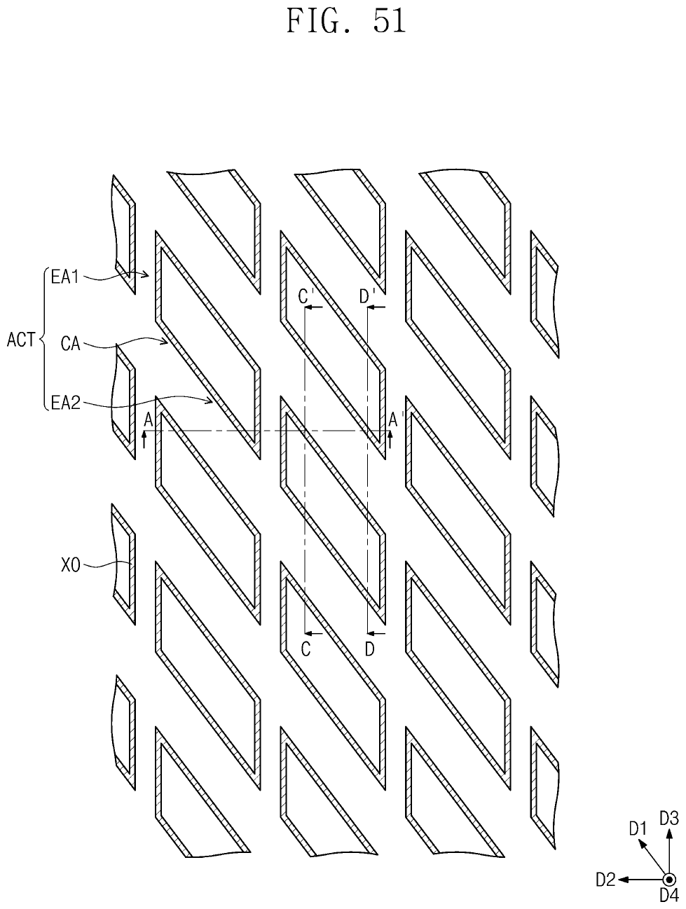

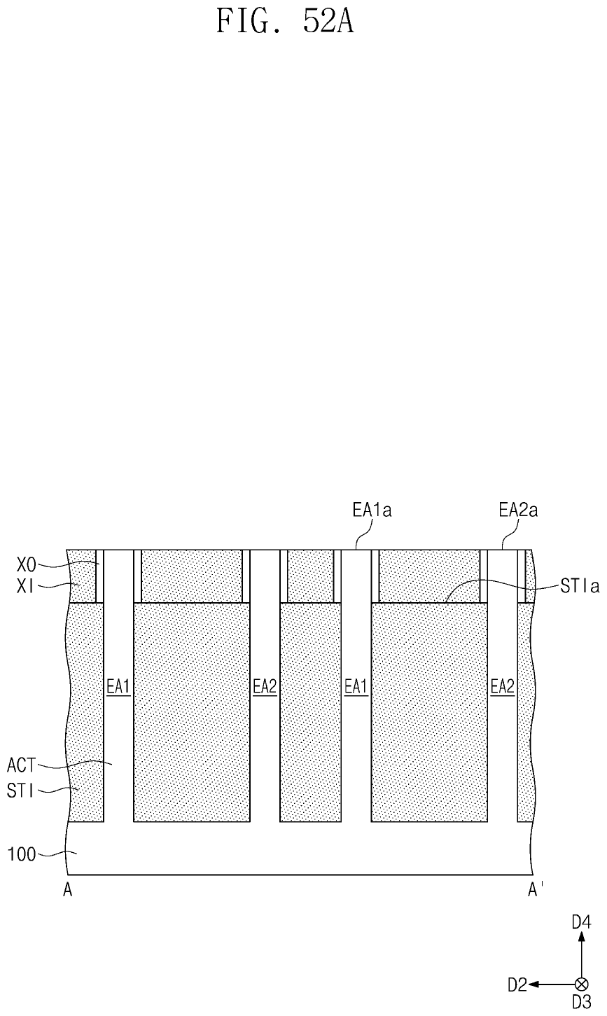

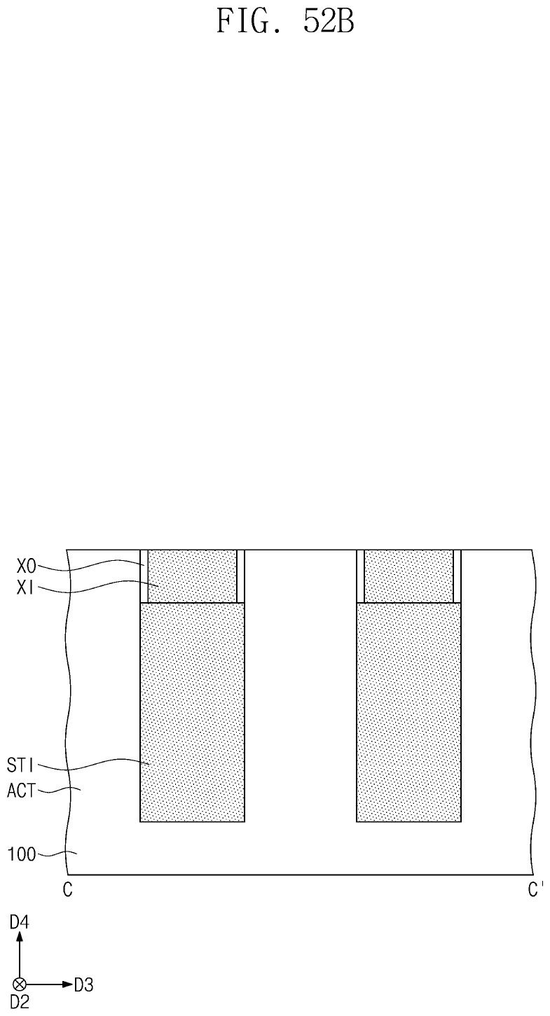

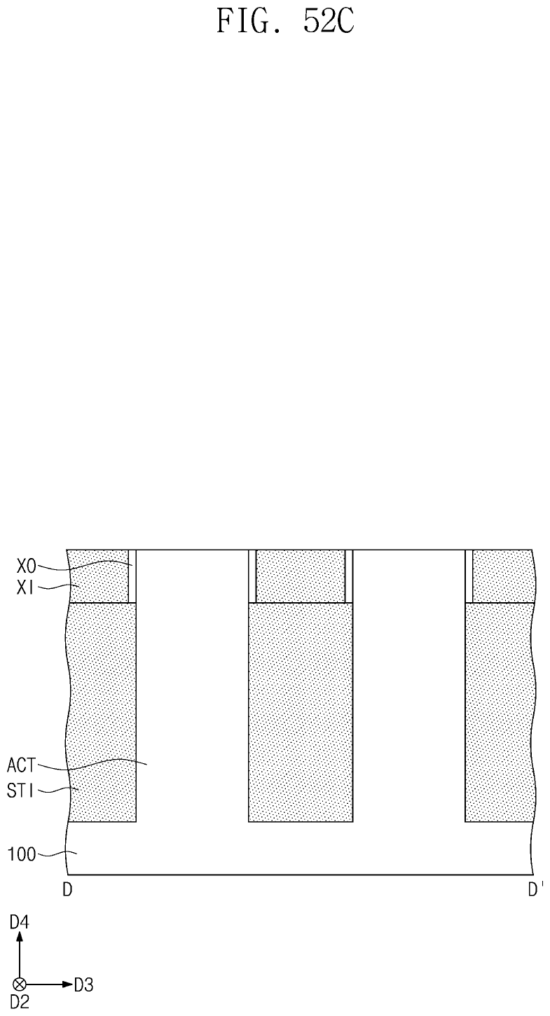

Referring to FIGS. 51 to 52C, after the formation of the active pattern ACT and the device isolation pattern STI discussed with reference to FIGS. 27 to 28D, a removal process may be performed on an upper portion of the device isolation pattern STI. Thus, the device isolation pattern STI may have an uppermost surface STIa located at a level lower than that of a top surface of the active pattern ACT, and an upper portion of the active pattern ACT may have a lateral surface that is outwardly exposed.

An active pad XO may be formed to surround the exposed lateral surface of the upper portion of the active pattern ACT. For example, the formation of the active pad XO may include forming an active pad layer (not shown) to conformally cover or overlap the top and lateral surfaces of the active pattern ACT and the uppermost surface STIa of the device isolation pattern STI, and removing the active pad layer on the top surface of the active pattern ACT and a top surface of the device isolation pattern STI. The active pad layer may not be removed on the lateral surface of the active pattern ACT, and the remaining portion of the active pad layer may constitute or form the active pad XO.

Afterwards, an active dielectric pattern XI may be formed on the device isolation pattern STI between the active patterns ACT. Top surfaces EA1a and EA2a of the first and second edge parts EA1 and EA2 of the active pattern ACT, a top surface of the active pad XO, and a top surface of the active dielectric pattern XI may be located at substantially the same level and coplanar with each other.

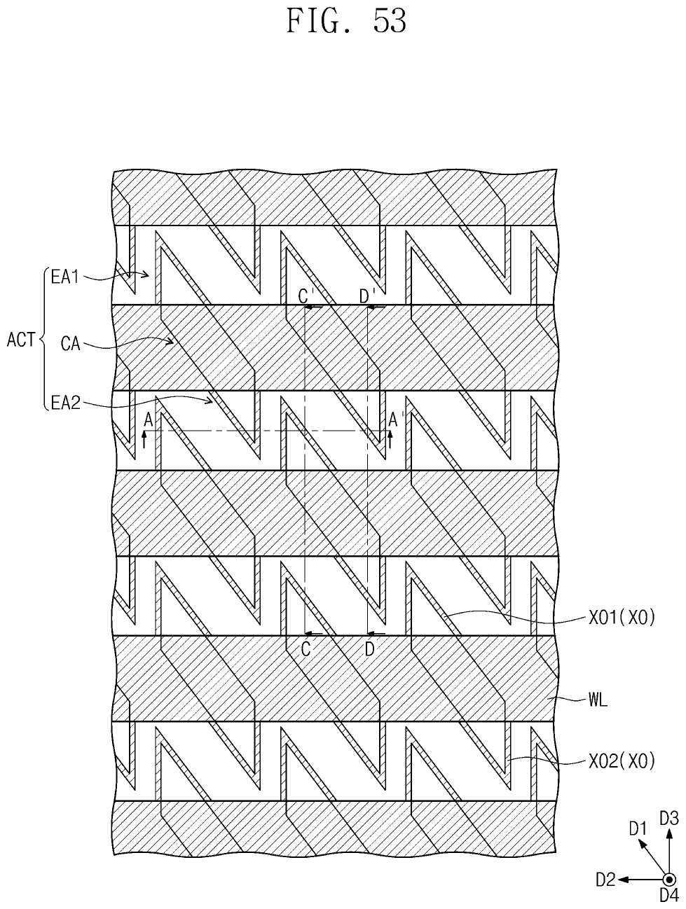

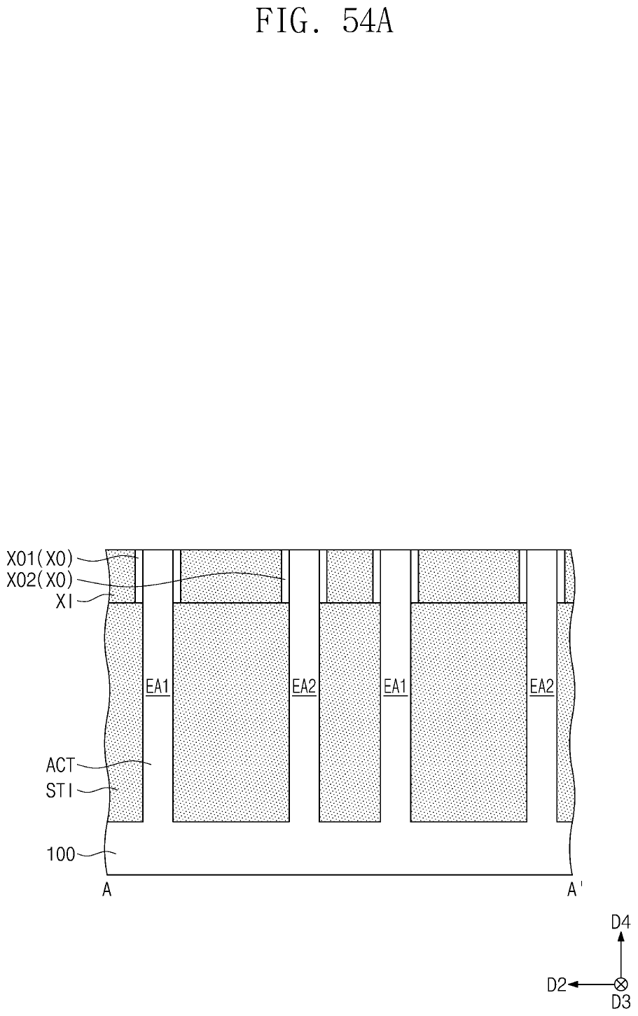

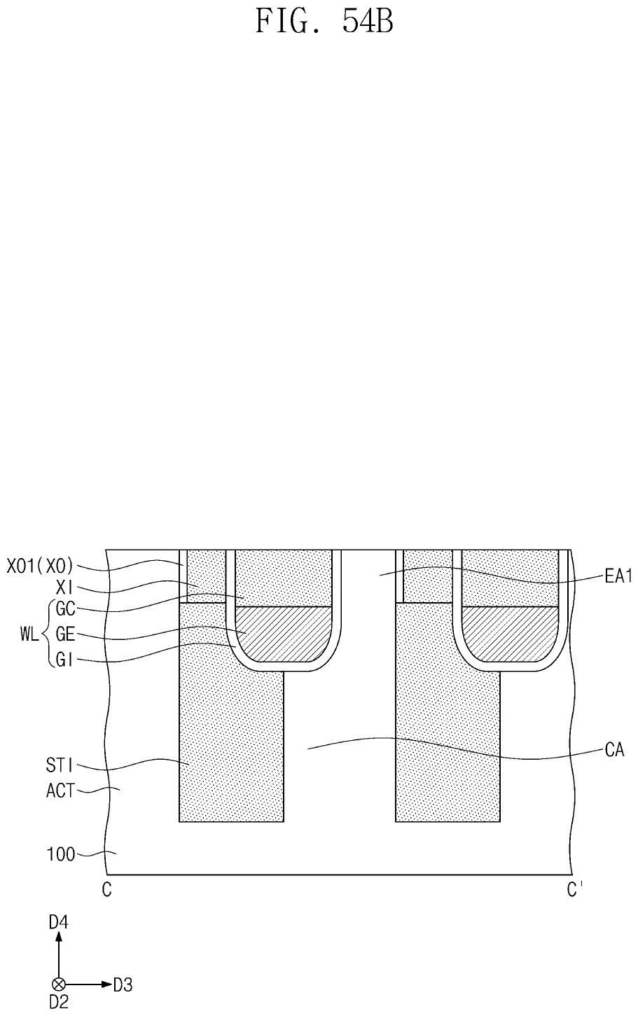

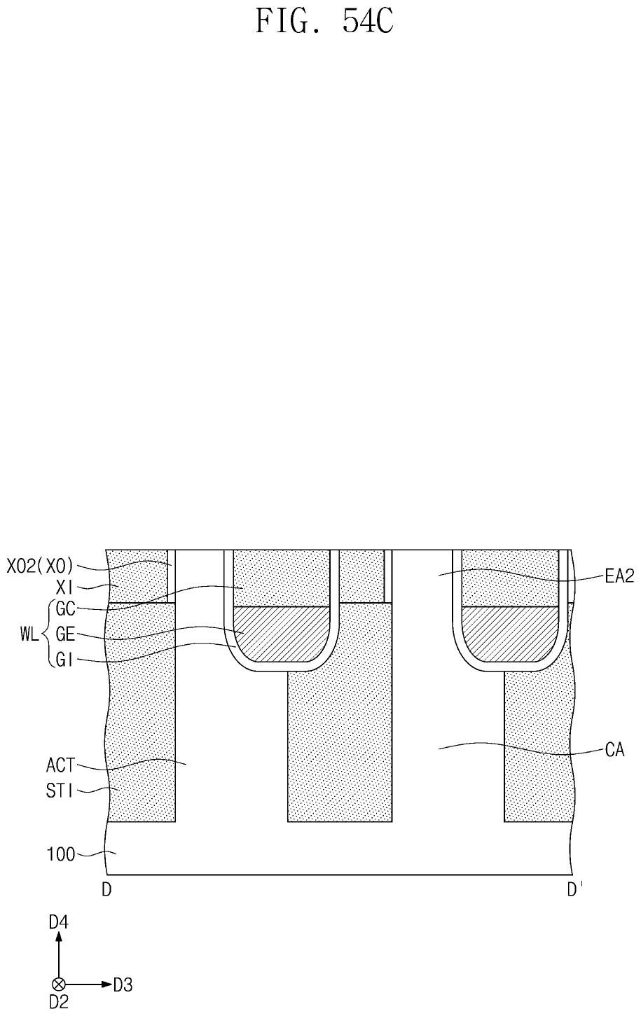

Referring to FIGS. 53 to 54D, a word line WL may be formed to run across the active pattern ACT, the device isolation pattern STI, and the active pad XO. The formation of the word line WL may be similar to that discussed with reference to FIGS. 31 to 32D. When the word line WL is formed, the active pad XO may be divided into first active pads XO1 and second active pads XO2.

Thereafter, a semiconductor fabrication method mentioned above may be used to fabricate a semiconductor device discussed with reference to FIGS. 9 to 10C.

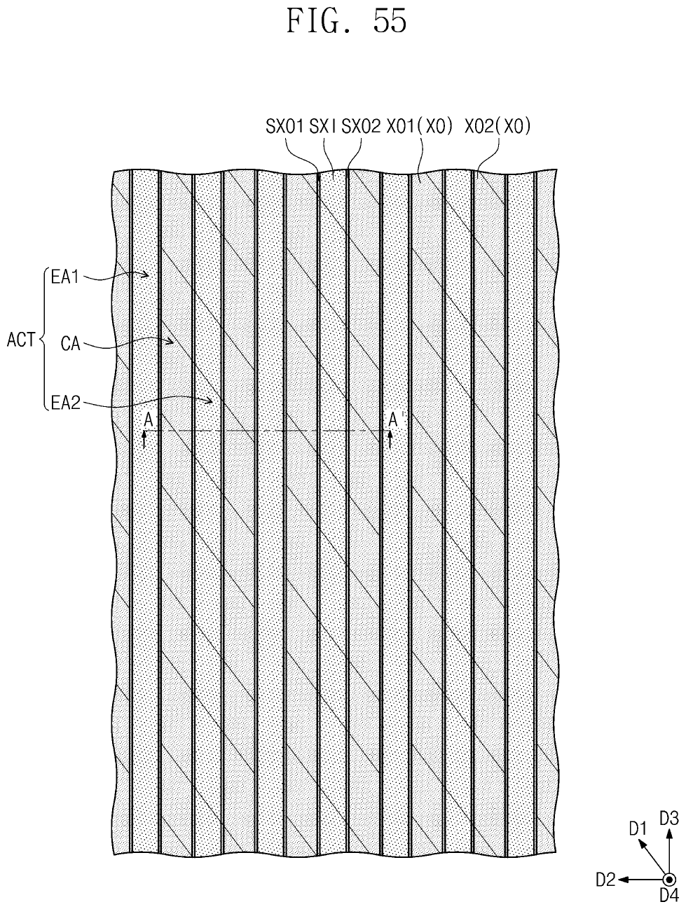

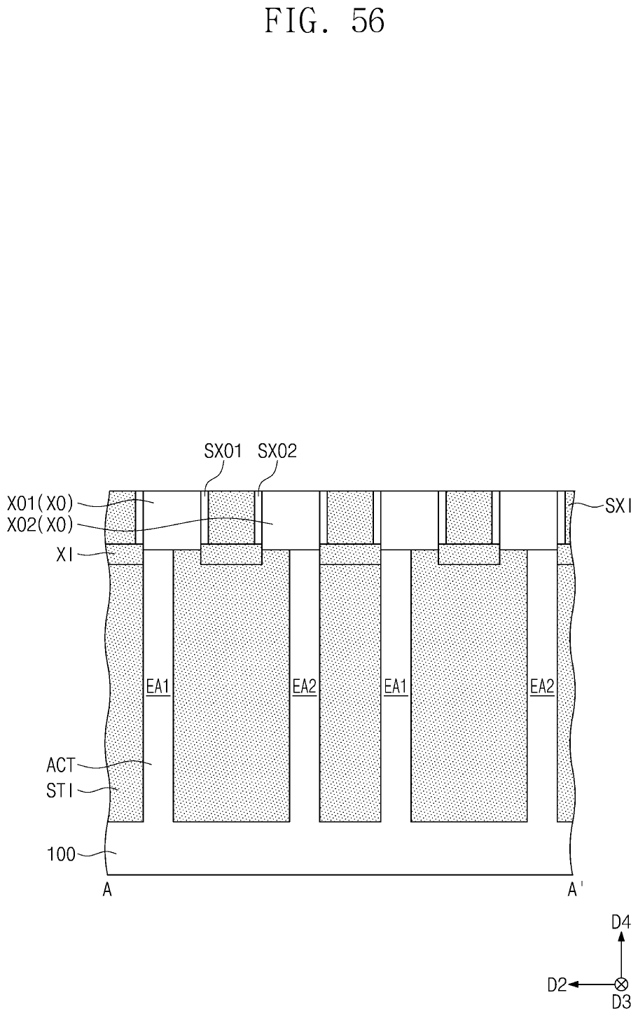

FIGS. 55 and 56 illustrate plan and cross-sectional views showing a method of fabricating a semiconductor device according to some embodiments of the present inventive concepts.

Referring to FIGS. 55 and 56, after the formation of the active dielectric pattern XI discussed with reference to FIGS. 29 to 30D, a removal process may be performed on an upper portion of the active dielectric pattern XI. Therefore, each of the first and second active pads XO1 and XO2 may have an outwardly exposed lateral surface.

A first active additional pad SXO1 may be formed to cover or overlap the exposed lateral surface of the first active pad XO1. The first active additional pad SXO1 may extend in the third direction D3 on a lateral surface of the first active pad XO1. A second active additional pad SXO2 may be formed to cover or overlap the exposed lateral surface of the second active pad XO2. The second active additional pad SXO2 may extend in the third direction D3 on the lateral surface of the second active pad XO2. For example, the formation of the first and second active additional pads SXO1 and SXO2 may include forming an active additional pad layer (not shown) to cover or overlap top surfaces and the exposed lateral surfaces of the first and second active pads XO1 and XO2 and a top surface of the active dielectric pattern XI, and removing the active additional pad layer to form the first and second active additional pads SXO1 and SXO2. An active additional dielectric pattern SXI may be formed on the active dielectric pattern XI between the first and second active additional pads SXO1 and SXO2.

Thereafter, a semiconductor fabrication method mentioned above may be used to fabricate a semiconductor device discussed with reference to FIGS. 11 to 12.

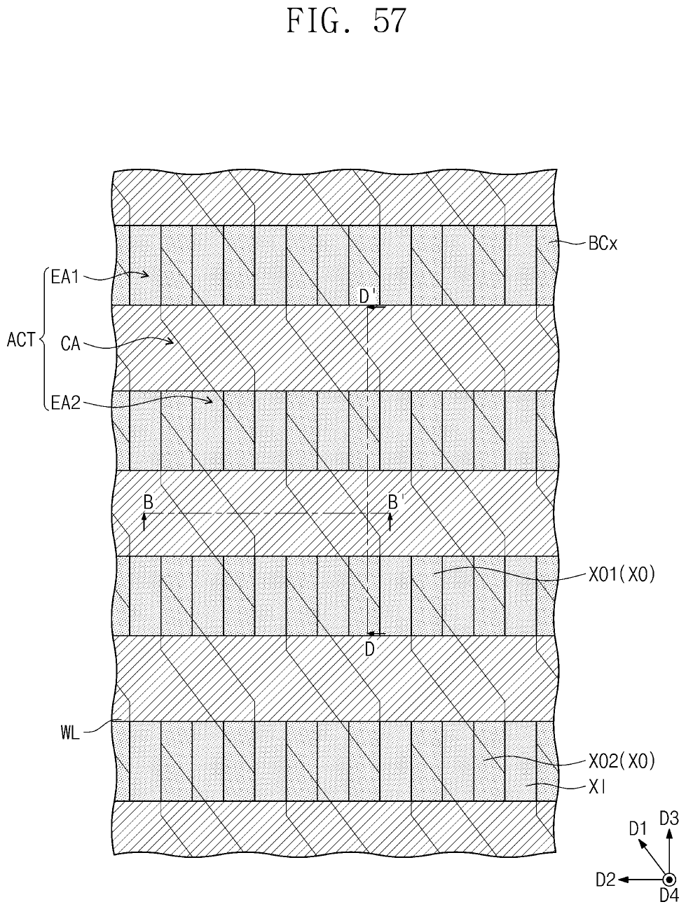

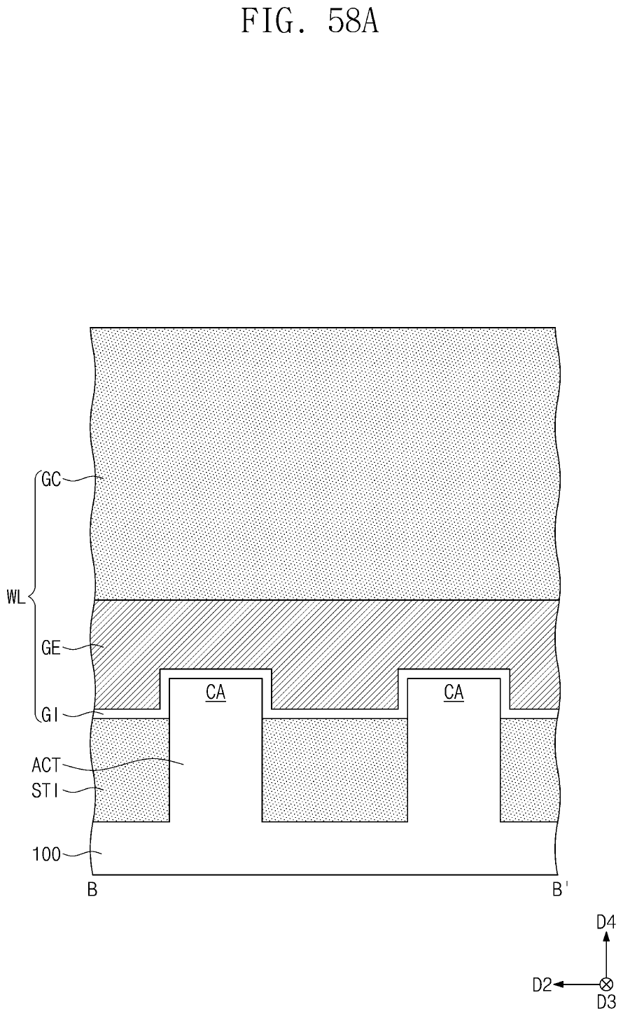

FIGS. 57 to 58B illustrate plan and cross-sectional views showing a method of fabricating a semiconductor device according to some embodiments of the present inventive concepts.

Referring to FIGS. 57 to 58B, after the formation of the active dielectric patterns XI discussed with reference to FIGS. 29 to 30D, a lower storage node contact layer may be formed on the front surface of the substrate 100 before a word line WL is formed.

Thereafter, a word line WL may be formed to run across the active pattern ACT and the device isolation pattern STI. The word line WL may be formed to penetrate the first active pads XO1, the second active pads XO2, and the lower storage node contact layer. Therefore, first active pads XO1 may be formed spaced apart from each other in the third direction D3, and second active pads XO2 may be formed spaced apart from each other in the third direction D3. In addition, a plurality of lower storage node contacts BCx may be formed which are spaced apart from each other in the third direction D3 and each of which extends in the second direction D2. The formation of the word line WL may be similar to that discussed with reference to FIGS. 31 to 32D.

Thereafter, a semiconductor fabrication method mentioned above may be used to fabricate a semiconductor device discussed with reference to FIGS. 13 to 14B.

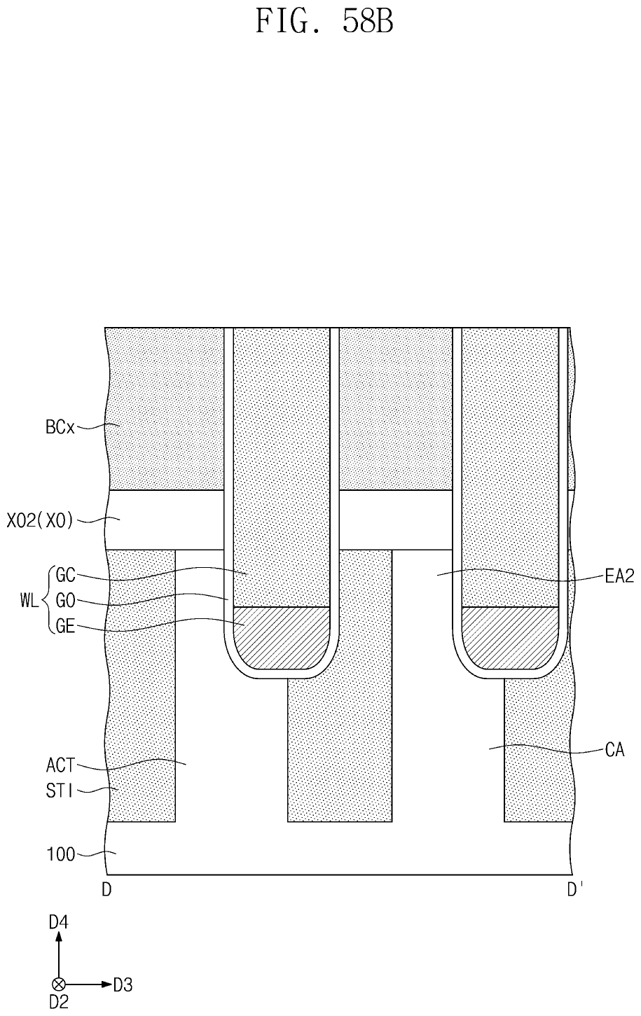

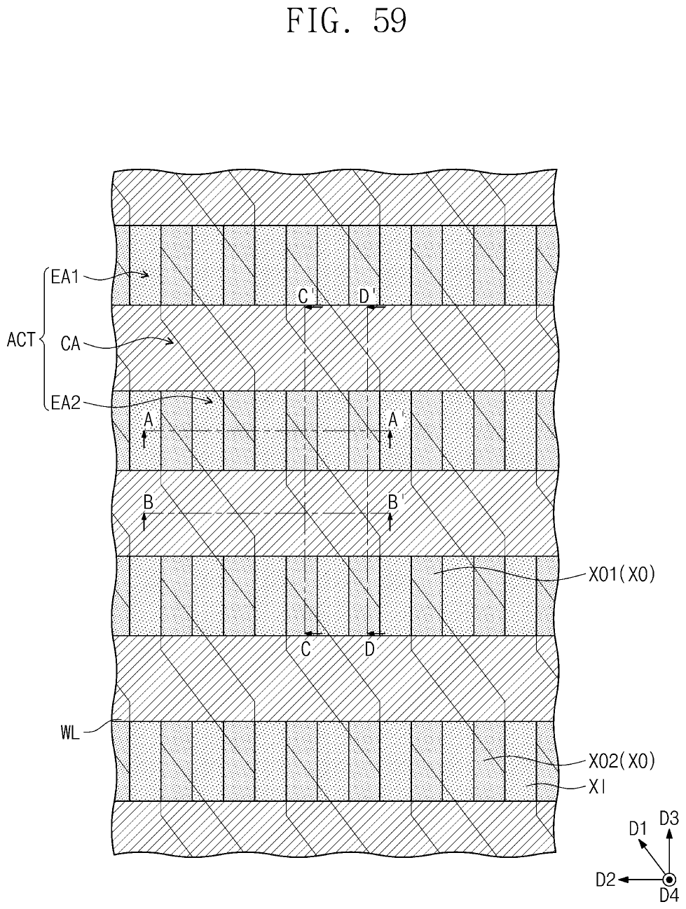

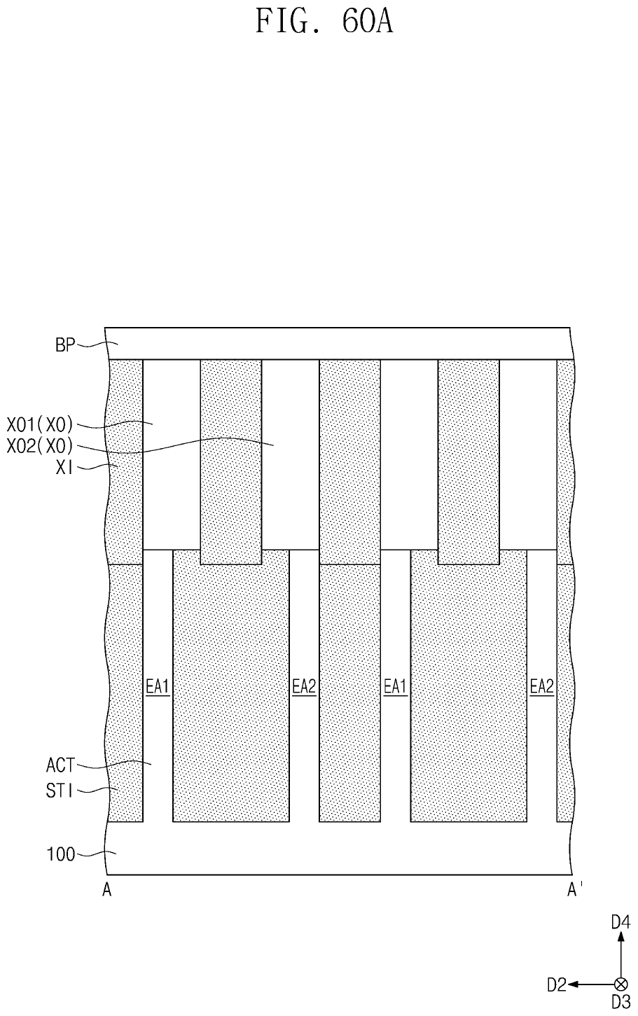

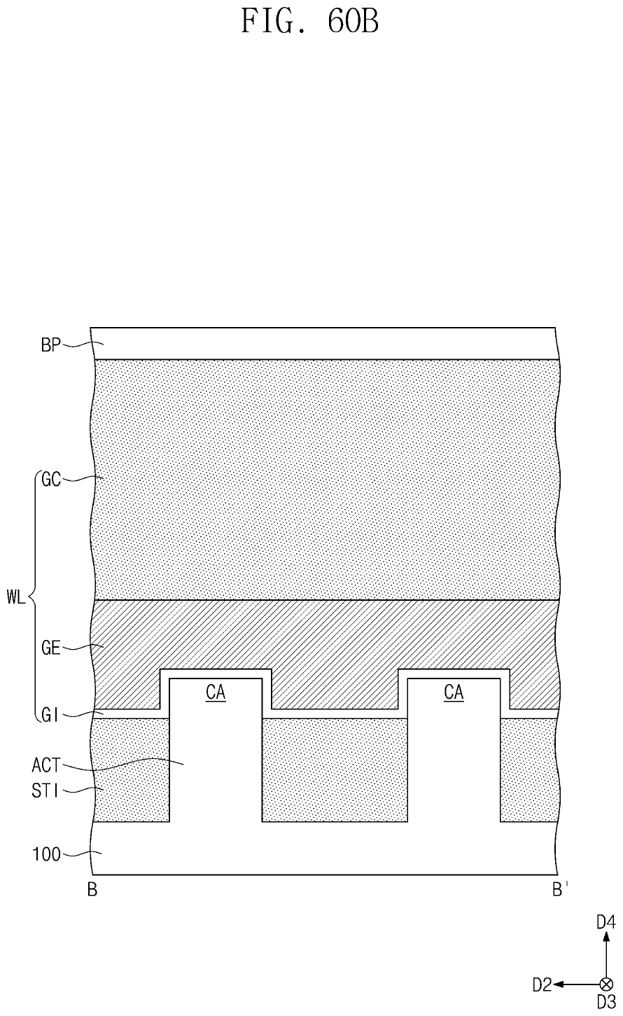

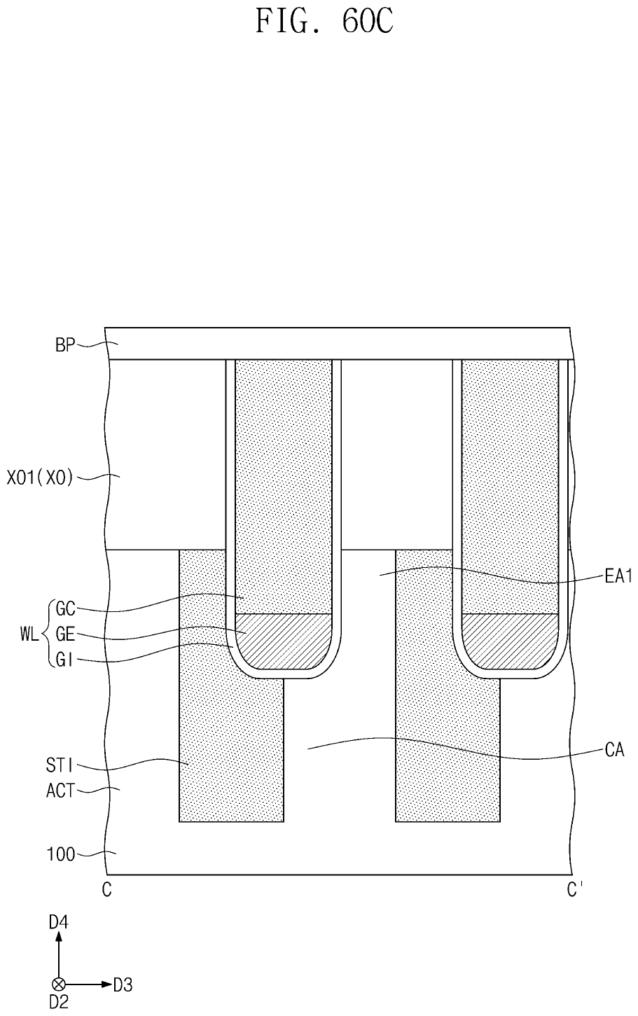

FIGS. 59 to 60D illustrate plan and cross-sectional views showing a method of fabricating a semiconductor device according to some embodiments of the present inventive concepts.

Referring to FIGS. 59 to 60D, after the formation of the word line WL discussed with reference to FIGS. 31 to 32D, there may be omitted the formation of the lower storage node contact BCx discussed with reference to FIGS. 31 to 32D, and a buffer pattern BP may be formed to cover or overlap the front surface of the substrate 100. First and second active pads XO1 and XO2 and an active dielectric pattern XI may each be formed to have a top surface located at a level higher than that discussed with reference to FIGS. 29 to 30D.

After the formation of the buffer pattern BP, with no separate process for forming the lower storage node contact BCx, a semiconductor fabrication method mentioned above may be used to sequentially form a bit line BL, a bit-line capping pattern BCP, a mold pattern MP, an upper storage node contact BCy, and a data storage pattern DSP, which may result in the formation of a semiconductor device discussed with reference to FIGS. 15 to 16D.

In some embodiments, after the step of forming the buffer pattern BP, a semiconductor fabrication method for forming a semiconductor device discussed with reference to FIGS. 17 to 18D may be partially different from the semiconductor fabrication method discussed above.

Referring to FIGS. 17 to 18D, a bit-line trench region BTR, a bit-line spacer BSP, a bit line BL, a bit-line capping pattern BCP, and a mold pattern MP may be sequentially formed, and each of which may be formed similarly to that discussed with reference to FIGS. 33 to 34D.

After that, contact holes CH may be formed between the bit lines BL that neighbor each other in the second direction D2. When the contact holes CH are formed, an upper portion of each of the second active pad XO2 and the active dielectric pattern XI may be recessed to a certain depth and outwardly exposed. For example, the contact holes CH in a certain queue may be disposed side by side along the second direction D2, and the contact holes CH in another queue may be disposed side by side along the third direction D3.

An upper storage node contact BCy, a second silicide pattern SC, and a landing pad spacer LSP may be formed in the contact hole CH, and each of which may be formed similarly to that discussed with reference to FIGS. 1A and 2A to 2D.

Thereafter, a lower landing pad LPx may be formed to partially or fully fill an unoccupied portion of the contact hole CH. The formation of the lower landing pad LPx may be similar to the formation of the landing pad LP discussed with reference to FIGS. 1A and 2A to 2D.

After that, upper landing pads LPy may be formed on the lower landing pads LPx. The formation of the upper landing pads LPy may include sequentially forming an upper landing pad layer (not shown) and mask patterns (not shown) to cover or overlap top surfaces of the lower landing pads LPx, and using the mask patterns as an etching mask to perform an anisotropic etching process in which the landing pad layer is removed to form a plurality of upper landing pads LPy.

Thereafter, a filling pattern FIL may be formed on a region where the landing pad layer is removed. The filling pattern FIL may be formed to surround each of the upper landing pads LPy. A data storage pattern DSP may be formed on each of the upper landing pads LPy.

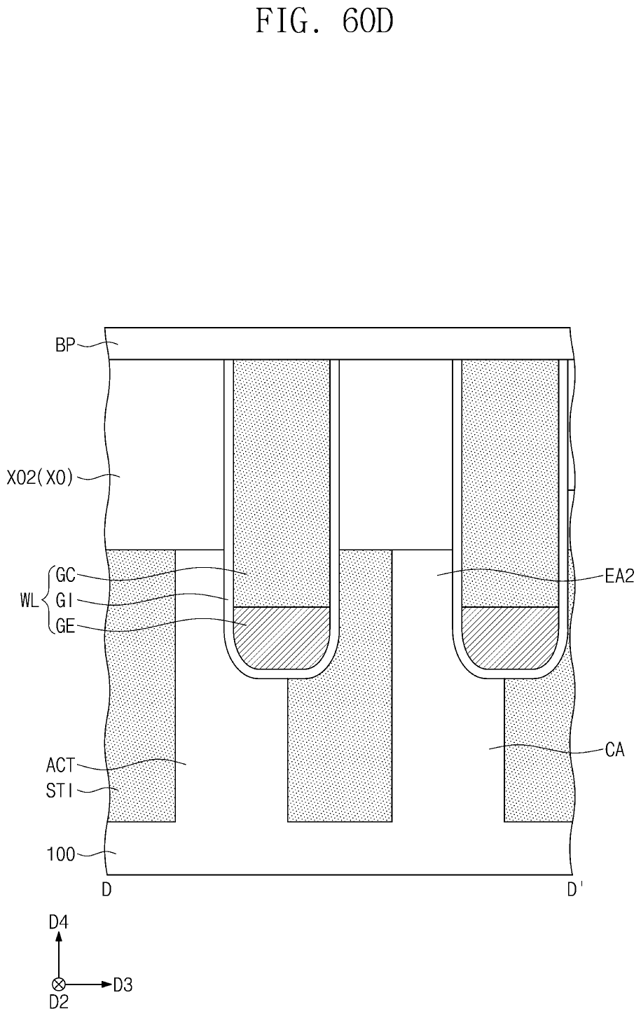

FIGS. 61 to 64D illustrate plan and cross-sectional views showing a method of fabricating a semiconductor device according to some embodiments of the present inventive concepts.

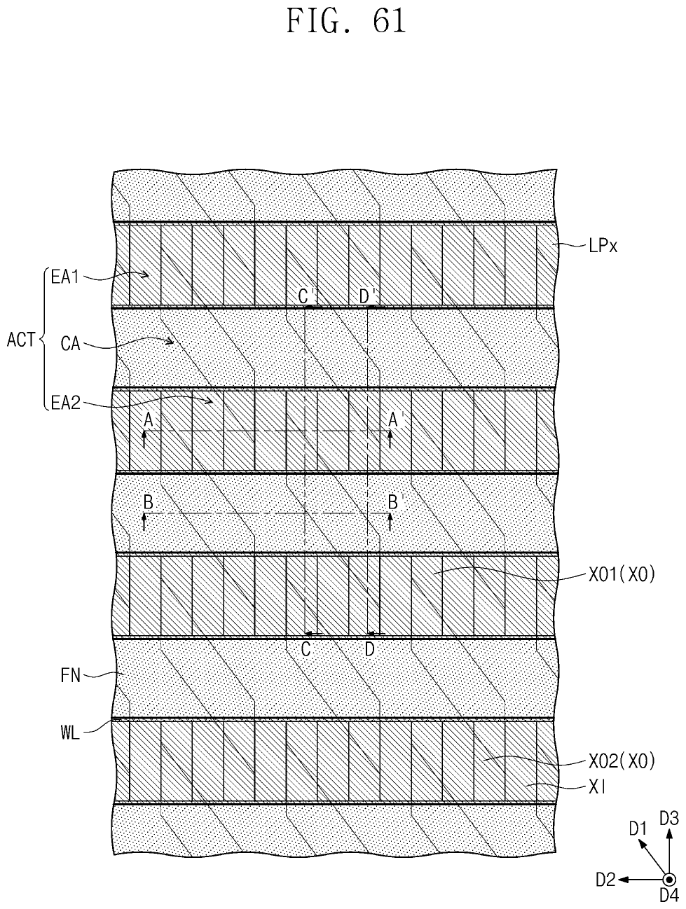

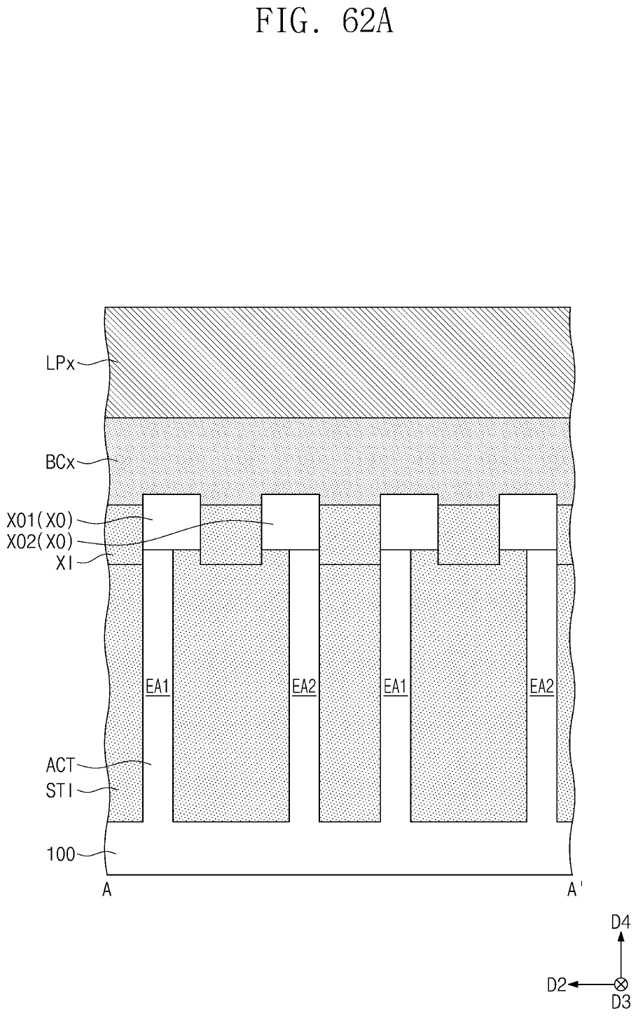

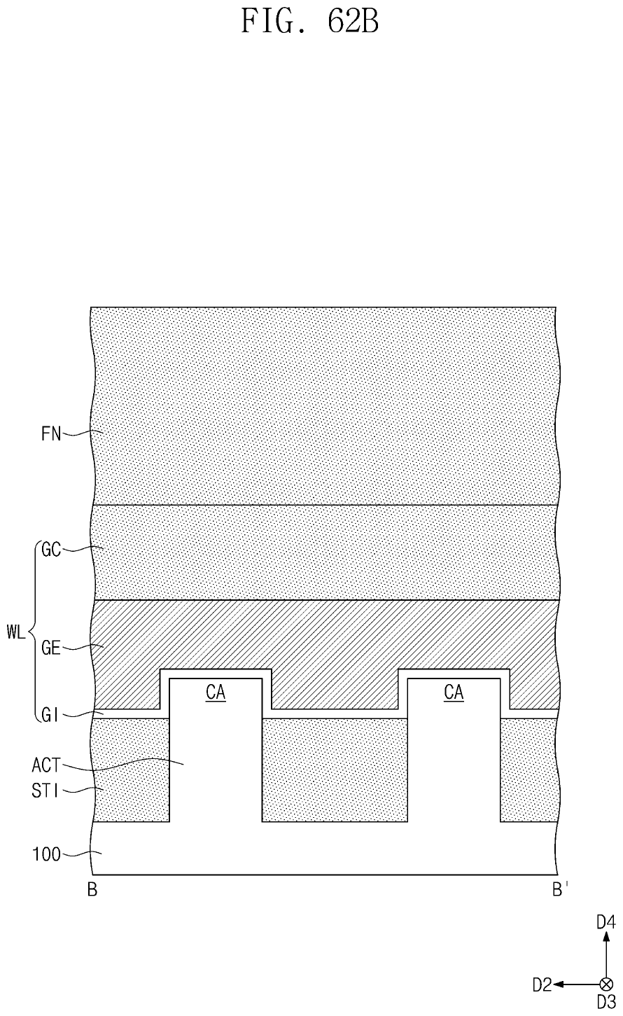

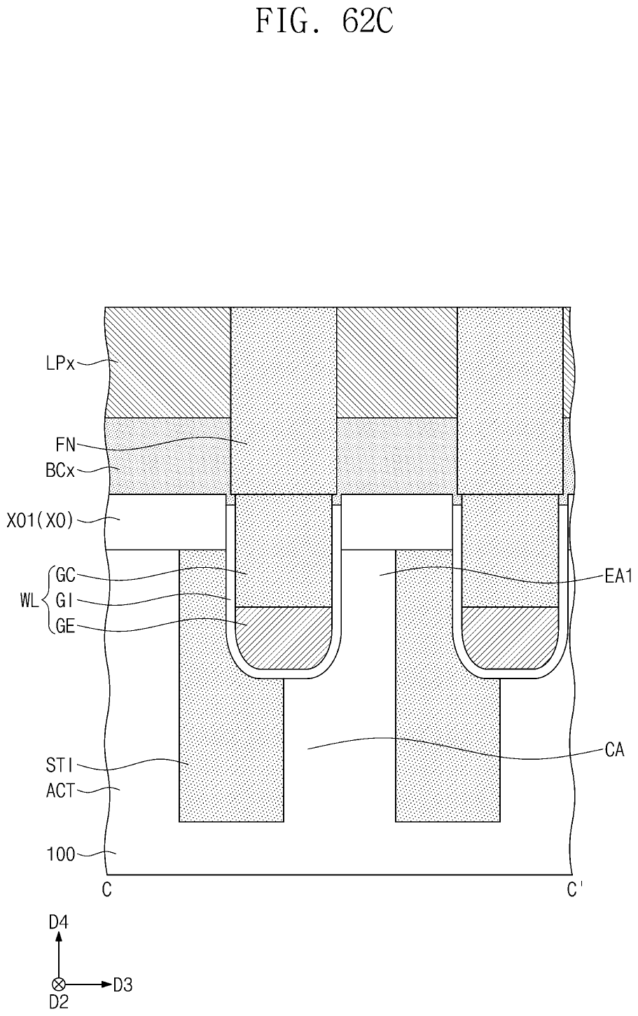

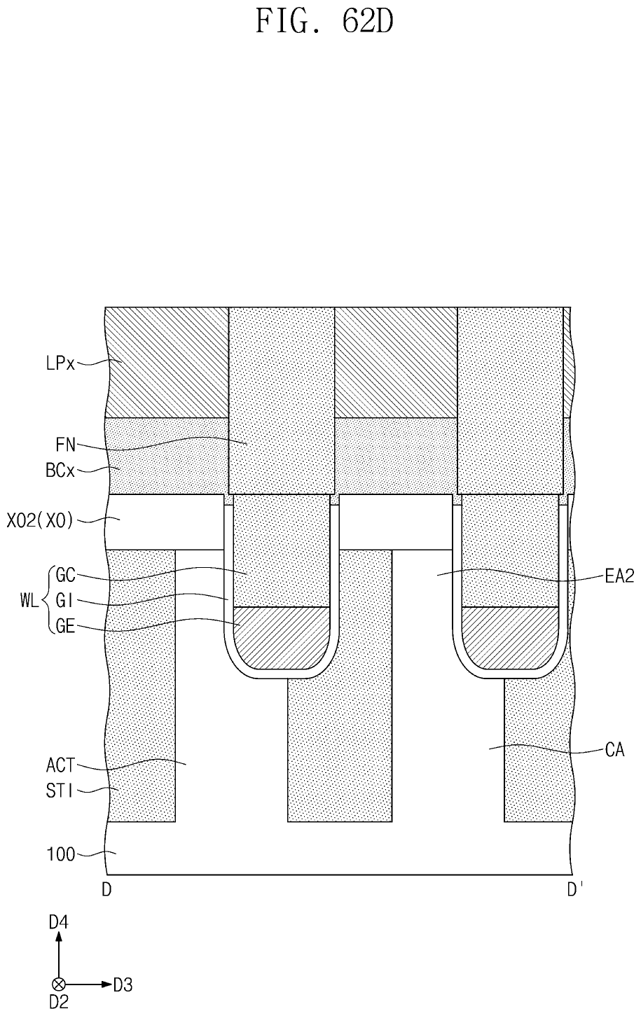

Referring to FIGS. 61 to 62D, after the removal of each of the active dielectric pattern XI and the gate dielectric pattern GI discussed with reference to FIGS. 50A and 50B, a lower storage node contact BCx and a lower landing pad LPx may be formed sequentially stacked on the substrate 100.

A fence pattern FN may be formed to extend along the second direction D2 on the word line WL. The fence pattern FN may be formed to penetrate the lower storage node contact BCx and the lower landing pad LPx. Therefore, the lower storage node contacts BCx may be spaced apart from each other in the third direction D3, and the lower landing pads LPx may be spaced apart from each other in the third direction D3.

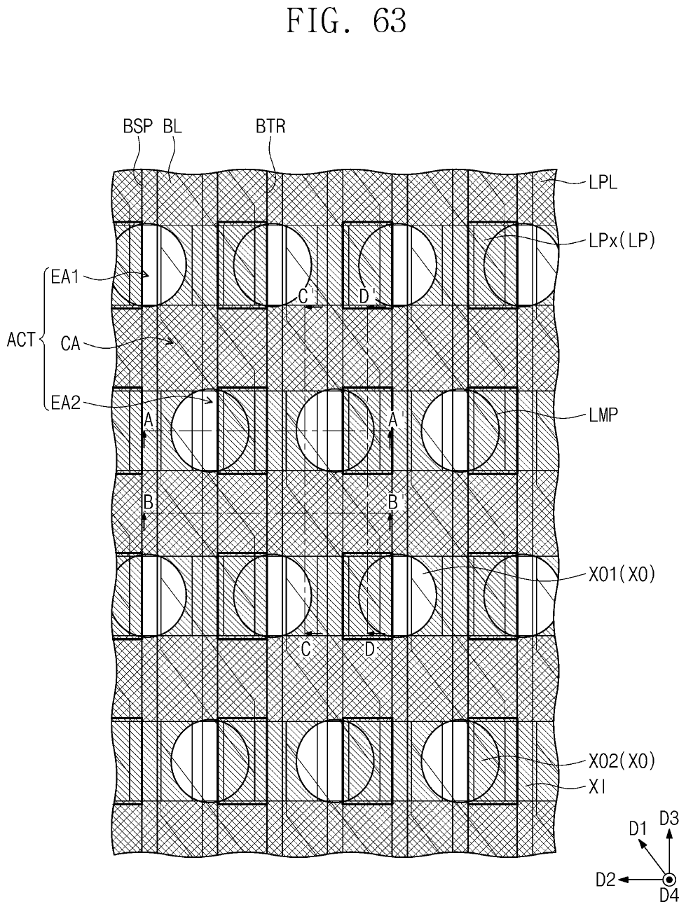

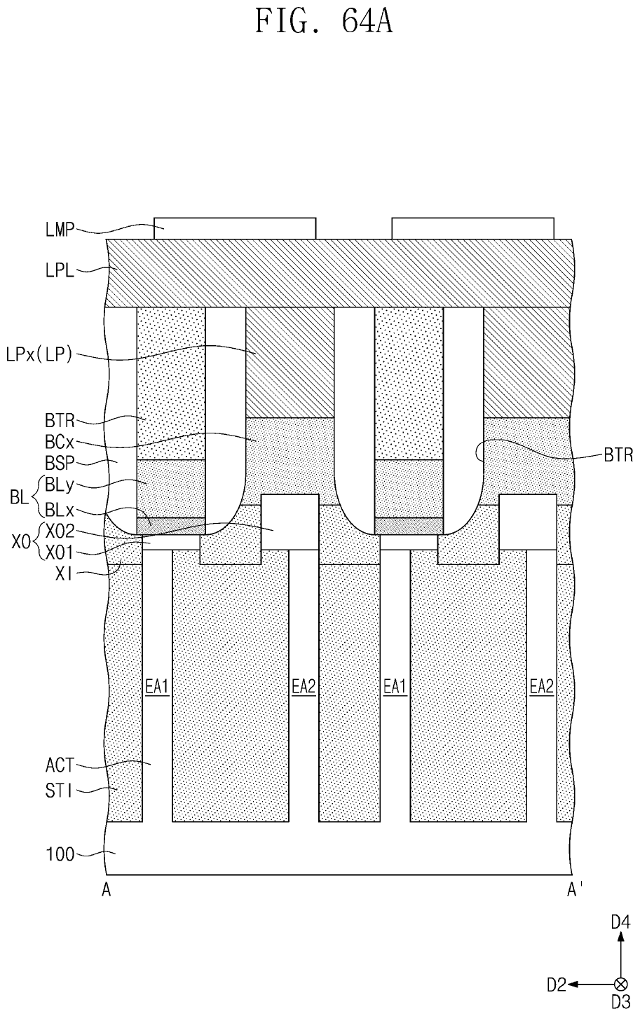

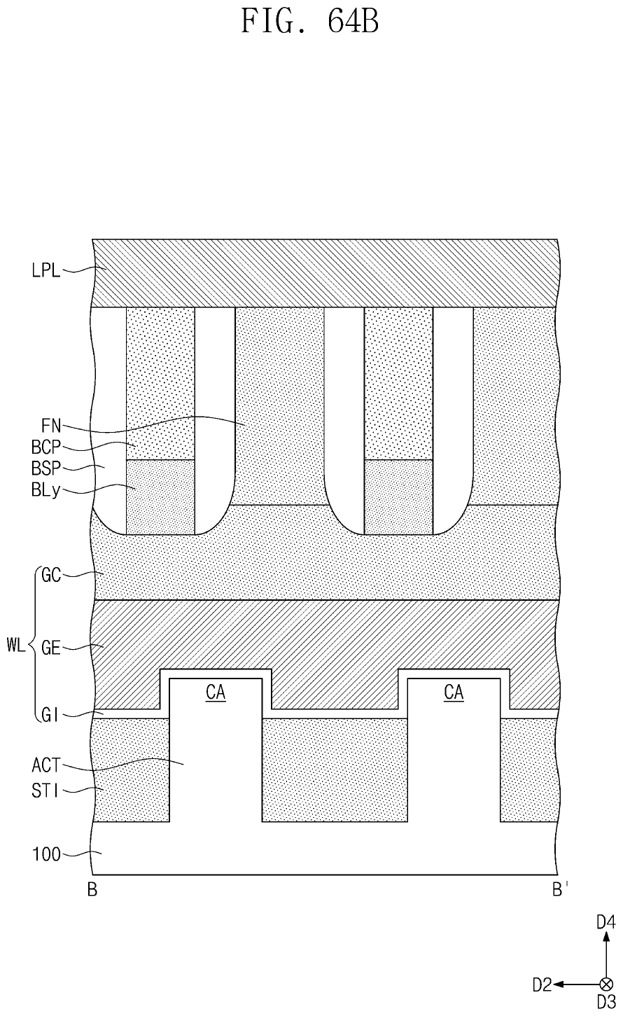

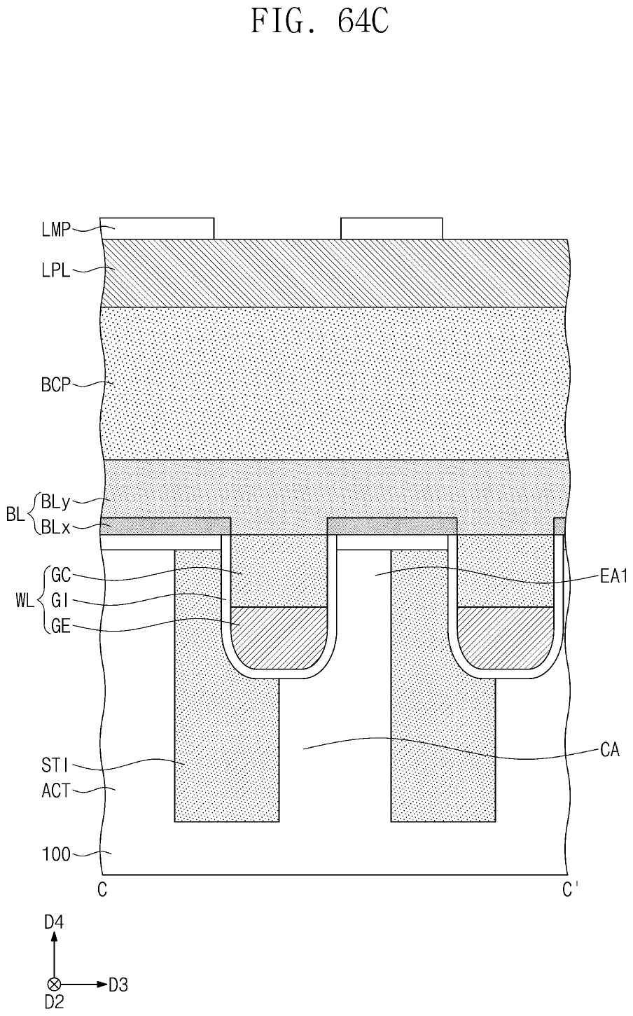

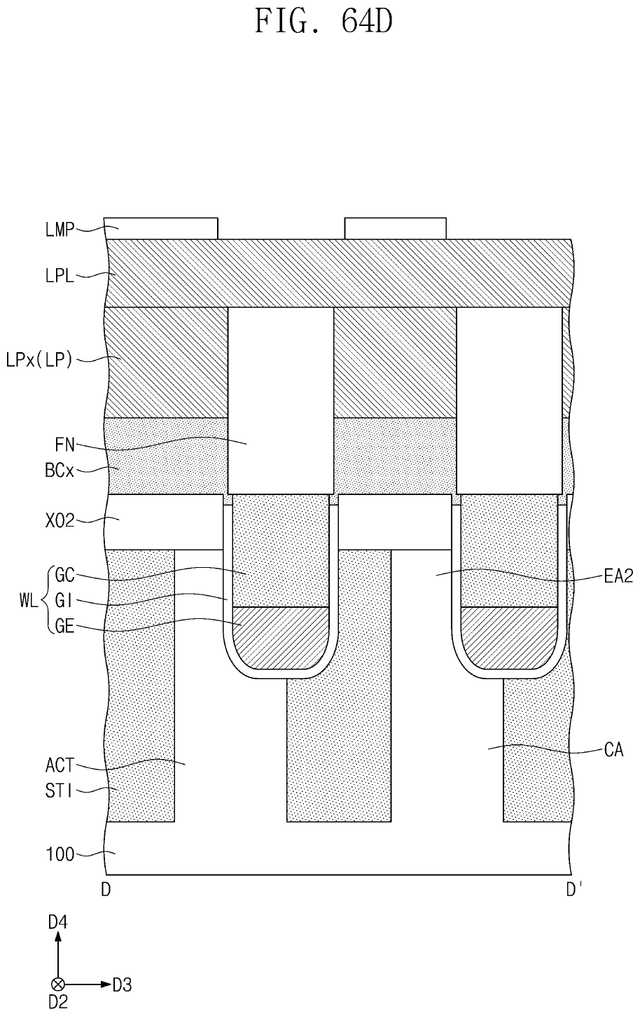

Referring to FIGS. 63 to 64D, there may be omitted the formation of the buffer pattern BP discussed with reference to FIGS. 31 to 32D. A bit-line trench region BTR, a bit-line spacer BSP, a bit line BL, and a bit-line capping pattern BCP may be sequentially formed, and each of which may be formed similarly to that discussed with reference to FIGS. 33 to 34D.

Afterwards, there may be omitted the formation of the mold pattern MP discussed with reference to FIGS. 33 to 34D. In addition, there may be omitted the formation of the upper storage node contact BCy, the second silicide pattern SC, and the landing pad spacer LSP discussed with reference to FIGS. 1A and 2A to 2D.

An upper landing pad layer LPL may be formed to cover or overlap the front surface of the substrate 100. Landing pad mask patterns LMP may be formed to the upper landing pad layer LPL. When viewed in plan, the landing pad mask patterns LMP may have positions similar to those of the contact holes CH discussed with reference to FIGS. 1A and 2A to 2D. The landing pad mask patterns LMP may be disposed linearly along the second direction D2, and may be arranged in a zigzag fashion along the third direction D3.

Referring to FIGS. 19 to 20D, the landing pad mask patterns LMP may be used as an etching mask to perform an etching process in which the upper landing pad layer LPL is etched to form a plurality of upper landing pads LPy. The etching process may include an anisotropic etching process.

Thereafter, a filling pattern FIL may be formed on a region where the upper landing pad LPy is removed. The filling pattern FIL may be formed to surround each of the upper landing pads LPy. A data storage pattern DSP may be formed on each of the upper landing pads LPy.

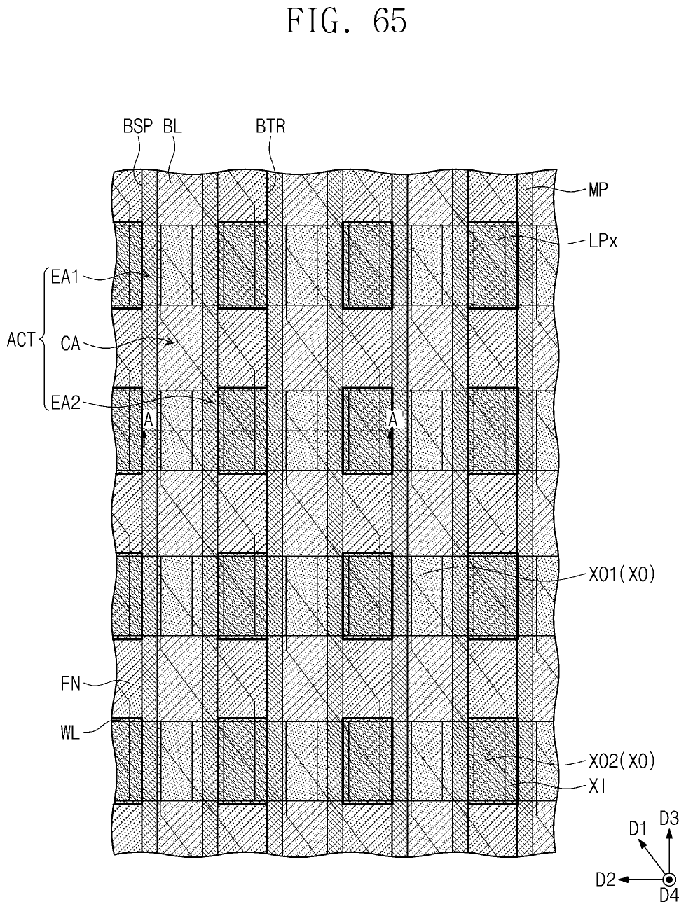

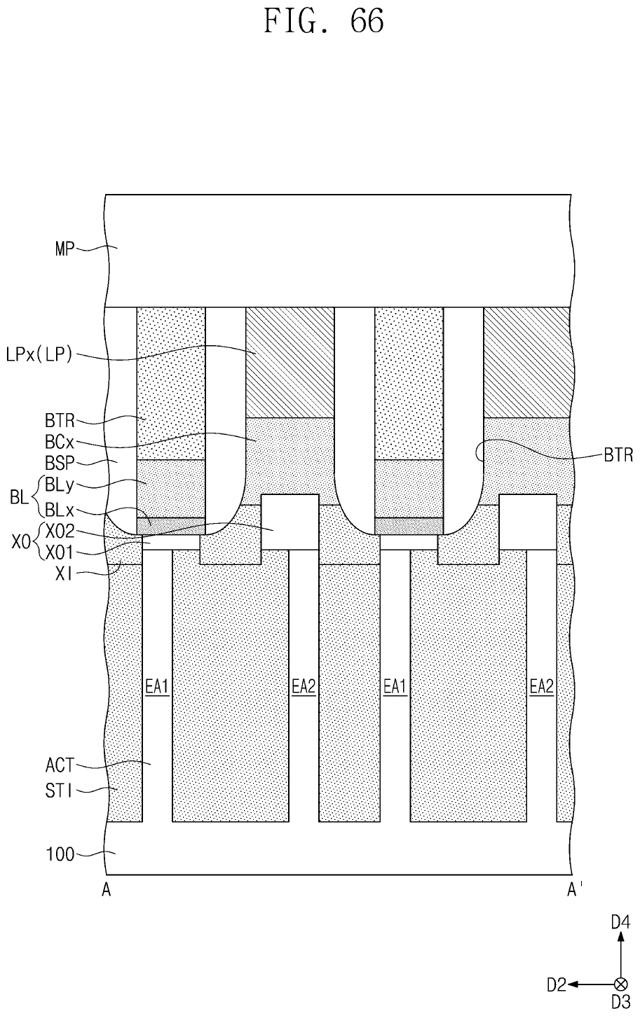

FIGS. 65 and 66 illustrate plan and cross-sectional views showing a method of fabricating a semiconductor device according to some embodiments of the present inventive concepts.

Referring to FIGS. 65 and 66, after the formation of the bit-line capping pattern BCP discussed with reference to FIGS. 63 to 64D, a mold pattern MP may be formed. For example, the formation of the mold pattern MP may be similar to that discussed with reference to FIGS. 33 to 34D.

Referring to FIGS. 19 and 21, contact holes CH may be formed to penetrate the mold pattern MP. The formation of the contact holes CH may be similar to that discussed with reference to FIGS. 1A and 2A to 2D.

Afterwards, there may be omitted the formation of the upper storage node contacts BCy, the second silicide patterns SC, and the landing pad spacers LSP discussed with reference to FIGS. 1A and 2A to 2D.

Upper landing pads LPy may be formed to partially or fully fill unoccupied portions of the contact holes CH. For example, the formation of the upper landing pads LPy may include forming an upper landing pad layer (not shown) to partially or fully fill the unoccupied portions of the contact holes CH and to cover or overlap a top surface of the mold pattern MP, and removing an upper portion of the upper landing pad layer to form the upper landing pads LPy that are separated from each other. The removal of the upper portion of the upper landing pad layer may include performing a chemical mechanical polishing process on the upper landing pad layer. A data storage pattern DSP may be formed on each of the upper landing pads LPy.

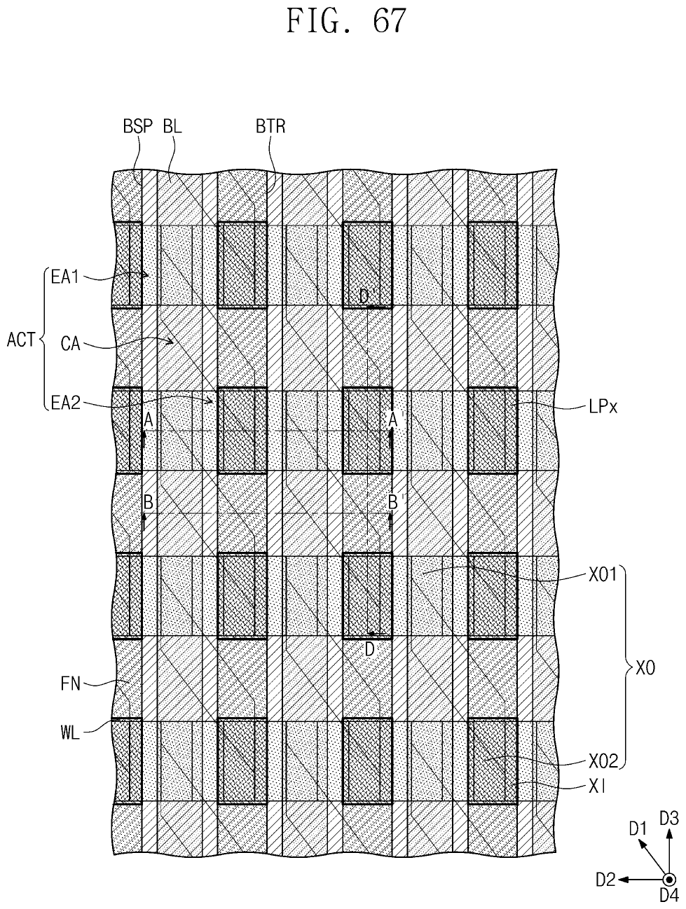

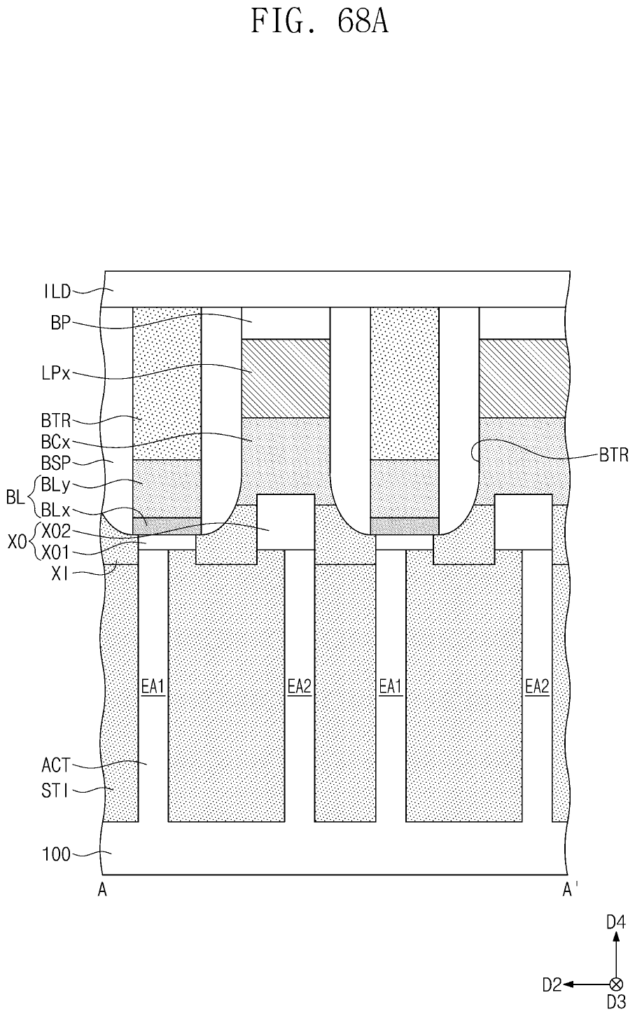

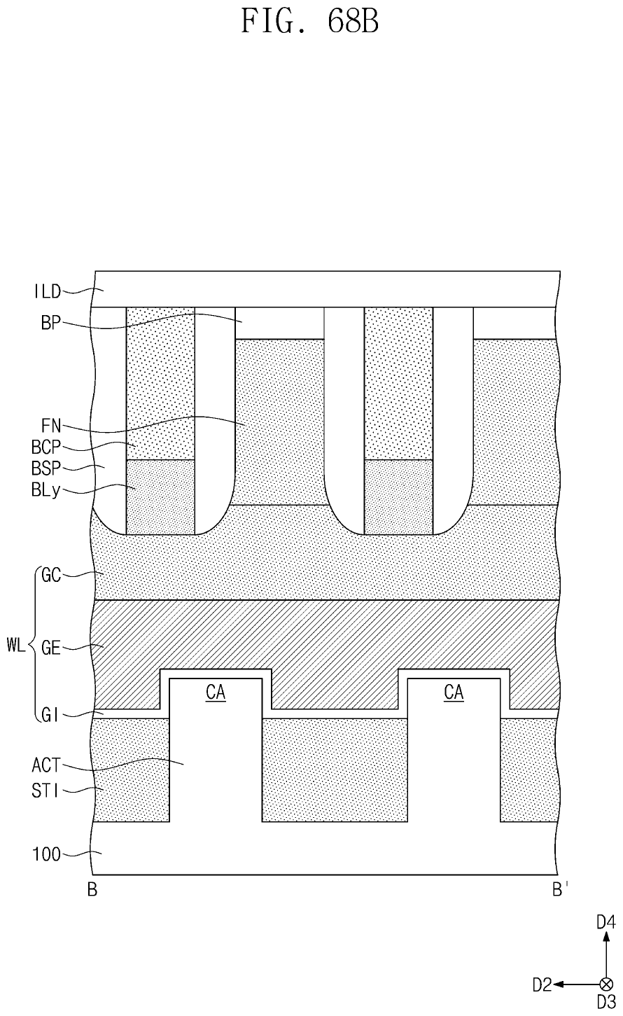

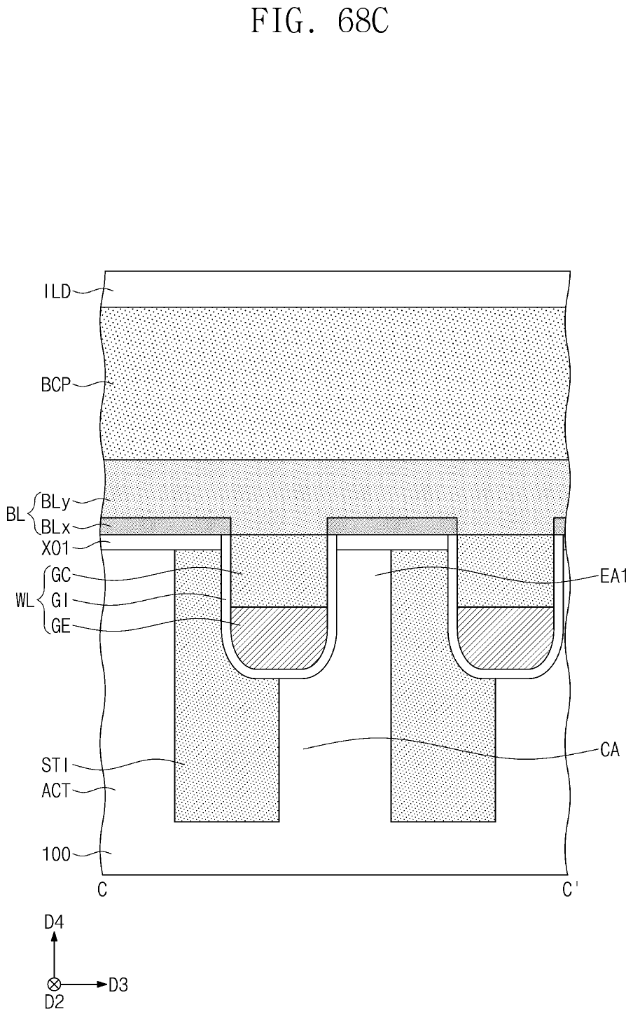

FIGS. 67 to 68D illustrate plan and cross-sectional views showing a method of fabricating a semiconductor device according to some embodiments of the present inventive concepts.

Referring to FIGS. 67 to 68D, after the formation of the lower landing pads LPx discussed with reference to FIGS. 61 to 62D, a buffer pattern BP may be formed on the lower landing pads LPx.

A bit-line trench region BTR, a bit-line spacer BSP, a bit line BL, and a bit-line capping pattern BCP may be sequentially formed, and each of which may be formed similarly to that discussed with reference to FIGS. 33 to 34D. There may be omitted the formation of the mold pattern MP discussed with reference to FIGS. 33 to 34D. An interlayer dielectric layer ILD may be formed on the front surface of the substrate 100.

Referring to FIGS. 22 to 23D, contact holes CH may be formed to penetrate the interlayer dielectric layer ILD. The formation of the contact holes CH may be similar to that discussed with reference to FIGS. 1A and 2A to 2D.

There may be omitted the formation of the upper storage node contact BCy, the second silicide pattern SC, and the landing pad spacer LSP discussed with reference to FIGS. 1A and 2A to 2D.

Bottom electrodes BE may be formed on the contact holes CH. The formation of the bottom electrodes BE may include forming a bottom electrode layer (not shown) to partially or fully fill the contact holes CH and to cover or overlap a top surface of the interlayer dielectric layer ILD, and removing the bottom electrode layer to form the bottom electrodes BE. The bottom electrode BE may include a lower part BEx and an upper part BEy.

A dielectric layer DL may be formed to conformally cover or overlap the top surface of the interlayer dielectric layer ILD and the upper parts BEy of the bottom electrodes BE. A top electrode TE may be formed between and on the upper parts BEy of the bottom electrodes BE.

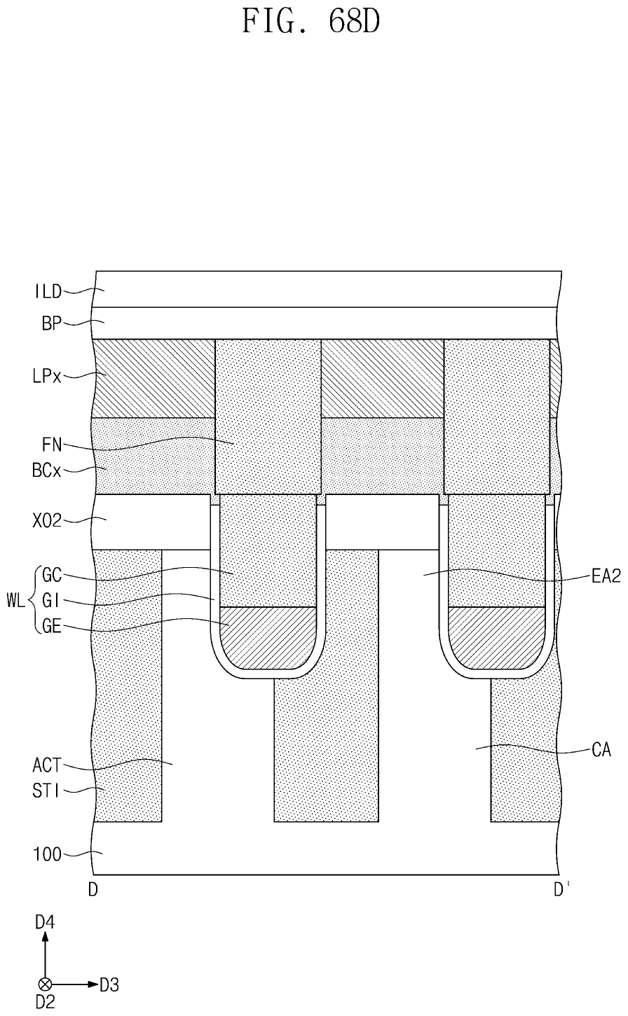

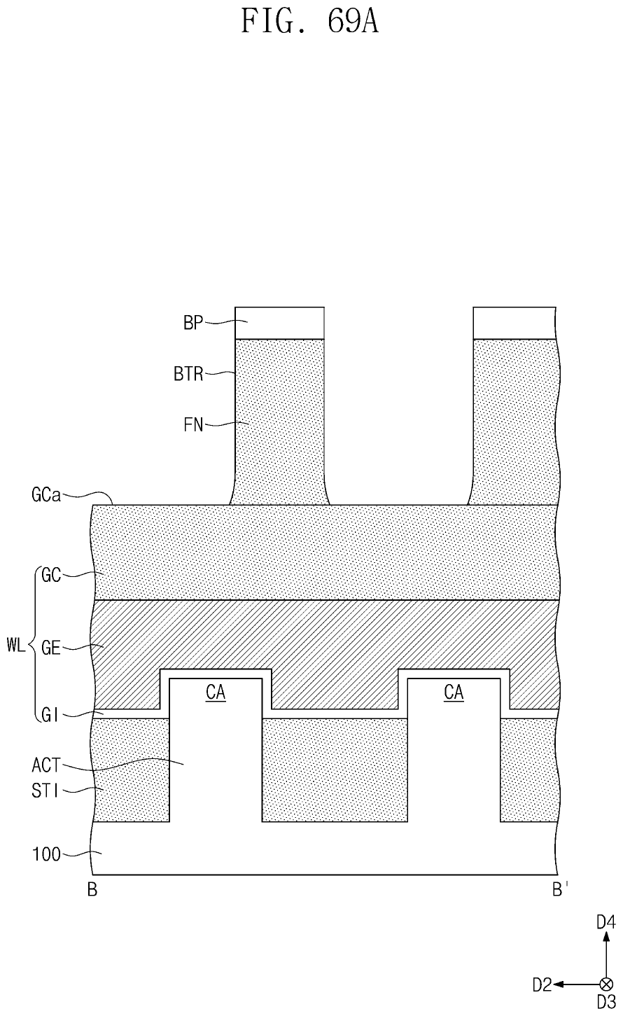

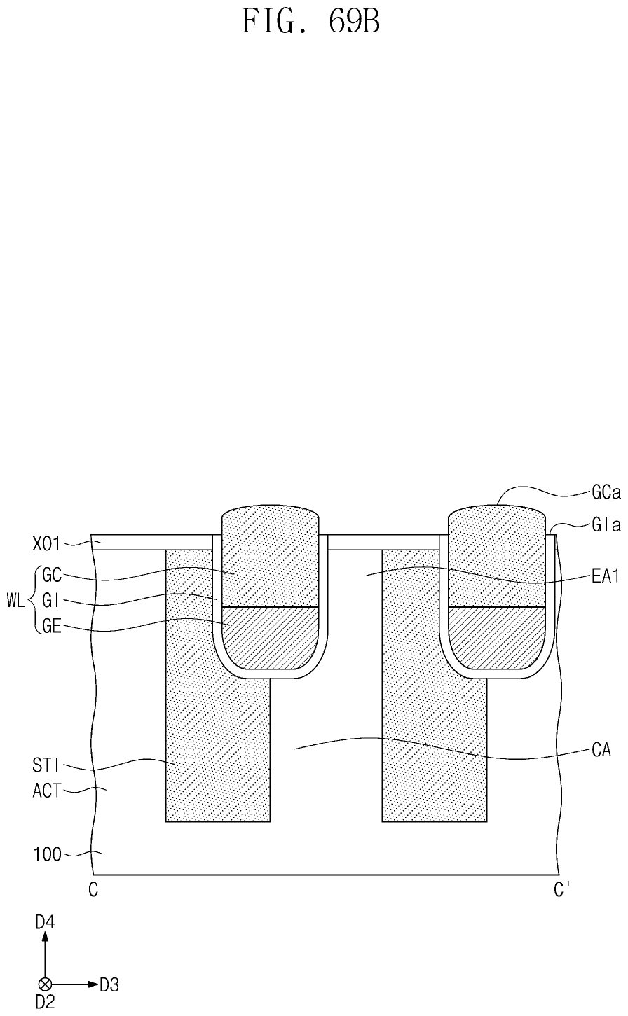

FIGS. 69A and 69B illustrate cross-sectional views showing a method of fabricating a semiconductor device according to some embodiments of the present inventive concepts.

Referring to FIGS. 69A and 69B, when the bit-line trench regions BTR are formed as discussed with reference to FIGS. 31 to 32D, a gate capping pattern GC may be formed to have a top surface GCa located at a level higher than that of a top surface of the first active pad XO1 and a top surface GIa of the gate dielectric pattern GI. This may be adjusted by using an etch selectivity between the gate capping pattern GC and its surrounding components (e.g., the first active pad XO1 and eth gate dielectric pattern GI). When the bit-line trench regions BTR are formed, the gate capping pattern GC may be removed less than the surrounding components.

According to the present inventive concepts, a first active pad may be provided between a bit line and a first edge part of an active pattern, and a second active pad may be provided between a storage node contact and a second edge part of the active pattern. Therefore, an easy electrical connection may be provided between the bit line and the first edge part and between the storage node contact and the second edge part. As a result, a semiconductor device may have improved electrical properties and increased reliability.

The aforementioned description provides some embodiments for explaining the present inventive concepts. Therefore, the present inventive concepts are not limited to the embodiments described above, and it will be understood by one of ordinary skill in the art that variations in form and detail may be made therein without departing from the spirit and described features of the present inventive concepts.

What is claimed is:

1. A semiconductor device, comprising:
a substrate;
an active pattern on the substrate, wherein the active pattern includes a first edge part and a second edge part that are spaced apart from each other in a first direction;
a word line that extends along a second direction between the first and second edge parts of the active pattern, wherein the second direction intersects the first direction;
a bit line that extends along a third direction on the first edge part of the active pattern, wherein the third direction intersects the first and second directions;
a storage node contact on the second edge part of the active pattern;
a first active pad between the bit line and the first edge part of the active pattern; and
a second active pad between the storage node contact and the second edge part of the active pattern,
wherein the first active pad extends in the third direction beyond the first edge part of the active pattern, and
wherein the second active pad extends in a direction opposite to the third direction beyond the second edge part of the active pattern.

2. The semiconductor device of claim 1, wherein a top surface of the second active pad is higher than a bottom surface of the bit line with respect to the substrate.

3. The semiconductor device of claim 1, wherein a bottom surface of the storage node contact is higher than a bottom surface of the bit line with respect to the substrate.

4. The semiconductor device of claim 1, further comprising:
a bit-line capping pattern on the bit line; and
a bottom electrode on the storage node contact,
wherein the bottom electrode is in contact with the bit-line capping pattern.

5. The semiconductor device of claim 1, wherein a top surface of the bit line is lower than a bottom surface of the storage node contact with respect to the substrate.

6. The semiconductor device of claim 1, wherein the storage node contact partially overlaps the bit line in a direction perpendicular to the second direction.

7. The semiconductor device of claim 1, further comprising:
a first active additional pad on a lateral surface of the first active pad; and
a second active additional pad on a lateral surface of the second active pad.

8. The semiconductor device of claim 1, wherein the first and second active pads include a material that is same as a material of the active pattern.

9. The semiconductor device of claim 1,
wherein the active pattern is a first active pattern,
wherein the semiconductor device further comprises:
a second active pattern that is adjacent in the second direction to the first active pattern;
a third active pattern that is adjacent in the third direction to the second active pattern; and
a fourth active pattern that is adjacent in the third direction to the first active pattern, and
wherein a second edge part of the fourth active pattern, the first edge part of the first active pattern, a second edge part of the third active pattern, and a first edge part of the second active pattern are sequentially disposed along the second direction.

10. The semiconductor device of claim 9,
wherein the word line is a first word line,
wherein the semiconductor device further comprises a second word line that is adjacent in the third direction to the first word line,
wherein the first word line intersects the first and second active patterns, and
wherein the second word line intersects the third and fourth active patterns.

11. A semiconductor device, comprising:
a substrate;
an active pattern on the substrate, wherein the active pattern includes a first edge part and a second edge part that are spaced apart from each other in a first direction;
a word line that extends along a second direction between the first and second edge parts of the active pattern, wherein the second direction intersects the first direction;
a bit line that extends along a third direction on the first edge part of the active pattern, wherein the third direction intersects the first and second directions;
a storage node contact on the second edge part of the active pattern;
a first active pad between the bit line and the first edge part of the active pattern; and
a second active pad between the storage node contact and the second edge part of the active pattern,
wherein a top surface of the second active pad is higher than a bottom surface of the bit line with respect to the substrate.

12. The semiconductor device of claim 11, wherein a bottom surface of the storage node contact is higher than the bottom surface of the bit line with respect to the substrate.

13. The semiconductor device of claim 11, wherein the first and second active pads include a material that is same as a material of the active pattern.

14. The semiconductor device of claim 11, wherein, when viewed in plan, an area of an overlapping region between the bit line and a top surface of the first active pad is greater than an area of an overlapping region between the bit line and a top surface of the first edge part of the active pattern.

15. The semiconductor device of claim 11, wherein, when viewed in plan, an area of an overlapping region between the storage node contact and a top surface of the first active pad is greater than an area of an overlapping region between the storage node contact and a top surface of the first edge part of the active pattern.

16. The semiconductor device of claim 11,
wherein the active pattern is a first active pattern,
wherein the semiconductor device further comprises:
a second active pattern that is adjacent in the second direction to the first active pattern;
a third active pattern that is adjacent in the third direction to the second active pattern; and
a fourth active pattern that is adjacent in the third direction to the first active pattern, and
wherein a second edge part of the fourth active pattern, the first edge part of the first active pattern, a second edge part of the third active pattern, and a first edge part of the second active pattern are sequentially disposed along the second direction.

17. A semiconductor device, comprising:
a substrate;
an active pattern on the substrate, wherein the active pattern includes a first edge part and a second edge part that are spaced apart from each other in a first direction;
a word line that extends along a second direction between the first and second edge parts of the active pattern, wherein the second direction intersects the first direction;
a bit line that extends along a third direction on the first edge part of the active pattern, wherein the third direction intersects the first and second directions;
a lower storage node contact on the second edge part of the active pattern;
an upper storage node contact on the lower storage node contact, wherein the upper storage node contact partially overlaps the lower storage node contact in a direction perpendicular to the second direction;
a first active pad between the bit line and the first edge part of the active pattern;
a second active pad between the lower storage node contact and the second edge part of the active pattern;
a landing pad on the upper storage node contact; and
a data storage pattern on the landing pad,
wherein the first active pad extends in the third direction beyond the first edge part of the active pattern, and
wherein the second active pad extends in a direction opposite to the third direction beyond the second edge part of the active pattern.

18. The semiconductor device of claim 17, wherein the upper storage node contact is offset from the lower storage node contact in the second direction or in a direction opposite to the second direction.

19. The semiconductor device of claim 17, further comprising:
a bit-line capping pattern on the bit line,
wherein the upper storage node contact is in contact with the bit-line capping pattern.

20. The semiconductor device of claim 19, wherein a bottom surface of the landing pad is higher than a top surface of the bit-line capping pattern with respect to the substrate.
